(19) United States
(12) Patent Application Publication
(10) Pub. No.: US 2013/0306151 A1
(43) Pub. Date: Nov. 21, 2013

(54) ORGANIC PHOTOVOLTAIC DEVICE AND MANUFACTURING METHOD THEREOF

(71) Applicants: Tero Mustonen, Binningen (CH); Natalia Chebotareva, Hagenthal le Bas (FR)

(72) Inventors: Tero Mustonen, Binningen (CH); Natalia Chebotareva, Hagenthal le Bas (FR)

(73) Assignee: BASF SE, Ludwigshafen (DE)

(21) Appl. No.: 13/978,260

(22) PCT Filed: Jan. 11, 2012
(86) PCT No.: PCT/IB2012/050132

§ 371 Date: Jul. 3, 2013

Related U.S. Application Data
(60) Provisional application No. 61/432,204, filed on Jan. 13, 2011.

(30) Foreign Application Priority Data
Jan. 13, 2011 (EP) 11150782.8
Feb. 28, 2011 (EP) 11156218.7

(51) Int. Cl. H01L 51/00

(52) U.S. Cl. CPC H01L 51/0036; H01L 51/0043; H01L 51/0001
USPC 136/263; 252/500; 438/82

(57) ABSTRACT

An organic photovoltaic (OPV) device is provided. The OPV device comprises at least one photovoltaic layer, said layer comprising a mixture which comprises at least one diketopyrrolopyrrole (DPP) polymer and at least one stabilizing agent wherein the stabilizing agent is selected from the group consisting of a UV absorbing agent and an anti-radical agent. The mixture, which comprises at least one stabilizing agent which is preferably a UV absorbing agent or an anti-radical agent, and at least one DPP polymer, can be used for increasing the product life of an OPV device and for preventing the at least one DPP polymer from degradation during the production of an OPV device.

The present invention relates to an organic photovoltaic (OPV) device comprising at least one photovoltaic layer, said layer comprising a mixture which comprises at least one diketopyrrolopyrrole (DPP) polymer and at least one stabilizing agent wherein the stabilizing agent is preferably selected from the group consisting of a UV absorbing agent and an anti-radical agent; and further relates to the use of a mixture comprising at least one stabilizing agent which is preferably a UV absorbing agent or an anti-radical agent, and at least one DPP polymer for increasing the product life of an OPV device containing the mixture in at least one photovoltaic layer, or to the use of a mixture comprising at least one stabilizing agent which is preferably a UV absorbing agent or an anti-radical agent, and at least one DPP polymer for preventing the at least one DPP polymer from degradation during production of an OPV device containing the mixture in at least one photovoltaic layer.

A common problem of organic photovoltaic (OPV) devices which contain an organic semiconductor layer as photovoltaic layer is the degradation of said layer due to, for example, the direct contact with oxygen and/or (sun)light (e.g. Neugebauer et al., Solar Energy Mat. & Solar Cells 61 [2000]35). In order to prevent this organic semiconductor layer from degradation, it is a usual method to apply a suitable protecting material onto said organic semiconductor layer. However, the conditions under which such protecting material are applied onto such organic semiconductor layer are often times very harsh, and there is a considerable risk to damage the organic semiconductor material during application of the protecting material and thus to loose at least partially the semiconducting properties of the organic material.

As far as said organic semiconductor materials are concerned, DPP polymers exhibit excellent characteristics such as high efficiency in energy conversion, field effect mobility, good on/off current ratios, and stability. Moreover, these polymers have an excellent solubility in organic solvents and also excellent film-forming properties. Certain DPP polymers are described, for example, in WO 2008/000664 A1, WO 2010/049321 A1, or WO 2010/049323 A1. In particular, WO 2008/000664 A1 discloses the use of DPP polymers in OPV devices; however, this document is silent on OPV devices comprising specific stabilizing agents to prevent the DPP polymers from degradation.

Therefore, it is an object of the invention to provide an OPV device which, on the one hand, exhibits an excellent product life and, on the other hand, allows for a production which lacks above-mentioned risk of at least partially destroying the organic semiconductor material.

According to the present invention, it was found that a photovoltaic layer comprising or consisting of DPP polymer, and a corresponding photovoltaic cell or device containing such a layer, surprisingly may be protected against degradation by radiation and/or oxidation in that at least one stabilizing agent is admixed to the photoactive layer comprising the DPP polymer while photoelectric activity is retained. Thus, instead of applying a protecting material onto an already existing DPP polymer layer, i.e. a photovoltaic layer comprising or consisting of DPP polymer, a mixture of at least one stabilizing agent and at least one polymer can be used at least as component of a photovoltaic layer of an OPV device.

Therefore, the present invention relates to an organic photovoltaic (OPV) device comprising at least one photovoltaic layer, said layer comprising a mixture which comprises at least one diketopyrrolopyrrole (DPP) polymer and at least one stabilizing agent.

Further, the present invention relates to a process for the production of an organic photovoltaic (OPV) device, said process comprising
(aa) providing at least one diketopyrrolopyrrole (DPP) polymer, at least one stabilizing agent which is preferably a UV absorbing agent or an anti-radical agent, and preferably at least one electron acceptor material;
(bb) providing a substrate onto which an anode and optionally, onto the anode, a smoothing layer has been applied;
(cc) mixing the compounds provided in (aa) with at least one suitable solvent;
(dd) applying the mixture obtained from (cc) onto the anode, optionally onto the smoothing layer.

Yet further, the present invention relates to the use of a mixture comprising at least one stabilizing agent which is preferably a UV absorbing agent or an anti-radical agent, and at least one diketopyrrolopyrrole (DPP) polymer for increasing the product life of an organic photovoltaic (OPV) device containing the mixture in at least one photovoltaic layer.

Still further, the present invention relates to the use of a mixture comprising at least one stabilizing agent which is preferably a UV absorbing agent or an anti-radical agent, and at least one diketopyrrolopyrrole (DPP) polymer for preventing the at least one DPP polymer from degradation during production of an OPV device containing the mixture in at least one photovoltaic layer.

### The Stabilizing Agent

The term “stabilizing agent” has the meaning commonly known in the field of organic polymer technology and generally stands for an agent providing protection against degradation by irradiation and/or oxidation; see chapters “antioxidants” and “light stabilizers” in Plastics Additives Handbook, H. Zweifel (ed), 5^{th} edition, Hanser 2001. As far as the at least one stabilizing agent used according to the present invention is concerned, no specific restrictions exist with the proviso that the desired stabilization of the at least one DPP polymer is achieved. The stabilizing agent itself generally has no conducting, semiconducting, photoelectric properties. The stabilizing agents often are classified as UV absorbers (i.e. UV absorbing agents) or anti-radical agents. UV absorbers generally possess a high extinction coefficient (usually higher than the one of the material to be protected) and are not degraded during their action since the absorbed radiation energy is transformed into heat. Anti-radical agents commonly are either radical-trapping agents (radical scavengers) or antioxidants. Antioxidants, such as hindered phenols, mainly act as reducing agents (H-donors), which get oxidized themselves during their activity. Radical-trapping agents, such as hindered amine light stabilizers (HALS) show further effects; alike UV absorbers, HALS generally retain their activity over several cycles. Conceivable stabilizing agents thus are, for example, UV absorbers and anti-radical agents such as hindered phenols or HALS.

Hindered amines such as hindered amine light stabilizer (HALS), hindered nitroxyl compounds or hindered hydroxylamine compounds or salts thereof generally conform to the structures

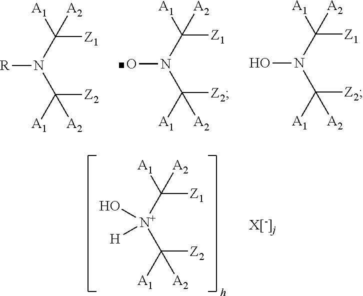

wherein, for example, R is H or an organic residue such as alkyl or alkoxy (e.g. of 1 to 20 carbon atoms); A₁ and A₂ are independently alkyl of 1 to 4 carbon atoms or are together pentamethylene, Z₁ and Z₂ are, for example, each methyl, or Z₁ and Z₂ together form a linking moiety which may additionally be substituted by an ester, ether, hydroxy, oxo, cyanohydrin, amide, amino, carboxy or urethane group, h is the number of positive charges and j is the number of negative charges, X is an inorganic or organic anion, and where the total charge of cations h is equal to the total charge of anions j.

Further anti-radical agents are benzofuranone compounds, e.g. of the structure

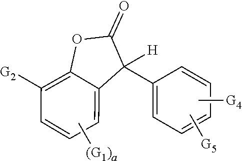

wherein, for example, G₁ is hydrogen; C₁-C₂₂alkyl; C₁-C₂₂alkylthio; C₂-C₂₂alkylthioalkyl; C₅-C₇cycloalkyl; phenyl; C₇-C₉-phenylalkyl; or SO₃M; G₂ is C₁-C₂₂alkyl; C₅-C₇cycloalkyl; phenyl; or C₇-C₉-phenylalkyl; G₄ and G₅ are each independently of the other hydrogen; or C₁-C₂₂alkyl; and

a is 0, 1, or 2.

Useful UV absorbing agents are, for example, suitable benzophenone derivatives like 2-hydroxybenzophenone derivatives, suitable benzotriazole derivatives like 2-hydroxyphenyl benzotriazole derivatives, or suitable hydroxyphenyltriazine derivatives like 2-hydroxyphenyltriazine derivatives.

Further useful antioxidants include the hindered phenols, as explained in more detail below.

Preferably, according to the present invention, the stabilizing agent is selected from the group consisting of a UV absorbing agent and an anti-radical agent. More preferably, the anti-radical agent is a hindered phenol.

According to one preferred embodiment of the present invention, the mixture comprising at least one diketopyrrolopyrrole (DPP) polymer and at least one stabilizing agent is free of a hindered amine light stabilizer (HALS), preferably free of a hindered amine, said mixture being comprised in the at least one photovoltaic layer comprised in the organic photovoltaic (OPV) device.

### UV Absorbing Agent

Preferred UV absorbing agents used according to the present invention are selected from the group consisting of hydroxybenzophenone derivatives, hydroxyphenyl benzotriazole derivatives, oxalic acid anilide derivatives, hydroxyphenyl triazine derivatives, and mixtures of two or more thereof. More preferably, the UV absorbing agents used according to the present invention are selected from the group consisting of hydroxybenzophenone derivatives, hydroxyphenyl benzotriazole derivatives, hydroxyphenyl triazine derivatives, and mixtures of two or more thereof. Even more preferably, the UV absorbing agents used according to the present invention are selected from the group consisting of 2-hydroxybenzophenone derivatives, 2-hydroxyphenyl benzotriazole derivatives, 2-hydroxyphenyl triazine derivatives, and mixtures of two or more thereof.

Therefore, the present invention relates to above-described OPV device wherein the UV absorbing agent is

a 2-hydroxybenzophenone of formula I

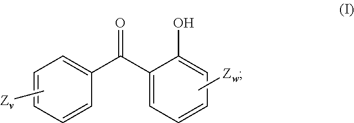

a 2-hydroxyphenylbenzotriazole of formula IIa, IIb or IIc

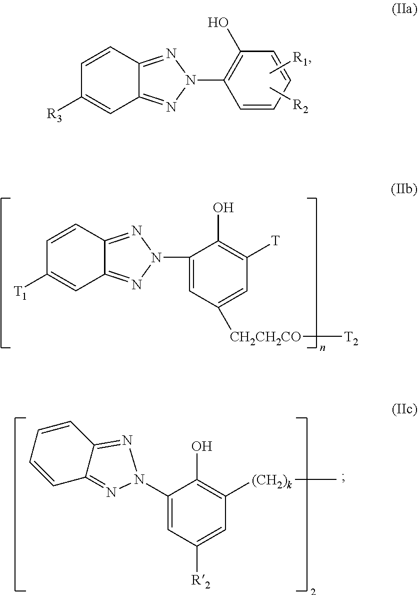

a 2-hydroxyphenyltriazine is of formula III

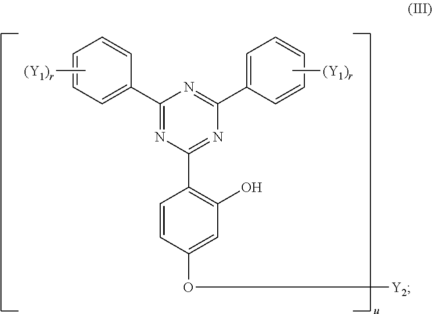

an oxanilide is of formula (IV)

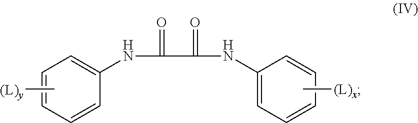

wherein
in the compounds of the formula (I),
v is an integer from 1 to 3 and w is 1 or 2 and the substituents Z independently of one another are hydrogen, halogen, hydroxyl or alkoxy having 1 to 12 carbon atoms;
in the compounds of the formula (IIa),
R₁ is hydrogen, alkyl having 1 to 24 carbon atoms, phenylalkyl having 1 to 4 carbon atoms in the alkyl moiety, cycloalkyl having 5 to 8 carbon atoms or a radical of the formula

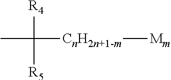

R₄ and R₅ independently of one another are alkyl having in each case 1 to 5 carbon atoms, or
R₄, together with the radical CₙH₂ₙ₊₁₋ₘ, forms a cycloalkyl radical having 5 to 12 carbon atoms,
m is 1 or 2, n is an integer from 2 to 20 and
M is a radical of the formula —COOR₆ in which
R₆ is hydrogen, alkyl having 1 to 12 carbon atoms, alkoxyalkyl having in each case 1 to 20 carbon atoms in the alkyl moiety and in the alkoxy moiety or phenylalkyl having 1 to 4 carbon atoms in the alkyl moiety,
R₂ is hydrogen, halogen, alkyl having 1 to 18 carbon atoms, and phenylalkyl having 1 to 4 carbon atoms in the alkyl moiety, and
R₃ is hydrogen, chlorine, alkyl or alkoxy having in each case 1 to 4 carbon atoms or —COOR₆ in which R₆ is as defined above, at least one of the radicals R₁ and R₂ being other than hydrogen;
in the compounds of the formula (IIb),
T is hydrogen or alkyl having 1 to 6 carbon atoms,
T₁ is hydrogen, chlorine or alkyl or alkoxy having in each case 1 to 4 carbon atoms,
n is 1 or 2 and,
if n is 1,
T₂ is chlorine or a radical of the formula —OT₃ or

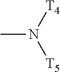

and,
if n is 2, T₂ is a radical of the formula

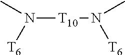

### or —O-T₉-O—;

in which
T₃ is hydrogen, alkyl which has 1 to 18 carbon atoms and is unsubstituted or substituted by 1 to 3 hydroxyl groups or by —OCOT₆, alkyl which has 3 to 18 carbon atoms, is interrupted once or several times by —O— or —NT₆- and is unsubstituted or substituted by hydroxyl or —OCOT₆, cycloalkyl which has 5 to 12 carbon atoms and is unsubstituted or substituted by hydroxyl and/or alkyl having 1 to 4 carbon atoms, alkenyl which has 2 to 18 carbon atoms and is unsubstituted or substituted by hydroxyl, phenylalkyl having 1 to 4 carbon atoms in the alkyl moiety, or a radical of the formula

—CH₂CH(OH)-T₇

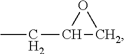

T₄ and T₅ independently of one another are hydrogen, alkyl having 1 to 18 carbon atoms, alkyl which has 3 to 18 carbon atoms and is interrupted once or several times by —O— or —NT₆-, cycloalkyl having 5 to 12 carbon atoms, phenyl, phenyl which is substituted by alkyl having 1 to 4 carbon atoms, alkenyl having 3 to 8 carbon atoms, phenylalkyl having 1 to 4 carbon atoms in the alkyl moiety or hydroxyalkyl having 2 to 4 carbon atoms,
T₆ is hydrogen, alkyl having 1 to 18 carbon atoms, cycloalkyl having 5 to 12 carbon atoms, alkenyl having 3 to 8 carbon atoms, phenyl, phenyl which is substituted by alkyl having 1 to 4 carbon atoms, phenylalkyl having 1 to 4 carbon atoms in the alkyl moiety,
T₇ is hydrogen, alkyl having 1 to 18 carbon atoms, phenyl which is unsubstituted or substituted by hydroxyl, phenylalkyl having 1 to 4 carbon atoms in the alkyl moiety, or —CH₂OT₈,
T₈ is alkyl having 1 to 18 carbon atoms, alkenyl having 3 to 8 carbon atoms, cycloalkyl having 5 to 10 carbon atoms, phenyl, phenyl which is substituted by alkyl having 1 to 4 carbon atoms, or phenylalkyl having 1 to 4 carbon atoms in the alkyl moiety,
T₉ is alkylene having 2 to 8 carbon atoms, alkenylene having 4 to 8 carbon atoms, alkynylene having 4 carbon atoms, cyclohexylene, alkylene which has 2 to 8 carbon atoms and is interrupted once or several times by —O—, or a radical of the formula —CH₂CH(OH)CH₂OT₁₁OCH₂CH(OH)CH₂— or —CH₂—C(CH₂OH)₂—CH₂—,
T₁₀ is alkylene which has 2 to 20 carbon atoms and can be interrupted once or several times by —O—, or cyclohexylene,
T₁₁ is alkylene having 2 to 8 carbon atoms, alkylene which has 2 to 18 carbon atoms and is interrupted once or several times by —O—, 1,3-cyclohexylene, 1,4-cyclohexylene, 1,3-phenylene or 1,4-phenylene, or
T₁₀ and T₆, together with the two nitrogen atoms, are a piperazine ring;
in the compounds of formula (IIc),
R₁₂ is C₁-C₁₂alkyl and k is a number from 1 to 4;
in the compounds of the formula (III),
u is 1 or 2 and r is an integer from 1 to 3, the substituents
Y₁ independently of one another are hydrogen, hydroxyl, phenyl or halogen, halogenomethyl, alkyl having 1 to 12 carbon atoms, alkoxy having 1 to 18 carbon atoms, alkoxy having 1 to 18 carbon atoms which is substituted by a group —COO(C₁-C₁₈alkyl);
if u is 1, Y₂ is alkyl having 1 to 18 carbon atoms, phenyl which is unsubstituted or substituted by hydroxyl, halogen, alkyl or alkoxy having 1 to 18 carbon atoms;
alkyl which has 1 to 12 carbon atoms and is substituted by —COOH, —COOY₈, —CONH₂, —CONHY₉, —CONY₉Y₁₀, —NH₂, —NHY₉, —NY₉Y₁₀, —NHCOY₁₁, —CN and/or —OCOY₁₁;
alkyl which has 4 to 20 carbon atoms, is interrupted by one or more oxygen atoms and is unsubstituted or substituted by hydroxyl or alkoxy having 1 to 12 carbon atoms, alkenyl having 3 to 6 carbon atoms, glycidyl, cyclohexyl which is unsubstituted or substituted by hydroxyl, alkyl having 1 to 4 carbon atoms and/or —OCOY₁₁, phenylalkyl which has 1 to 5 carbon atoms in the alkyl moiety and is unsubstituted or substituted by hydroxyl, chlorine and/or methyl, —COY₁₂ or —SO₂Y₁₃, or,
if u is 2,
Y₂ is alkylene having 2 to 16 carbon atoms, alkenylene having 4 to 12 carbon atoms, xylylene, alkylene which has 3 to 20 carbon atoms, is interrupted by one or more —O— atoms and/or is substituted by hydroxyl, —CH₂CH(OH)CH₂—O—Y₁₅—OCH₂CH(OH)CH₂, —CO—Y₁₆—CO—, —CO—NH—Y₁₇—NH—CO— or —(CH₂)ₘ—CO₂—Y₁₈—OCO—(CH₂)ₘ, in which
m is 1, 2 or 3,
Y₈ is alkyl having 1 to 18 carbon atoms, alkenyl having 3 to 18 carbon atoms, alkyl which has 3 to 20 carbon atoms, is interrupted by one or more oxygen or sulfur atoms or —NT₆- and/or is substituted by hydroxyl, alkyl which has 1 to 4 carbon atoms and is substituted by —P(O)(OY₁₄)₂, —NY₉Y₁₀ or —OCOY₁₁ and/or hydroxyl, alkenyl having 3 to 18 carbon atoms, glycidyl, or phenylalkyl having 1 to 5 carbon atoms in the alkyl moiety,
Y₉ and Y₁₀ independently of one another are alkyl having 1 to 12 carbon atoms, alkoxyalkyl having 3 to 12 carbon atoms, dialkylaminoalkyl having 4 to 16 carbon atoms or cyclohexyl having 5 to 12 carbon atoms, or Y₉ and Y₁₀ together are alkylene, oxaalkylene or azaalkylene having in each case 3 to 9 carbon atoms,
Y₁₁ is alkyl having 1 to 18 carbon atoms, alkenyl having 2 to 18 carbon atoms or phenyl,
Y₁₂ is alkyl having 1 to 18 carbon atoms, alkenyl having 2 to 18 carbon atoms, phenyl, alkoxy having 1 to 12 carbon atoms, phenoxy, alkylamino having 1 to 12 carbon atoms or phenylamino,
Y₁₃ is alkyl having 1 to 18 carbon atoms, phenyl or alkylphenyl having 1 to 8 carbon atoms in the alkyl radical,
Y₁₄ is alkyl having 1 to 12 carbon atoms or phenyl,
Y₁₅ is alkylene having 2 to 10 carbon atoms, phenylene or a group -phenylene-M-phenylene- in which M is —O—, —S—, —SO₂—, —CH₂— or —C(CH₃)₂—,
Y₁₆ is alkylene, oxaalkylene or thiaalkylene having in each case 2 to 10 carbon atoms, phenylene or alkenylene having 2 to 6 carbon atoms,
Y₁₇ is alkylene having 2 to 10 carbon atoms, phenylene or alkylphenylene having 1 to 11 carbon atoms in the alkyl moiety, and
Y₁₈ is alkylene having 2 to 10 carbon atoms or alkylene which has 4 to 20 carbon atoms and is interrupted once or several times by oxygen;
in the compounds of the formula (IV) x is an integer from 1 to 3 and the substituents L independently of one another are hydrogen, alkyl, alkoxy or alkylthio having in each case 1 to 22 carbon atoms, phenoxy or phenylthio.

C₁-C₁₈alkyl may be linear or branched. Examples of alkyl having up to 18 carbon atoms are methyl, ethyl, propyl, isopropyl, n-butyl, sec-butyl, isobutyl, tert-butyl, 2-ethylbutyl, n-pentyl, isopentyl, 1-methylpentyl, 1,3-dimethylbutyl, n-hexyl, 1-methylhexyl, n-heptyl, isoheptyl, 1,1,3,3-tetramethylbutyl, 1-methylheptyl, 3-methylheptyl, n-octyl, 2-ethylhexyl, 1,1,3-trimethylhexyl, 1,1,3,3-tetramethylpentyl, nonyl, decyl, undecyl, 1-methylundecyl, dodecyl, 1,1,3,3,5,5-hexamethylhexyl, tridecyl, tetradecyl, pentadecyl, hexadecyl, heptadecyl and octadecyl.

In the compounds of the formula (IIa) R₁ can be hydrogen or alkyl having 1 to 24 carbon atoms, such as methyl, ethyl, propyl, butyl, hexyl, octyl, nonyl, dodecyl, tetradecyl, hexadecyl, octadecyl, nonadecyl and eicosyl and also corresponding branched isomers. Furthermore, in addition to phenylalkyl having 1 to 4 carbon atoms in the alkyl moiety, for example benzyl, R₁ can also be cycloalkyl having 5 to 8 carbon atoms, for example cyclopentyl, cyclohexyl and cyclooctyl, or a radical of the formula

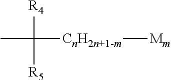

in which R₄ and R₅ independently of one another are alkyl having in each case 1 to 5 carbon atoms, in particular methyl, or R₄, together with the CₙH₂ₙ₊₁₋ₘ radical, forms a cycloalkyl radical having 5 to 12 carbon atoms, for example cyclohexyl, cyclooctyl and cyclodecyl. M is a radical of the formula —COOR₆ in which R₆ is not only hydrogen but also alkyl having 1 to 12 carbon atoms or alkoxyalkyl having 1 to 20 carbon atoms in each of the alkyl and alkoxy moieties. Suitable alkyl radicals R₆ are those enumerated for R₁. Examples of suitable alkoxyalkyl groups are —C₂H₄OC₂H₅, —C₂H₄OC₈H₁₇ and —C₄H₈₀C₄H₉. As phenylalkyl having 1 to 4 carbon atoms, R₆ is, for example, benzyl, cumyl, alpha-methylbenzyl or phenylbutyl.

In addition to hydrogen and halogen, for example chlorine and bromine, R₂ can also be alkyl having 1 to 18 carbon atoms. Examples of such alkyl radicals are indicated in the definitions of R₁. R₂ can also be phenylalkyl having 1 to 4 carbon atoms in the alkyl moiety, for example benzyl, alpha-methylbenzyl and cumyl.

Halogen as a substituent means in all cases fluorine, chlorine, bromine or iodine, preferably chlorine or bromine and more preferably chlorine.

At least one of the radicals R₁ and R₂ must be other than hydrogen.

In addition to hydrogen or chlorine, R₃ is also alkyl or alkoxy having in each case 1 to 4 carbon atoms, for example methyl, butyl, methoxy and ethoxy, and also —COOR₆.

In the compounds of the formula (IIb) T is hydrogen or alkyl having 1 to 6 carbon atoms, such as methyl and butyl, T₁ is not only hydrogen or chlorine, but also alkyl or alkoxy having in each case 1 to 4 carbon atoms, for example methyl, methoxy and butoxy, and, if n is 1, T₂ is chlorine or a radical of the formula —OT₃ or —NT₄T₅. T₃ is here hydrogen or alkyl having 1 to 18 carbon atoms (cf. the definition of R₁). These alkyl radicals can be substituted by 1 to 3 hydroxyl groups or by a radical —OCOT₆. Furthermore, T₃ can be alkyl having 3 to 18 carbon atoms (cf. the definition of R₁) which is interrupted once or several times by —O— or —NT₆- and is unsubstituted or substituted by hydroxyl or —OCOT₆. Examples of T₃ as cycloalkyl are cyclopentyl, cyclohexyl or cyclooctyl. T₃ can also be alkenyl having 2 to 18 carbon atoms. Suitable alkenyl radicals are derived from the alkyl radicals enumerated in the definitions of R₁. These alkenyl radicals can be substituted by hydroxyl. Examples of T₃ as phenylalkyl are benzyl, phenylethyl, cumyl, alpha-methylbenzyl or benzyl. T₃ can also be a radical of the formula —CH₂CH(OH)-T₇ or

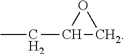

Like T₃, T₄ and T₅ can, independently of one another, be not only hydrogen but also alkyl having 1 to 18 carbon atoms or alkyl which has 3 to 18 carbon atoms and is interrupted once or several times by —O— or —NT₆-. T₄ and T₅ can also be cycloalkyl having 5 to 12 carbon atoms, for example cyclopentyl, cyclohexyl and cyclooctyl. Examples of T₄ and T₅ as alkenyl groups can be found in the illustrations of T₃. Examples of T₄ and T₅ as phenylalkyl having 1 to 4 carbon atoms in the alkyl moiety are benzyl or phenylbutyl. Finally, these substituents can also be hydroxyalkyl having 1 to 3 carbon atoms.

If n is 2, T₂ is a divalent radical of the formula

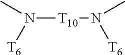

### or —O-T₉-O—.

In addition to hydrogen, T₆ (see above also) is alkyl, cycloalkyl, alkenyl, aryl or phenylalkyl; examples of such radicals have already been given above.

In addition to hydrogen and the phenylalkyl radicals and long-chain alkyl radicals mentioned above, T₇ can be phenyl or hydroxyphenyl and also —CH₂OT₈ in which T₈ can be one of the alkyl, alkenyl, cycloalkyl, aryl or phenylalkyl radicals enumerated.

The divalent radical T₉ can be alkylene having 2 to 8 carbon atoms, and such radicals can also be branched. This also applies to the alkenylene and alkynylene radicals T₉. As well as cyclohexylene, T₉ can also be a radical of the formula —CH₂CH(OH)CH₂OT₁₁OCH₂CH(OH)CH₂— or —CH₂—C(CH₂OH)₂—CH₂—.

T₁₀ is a divalent radical and, in addition to cyclohexylene, is also alkylene which has 2 to 20 carbon atoms and which can be interrupted once or several times by —O—. Suitable alkylene radicals are derived from the alkyl radicals mentioned in the definitions of R₁.

T₁₁ is also an alkylene radical. It contains 2 to 8 carbon atoms or, if it is interrupted once or several times by —O—, 4 to 10 carbon atoms. T₁₁ is also 1,3-cyclohexylene, 1,4-cyclohexylene, 1,3-phenylene or 1,4-phenylene.

Together with the two nitrogen atoms, T₆ and T₁₀ can also be a piperazine ring.

Examples of alkyl, alkoxy, phenylalkyl, alkylene, alkenylene, alkoxyalkyl and cycloalkyl radicals and also alkylthio, oxaalkylene or azoalkylene radicals in the compounds of the formulae (I), (IIa), (IIb), (IIc), (III) and IV) can be deduced from the above statements.

According to the present invention, the compounds of formulae (IIa), (IIb), and (IIc) as well as (III) are preferred. Within the benzotriazole UV-absorbers those according to formula (IIa) are in general preferred.

The UV absorbers of the formulae (I), (IIa), (IIb), (IIc), (III) and (IV) are known per se and are described, together with their preparation in, for example, WO 96/28431 A1, EP 0 323 408 A1, EP 0 057 160 A1, U.S. Pat. No. 5,736,597, EP 0 434 608 A1, U.S. Pat. No. 4,619,956, DE 31 35 810 A1, GB 1 336 391 A. Preferred meanings of substituents and individual compounds can be deduced from the documents mentioned.

According to an even more preferred embodiment, the present invention relates to above-described device wherein

the 2-hydroxybenzophenone is selected from group consisting of the 4-hydroxy, 4-methoxy, 4-octyloxy, 4-decyloxy, 4-dodecyloxy, 4-benzyloxy, and 2′-hydroxy-4,4′-dimethoxy derivative of the hydroxybenzophenone;
the 2-hydroxyphenylbenzotriazole is selected from the group consisting of 2-(2′-hydroxy-5′-methylphenyl)-benzotriazole, 2-(3′,5′-di-tert-butyl-2′-hydroxyphenyl)benzotriazole, 2-(5′-tert-butyl-2′-hydroxyphenyl)benzotriazole, 2-(2′-hydroxy-5′-(1,1,3,3-tetramethylbutyl)phenyl)benzotriazole, 2-(3′,5′-di-tert-butyl-2′-hydroxyphenyl)-5-chloro-benzotriazole, 2-(3′-tert-butyl-2′-hydroxy-5′-methylphenyl)-5-chloro-benzotriazole, 2-(3′-sec-butyl-5′-tert-butyl-2′-hydroxyphenyl)benzotriazole, 2-(2′-hydroxy-4′-octyloxyphenyl)benzotriazole, 2-(3′,5′-di-tert-amyl-2′-hydroxyphenyl)benzotriazole, 2-(3′,5′-bis-(alpha,alpha-dimethylbenzyl)-2′-hydroxyphenyl)benzotriazole, 2-(3′-tert-butyl-2′-hydroxy-5′-(2-octyloxycarbonylethyl)phenyl)-5-chloro-benzotriazole, 2-(3′-tert-butyl-5′-[2-(2-ethylhexyloxy)-carbonylethyl]-2′-hydroxyphenyl)-5-chloro-benzotriazole, 2-(3′-tert-butyl-2′-hydroxy-5′-(2-methoxycarbonylethyl)phenyl)-5-chloro-benzotriazole, 2-(3′-tert-butyl-2′-hydroxy-5′-(2-methoxycarbonylethyl)phenyl)benzotriazole, 2-(3′-tert-butyl-2′-hydroxy-5′-(2-octyloxycarbonylethyl)phenyl)benzotriazole, 2-(3′-tert-butyl-5′-[2-(2-ethylhexyloxy)carbonylethyl]-2′-hydroxyphenyl)benzotriazole, 2-(3′-dodecyl-2′-hydroxy-5′-methylphenyl)benzotriazole, 2-(3′-tert-butyl-2′-hydroxy-5′-(2-isooctyloxycarbonylethyl)phenylbenzotriazole, 2,2′-methylene-bis[4-(1,1,3,3-tetramethylbutyl)-6-benzotriazole-2-ylphenol]; the transesterification product of 2-[3′-tert-butyl-5′-(2-methoxycarbonylethyl)-2′-hydroxyphenyl]-2H-benzotriazole with polyethylene glycol 300; [R—CH₂CH₂—COO—CH₂CH₂ where R=3′-tert-butyl-4′-hydroxy-5′-2H-benzotriazol-2-ylphenyl, 2-[2′-hydroxy-3′-(alpha,alpha-dimethylbenzyl)-5′-(1,1,3,3-tetramethylbutyl)-phenyl]-benzotriazole; and 2-[2′-hydroxy-3′-(1,1,3,3-tetramethylbutyl)-5′-(alpha,alpha-dimethylbenzyl)-phenyl]benzotriazole;
the 2-hydroxyphenyltriazine is selected from the group consisting of 2,4,6-tris(2-hydroxy-4-octyloxyphenyl)-1,3,5-triazine, 2-(2-hydroxy-4-octyloxyphenyl)-4,6-bis(2,4-dimethylphenyl)-1,3,5-triazine, 2-(2,4-dihydroxyphenyl)-4,6-bis(2,4-dimethylphenyl)-1,3,5-triazine, 2,4-bis(2-hydroxy-4-propyloxyphenyl)-6-(2,4-dimethylphenyl)-1,3,5-triazine, 2-(2-hydroxy-4-octyloxyphenyl)-4,6-bis(4-methylphenyl)-1,3,5-triazine, 2-(2-hydroxy-4-dodecyloxyphenyl)-4,6-bis(2,4-dimethylphenyl)-1,3,5-triazine, 2-(2-hydroxy-4-tridecyloxyphenyl)-4,6-bis(2,4-dimethylphenyl)-1,3,5-triazine, 2-[2-hydroxy-4-(2-hydroxy-3-butyloxy-propoxy)phenyl]-4,6-bis(2,4-dimethyl)-1,3,5-triazine, 2-[2-hydroxy-4-(2-hydroxy-3-octyloxy-propyloxy)phenyl]-4,6-bis(2,4-dimethyl)-1,3,5-triazine, 2-[4-(dodecyloxy/tridecyloxy-2-hydroxypropoxy)-2-hydroxy-phenyl]-4,6-bis(2,4-dimethylphenyl)-1,3,5-triazine, 2-[2-hydroxy-4-(2-hydroxy-3-dodecyloxy-propoxy)phenyl]-4,6-bis(2,4-dimethylphenyl)-1,3,5-triazine, 2-(2-hydroxy-4-hexyloxy)phenyl-4,6-diphenyl-1,3,5-triazine, 2-(2-hydroxy-4-methoxyphenyl)-4,6-diphenyl-1,3,5-triazine, 2,4,6-tris[2-hydroxy-4-(3-butoxy-2-hydroxy-propoxy)phenyl]-1,3,5-triazine, 2-(2-hydroxyphenyl)-4-(4-methoxyphenyl)-6-phenyl-1,3,5-triazine, 2-{2-hydroxy-4-[3-(2-ethylhexyl-1-oxy)-2-hydroxy-propyloxy]phenyl}-4,6-bis(2,4-dimethylphenyl)-1,3,5-triazine and 2-(2-hydroxy-4-(2-ethyl-hexyl)oxy)phenyl-4,6-di(4-phenyl)phenyl-1,3,5-triazine.

A preferred 2-hydroxybenzophenone is the compound of formula

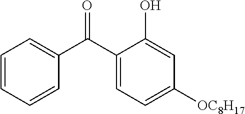

which is known as commercially available Chimassorb® 81.

An especially preferred the 2-hydroxyphenylbenzotriazole is the compound of formula

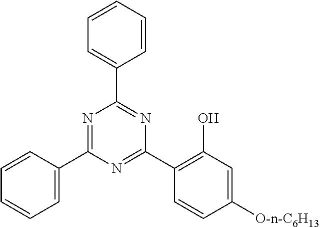

which is known as commercially available Tinuvin® 1577.

An especially preferred 2-hydroxyphenyltriazine is the compound of formula

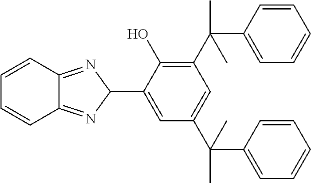 [SMILES: CC(C)(c1ccccc1)c1cc(C2N=c3ccccc3=N2)c(O)c(C(C)(C)c2ccccc2)c1]

which is known as commercially available Tinuvin® 234.

Further important UV absorbing agents are merocyanines such as disclosed in US-2011/200540 and further references cited therein; see especially sections [0015]-[0047], [0072]-[0078], [0079]-[0084], compounds of table 1 in section [0085], sections [0247]-[0256](example A1), which passages of US-2011/200540 are hereby incorporated by reference. Thus, merocyanines useful in the present invention include compounds of the formula V

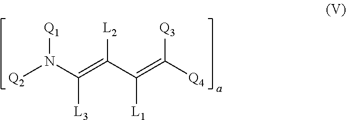

including E,E-, E,Z- and Z,Z-geometrical isomers thereof, wherein
Q₁ and Q₂ independently of each other are hydrogen; C₁-C₂₂alkyl; C₂-C₂₂ alkenyl, C₂-C₂₂alkinyl, C₃-C₁₂cycloalkyl, C₃-C₁₂cycloalkenyl, C₇-C₂₀aralkyl, C₁-C₂₀heteroalkyl, C₃-C₁₂cycloheteroalkyl, C₅-C₁₁heteroaralkyl, C₆-C₂₀aryl, C₄-C₉heteroaryl, COQ₁₃ or CONQ₁₃Q₁₄;
Q₃ is CN; —COOQ₅; —CONHQ₅; —COQ₅; —SO₂Q₅; —CONQ₅Q₆; C₆-C₂₀aryl; or C₄-C₉ heteroaryl;
Q₄ is CN; —COOQ₇; —CONHQ₇; —COQ₇; —SO₂Q₇; —CONQ₇Q₈; C₁-C₂₂ alkyl; C₂-C₂₂alkenyl; C₂-C₂₂ alkinyl; C₃-C₁₂cycloalkyl; C₃-C₁₂cycloalkenyl; C₇-C₂₀aralkyl; C₁-C₂₀heteroalkyl; C₃-C₁₂cycloheteroalkyl; C₅-C₁₁ heteroaralkyl; C₆-C₂₀ aryl; or C₄-C₉ heteroaryl;
Q₅, Q₆, Q₇ and Q₈ independently of each other are hydrogen; C₁-C₂₂alkyl; C₂-C₂₂alkenyl; C₂-C₂₂ alkinyl; C₃-C₁₂cycloalkyl; C₃-C₁₂cycloalkenyl; C₇-C₂₀aralkyl; C₁-C₂₀heteroalkyl, C₃-C₁₂cycloheteroalkyl; C₅-C₁₁heteroaralkyl; C₆-C₂₀aryl; C₄-C₉heteroaryl; SiQ₁₅Q₁₆Q₁₇; Si(OQ₁₅)(OQ₁₆)(OQ₁₇); SiQ₁₅(OQ₁₆)(OQ₁₇); SiQ₁₅Q₁₆(OQ₁₇); or a radical —XS;
L₁, L₂ or L₃ independently of each other are hydrogen, C₁-C₂₂alkyl; C₂-C₂₂alkenyl, C₂-C₂₂alkinyl; C₃-C₁₂cycloalkyl; C₃-C₁₂cycloalkenyl; C₇-C₂₀aralkyl; C₁-C₂₀heteroalkyl; C₃-C₁₂cycloheteroalkyl; C₅-C₁₁heteroaralkyl; C₆-C₂₀aryl; C₄-C₉heteroaryl; CN; OH; OQ₉; or COOQ₉;
Q₉ is hydrogen; C₁-C₂₂alkyl; C₂-C₂₂alkenyl; C₂-C₂₂alkinyl; C₃-C₁₂cycloalkyl; C₃-C₁₂cycloalkenyl; C₇-C₂₀aralkyl; C₁-C₂₀heteroalkyl; C₃-C₁₂cycloheteroalkyl; C₅-C₁₁hetero-aralkyl; C₆-C₂₀ aryl; or C₄-C₉heteroaryl;
L₁ and L₂, L₁ and L₃, L₂ and L₃, L₁ and Q₄, L₂ and Q₄, L₁ and Q₁, L₂ and Q₁, L₃ and Q₁, L₃ and Q₅, Q₃ and Q₄, Q₁ and Q₂, Q₇ and Q₈, Q₅ and Q₆ may be linked together to form 1, 2, 3 or 4 carbocyclic or N, O and/or S-heterocyclic rings, which may be further fused with other aromatic rings;
Q₁₀ represents Q₁₃; COQ₁₃; COOQ₁₃; CONH₂; CONHQ₁₃; or CONQ₁₃Q₁₄;
Q₁₁ represents halogen; OH; NH₂; NHQ₁₅; NQ₁₅Q₁₆; NQ₁₅OQ₁₆; O-Q₁₅; O—CO-Q₁₅; S-Q₁₅; CO-Q₁₅; oxo; thiono; CN; COOH; CONH₂; COOQ₁₅; CONHQ₁₅; CONQ₁₅Q₁₆; SO₂NH₂; SO₂NHQ₁₅; SO₂NQ₁₅Q₁₆; SO₂Q₁₅; SO₃Q₁₅; SiQ₁₅Q₁₆Q₁₇; SiOQ₁₅(OQ₁₆)(OQ₁₇); SiQ₁₅(OQ₁₆)(OQ₁₇); SiQ₁₅Q₁₆(OQ₁₇); O—Si-Q₁₅Q₁₆Q₁₇; O—Si—OQ₁₅(OQ₁₆)(OQ₁₇); O—Si-Q₁₅Q₁₆(OQ₁₇); O—SiQ₁₅(OQ₁₆)(OQ₁₇); PO(OQ₁₅)(OQ₁₆); or a radical *—XS;
Q₁₂ represents halogen, CN, SH, OH, CHO, Q₁₈; OQ₁₈; SQ₁₈; C(Q₁₈)=CQ₁₉Q₂₀; O—CO-Q₁₉; NHQ₁₉; NQ₁₈Q₁₉; CONH₂; CONHQ₁₈; CONQ₁₈Q₁₉; SO₂NH₂; SO₂NHQ₁₈; SO₂NQ₁₈Q₁₉; SO₂Q₁₈; COOH; COOQ₁₈; OCOOQ₁₈; NHCOQ₁₈; NQ₁₈COQ₁₉; NHCOOQ₁₉; NQ₁₉COOQ₂₀; SiQ₁₅Q₁₆Q₁₇; SiOQ₁₅(OQ₁₆)(OQ₁₇); SiQ₁₅(OQ₁₆)(OQ₁₇); SiQ₁₅Q₁₆(OQ₁₇); OSi Q₁₅Q₁₆Q₁₇; OSiOQ₁₅(OQ₁₆)(OQ₁₇); OSiQ₁₅Q₁₆(OQ₁₇); OSiQ₁₅(OQ₁₆)(OQ₁₇); P(═O)OQ₁₉OQ₂₀; P(═O)Q₁₉OQ₂₀; P(═O)Q₁₉Q₂₀; or a radical —XS; or is selected from the group consisting of C₁-C₂₂alkyl; C₃-C₁₂cycloalkyl; C₁-C₁₂alkenyl; C₃-C₁₂cycloalkenyl; C₁-C₁₂alkylthio; C₃-C₁₂cycloalkylthio; C₁-C₁₂alkenylthio; C₃-C₁₂cycloalkenylthio; C₁-C₁₂alkoxy; C₃-C₁₂cycloalkoxy; C₁-C₁₂alkenyloxy; or C₃-C₁₂cycloalkenyloxy, which may be unsubstituted or substituted by one or more, identical or different Q₁₁;
Q₁₃, Q₁₄, Q₁₅, Q₁₆, Q₁₇, Q₁₈, Q₁₉ and Q₂₀ independently of each other are C₁-C₂₂alkyl; C₃-C₁₂cycloalkyl; C₂-C₁₂alkenyl; C₃-C₁₂cycloalkenyl; C₆-C₁₄aryl; C₄-C₁₂heteroaryl; C₇-C₁₈aralkyl or C₅-C₁₆heteroaralkyl; or
Q₁₃ and Q₁₄, Q₁₅ and Q₁₆, Q₁₆ and Q₁₇ and/or Q₁₈ and Q₁₉ may be linked together to form unsubstituted or with C₁-C₄alkyl substituted pyrrolidine, piperidine, piperazine or morpholine;
X represents a linker;
S signifies a silane-, oligosiloxane- or polysiloxane-moiety; the term “oligosiloxane” denotes a group of the general formula Si(Q₁₅)ₘ[OSi(Q₁₆)]ₒ wherein
m has a value of 0, 1 or 2,
o has a value of 3, 2 or 1; and m+o have a value of 3 or refers to groups of the general formula

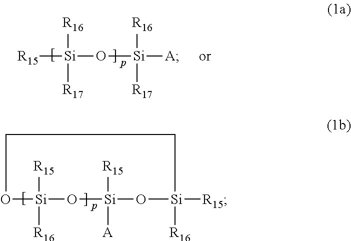

wherein
A represents a bond to the linker X; and
p has a value of 1 to 9;
the term “polysiloxane” refers in this context to groups of the general formula

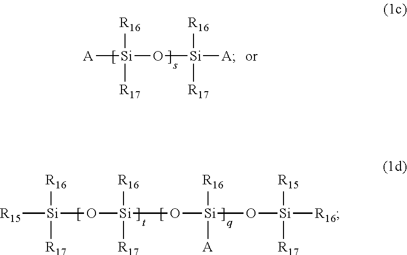

wherein
A represents a bond to the linker X;
has a value of 4 to 250;
t has a value of 5 to 250;
q has a value of 1 to 30;
n is 1 or integer;
n is from 1 to 6;
when n=2, Q₁, Q₅ or Q₄ is a bivalent alkyl group; or Q₁ and Q₂ together with the 2 nitrogen atoms linking them form a unsubstituted or alkyl-substituted

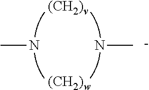

ring;
v is from 1 to 4,
w is from 1 to 4;
when n=3, Q₁, Q₅ or Q₄ is a trivalent alkyl group;
when n=4, Q₁, Q₅ or Q₄ is a tetravalent alkyl group; and
Q₁ and Q₂ in formula V are not simultaneously hydrogen.

### Anti-Radical Agent

Preferred anti-radical agents used according to the present invention are hindered phenols. More preferably, an anti-radical agent used according to the present invention is a compound of formula (1)

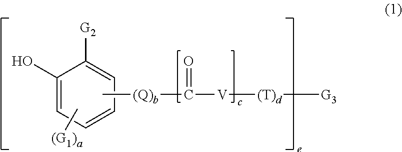

where in the above formulae
G₁ is hydrogen; C₁-C₂₂alkyl; C₁-C₂₂alkylthio; C₂-C₂₂alkylthioalkyl; C₅-C₇cycloalkyl; phenyl; C₇-C₉-phenylalkyl; or SO₃M;
G₂ is C₁-C₂₂alkyl; C₅-C₇cycloalkyl; phenyl; or C₇-C₉-phenylalkyl;

### Q is —CₘH₂ₘ—;

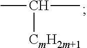

—CₘH₂ₘ—NH; a radical of formula

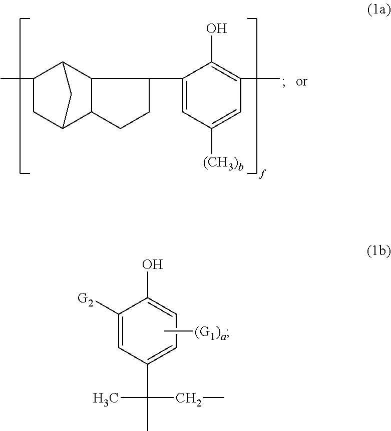

T is —CₙH₂ₙ—; —(CH₂)ₙ—O—CH₂—; phenylene;

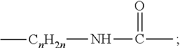

or a radical of formula

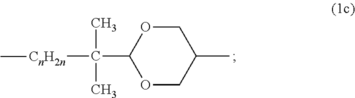

### V is —O—; or —NH—;

a is 0; 1; or 2;
d and g are each independently of one another 0; or 1;
e is an integer from 1 to 4;
f is an integer from 1 to 3; and
m, n and p are each independently of one another an integer from 1 to 3;
q is 0 or an integer from 1 to 3;
if e=1, each of b and c is 1;
G₃ is hydrogen; C₁-C₂₂alkyl; C₅-C₇cycloalkyl; C₁-C₂₂alkylthio; C₂-C₂₂alkylthioalkyl; C₂-C₁₈alkenyl; C₁-C₁₈phenylalkyl; M; SO₃M; a radical of formula

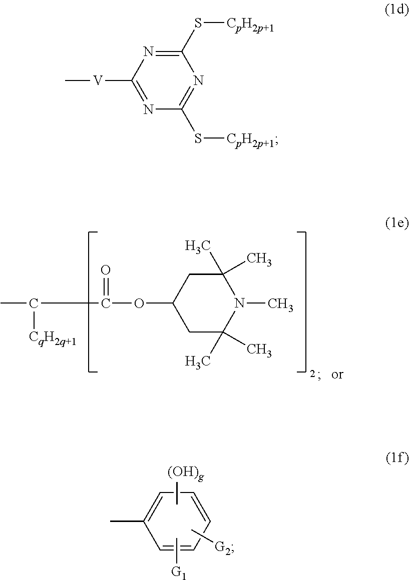

or G₃ is propyl substituted by OH and/or by C₂-C₂₂alkanoyloxy;
M is alkali; ammonium; H;
if e=2, then each of b and c independently is selected from 0 and 1;
G₃ is a direct bond; —CH₂—;

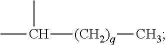

or —S—; or G₃ is propyl substituted by OH or C₂-C₂₂alkanoyloxy;
if e=3, then each of b and c independently is selected from 0 and 1;
G₃ is the radical of formula (1g);

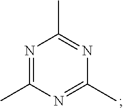

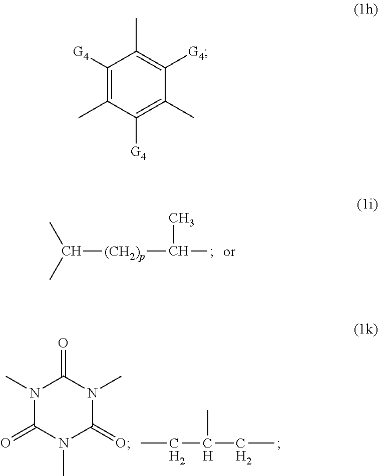

if e=4, then each of b and c independently is selected from 0 and 1;

### G₃ is

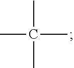

G₄ are each independently of the other hydrogen; or C1-C22alkyl;
or a compound of the formulae (16), (18), (20), (21), (22), (23)

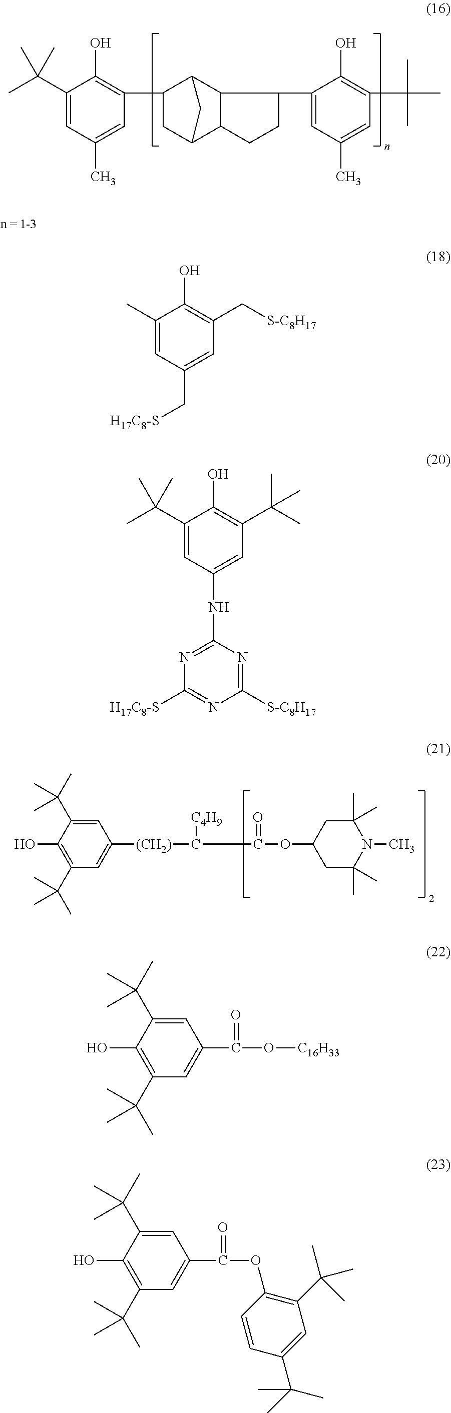

Preferred anti-radical agents include compounds listed in the following Table 1:

TABLE 1
Preferred anti-radical agents

| compound of | |
|---|---|
| formula | |
| (7) | 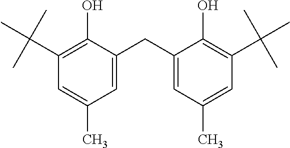 [SMILES: Cc1cc(Cc2cc(C)cc(C(C)(C)C)c2O)c(O)c(C(C)(C)C)c1] |
| (8) | 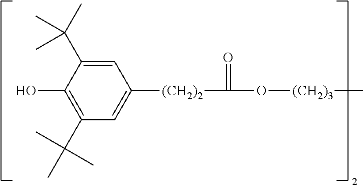 |
| (10) | 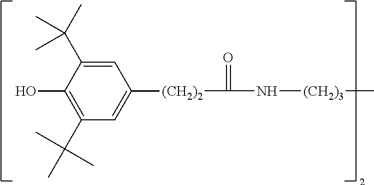 |
| (11) | 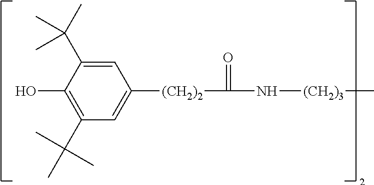 |
| (12) | 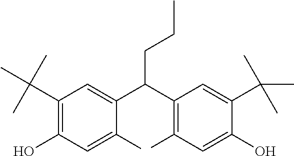 [SMILES: CCCC(c1cc(C(C)(C)C)c(O)cc1C)c1cc(C(C)(C)C)c(O)cc1C] |
| (13) | 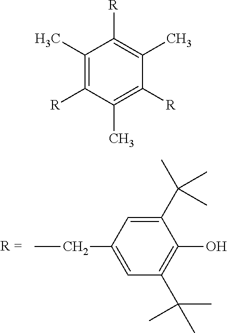 |
| (14) | 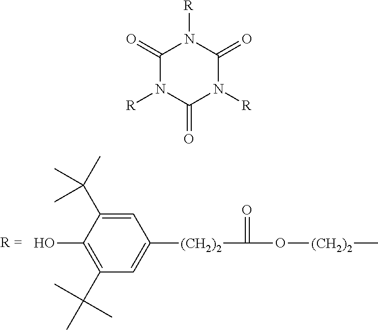 |
| (15) | 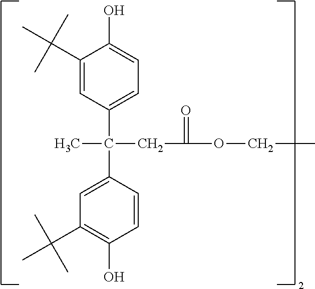 |
| (16) | 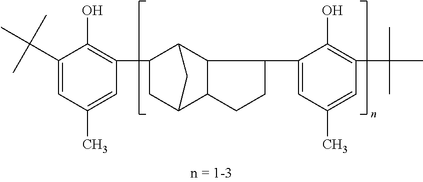 |
| (17) | 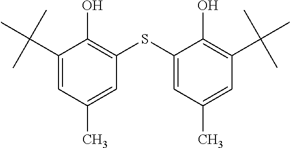 [SMILES: Cc1cc(Sc2cc(C)cc(C(C)(C)C)c2O)c(O)c(C(C)(C)C)c1] |
| (18) | 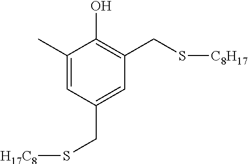 |
| (19) | 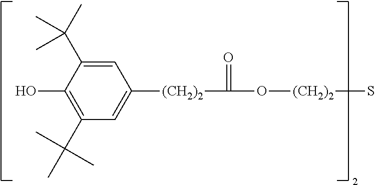 |
| (20) | 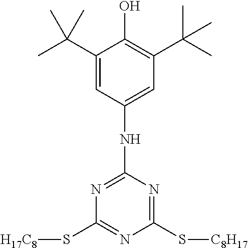 |
| (21) | 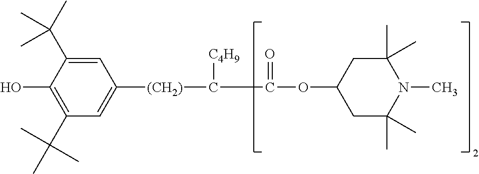 |
| (22) | 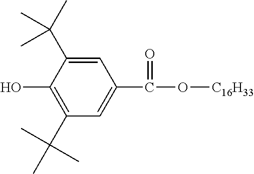 |
| (23) | 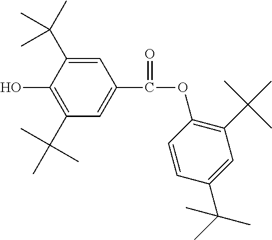 [SMILES: CC(C)(C)c1ccc(OC(=O)c2cc(C(C)(C)C)c(O)c(C(C)(C)C)c2)c(C(C)(C)C)c1] |
| (24) | 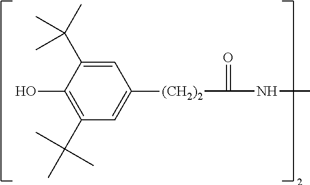 |
| (25) | 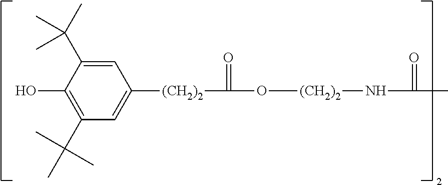 |
| (26) | 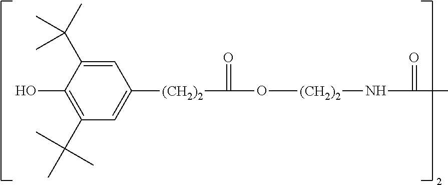 |
| (27) | 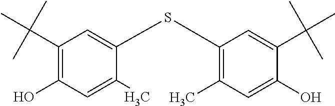 [SMILES: Cc1cc(O)c(C(C)(C)C)cc1Sc1cc(C(C)(C)C)c(O)cc1C] |
| (28) | 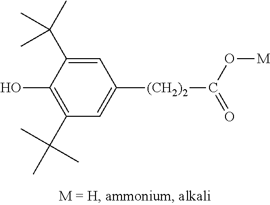 |
| (29) | 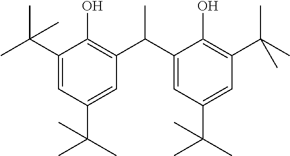 [SMILES: CC(c1cc(C(C)(C)C)cc(C(C)(C)C)c1O)c1cc(C(C)(C)C)cc(C(C)(C)C)c1O] |
| (30) | 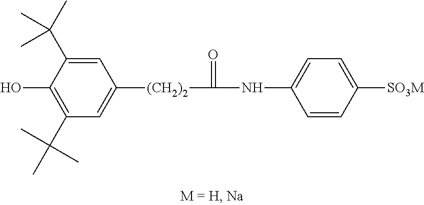 |
| (31) | 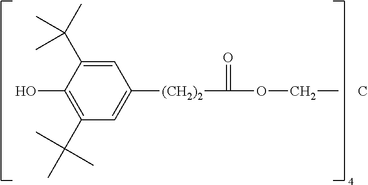 |
| (32) | 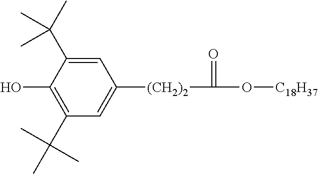 |
| (33) | 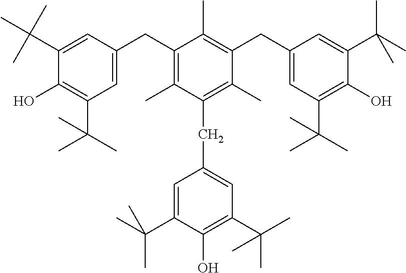 [SMILES: Cc1c(Cc2cc(C(C)(C)C)c(O)c(C(C)(C)C)c2)c(C)c(Cc2cc(C(C)(C)C)c(O)c(C(C)(C)C)c2)c(C)c1Cc1cc(C(C)(C)C)c(O)c(C(C)(C)C)c1] |

Most preferred anti-radical agents are compounds of formula (1) as defined above where both G₁ and G₂ are tert-butyl, and wherein a=1. More preferably, radical agents are compounds of formula (1) as defined above where both G₁ and G₂ are tert-butyl, wherein a=1, and wherein V is O. Still more preferred anti-radical agents are compounds of formula (1) as defined above where both G₁ and G₂ are tert-butyl, wherein a=1, and wherein V is 0, and wherein e=1. An especially preferred compound is the compound of formula (23)

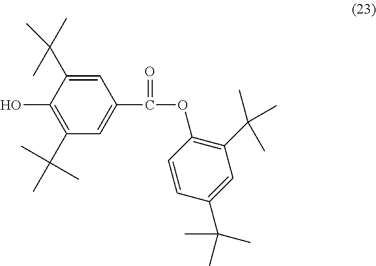 [SMILES: CC(C)(C)c1ccc(OC(=O)c2cc(C(C)(C)C)c(O)c(C(C)(C)C)c2)c(C(C)(C)C)c1]

which is known as commercially available Tinuvin® 120.

### The DPP Polymer

As far as the DPP polymer used as component of the photovoltaic layer according to the present invention is concerned, no specific restrictions exist with the proviso that the DPP polymer is suitable for use as semiconductor material in an OPV device.

Such DPP polymers are generally characterized in containing one or more DPP skeletons, as represented by the formula

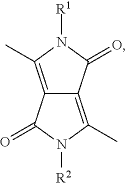

in the repeating unit, wherein R¹ and R² are the same or different from each other and are selected from the group consisting of hydrogen; a C₁-C₁₀₀ alkyl group; —COOR¹⁰⁶; a C₁-C₁₀₀ alkyl group which is substituted by one or more halogen atoms, hydroxyl groups, nitro groups, —CN, or C₆-C₁₈ aryl groups and/or interrupted by —O—, —COO—, —OCO—, or —S—; a C₇-C₁₀₀ arylalkyl group; a carbamoyl group; a C₅-C₁₂ cycloalkyl group which can be substituted one to three times with a C₁-C₈ alkyl group and/or a C₁-C₈ alkoxy group; a C₆-C₂₄ aryl group, in particular phenyl or 1- or 2-naphthyl which can be substituted one to three times with a C₁-C₈ alkyl group, a C₁-C₂₅ thioalkoxy group, and/or a C₁-C₂₅ alkoxy group; and pentafluorophenyl; with R¹⁰⁶ being a C₁-C₅₀ alkyl group, preferably a C₄-C₂₅ alkyl group.

Examples of DPP polymers and their synthesis are, for example, described in U.S. Pat. No. 6,451,459B1, WO05/049695, WO2008/000664, WO2010/049321, WO2010/049323, WO2010/108873, WO2010/115767, WO2010/136353, PCT/EP2011/060283, WO2010/136352; and especially PCT/EP2011/057878.

The DPP polymer usually stands for a polymer comprising at least one diketo-pyrrolopyrrole repeating unit of the formula

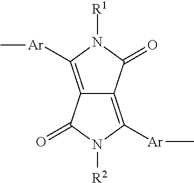

wherein
R¹ and R² independently are selected from hydrogen, a C₁-C₁₀₀alkyl group, such as a C₆-C₂₄alkyl group; said alkyl group which is substituted by one or more halogen atoms, hydroxyl groups, nitro groups, —CN, C₆-C₁₈aryl groups and/or is interrupted by —O—, —COO—, —OCO—, or —S—; COO—C₁-C₅₀alkyl; a C₇-C₁₀₀arylalkyl group; a carbamoyl group; C₅-C₁₂cycloalkyl which can be substituted one to three times with C₁-C₈alkyl and/or C₁-C₈alkoxy; C₆-C₂₄aryl, in particular phenyl or 1- or 2-naphthyl which can be substituted one to three times with C₁-C₈alkyl, C₁-C₈thioalkoxy, and/or C₁-C₈alkoxy, or pentafluorophenyl; and
Ar independently of each other are a group of formula

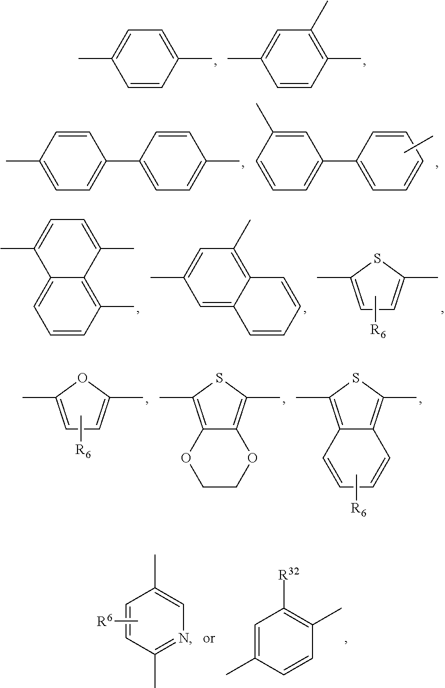

wherein
R⁶ is hydrogen, C₁-C₁₈alkyl, or C₁-C₁₈alkoxy, and R³² is methyl, Cl, or methoxy.
R¹ and R² preferably are optionally branched C₈-C₃₆alkyl groups in the DPP polymers used according to the invention. Further in the above formula, Ar independently stands for a divalent residue selected from 2,5-thienylene and 2,5-furylene, each of which may be unsubstituted or substituted by R³′, or for a divalent thiophene or thiazole moiety of the formula

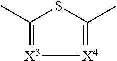

or for a divalent pyrrol moiety of the formula

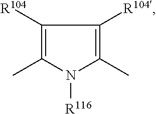

wherein one of X³ and X⁴ is N and the other is CH or CR^{3′}, and R³′ independently stands for halogen such as fluoro, or a C₁-C₂₅alkyl group, C₇-C₂₅arylalkyl, or C₁-C₂₅alkoxy, especially for a C₄-C₂₅alkyl group, which may optionally be interrupted by one or more oxygen or sulphur atoms;
R¹⁰⁴ and R^{104′} independently are hydrogen or are as defined for R³′; and
R¹¹⁶ is hydrogen, C₆-C₁₈aryl; C₆-C₁₈aryl which is substituted by C₁-C₁₈alkyl, C₁-C₁₈ perfluoroalkyl, or C₁-C₁₈alkoxy; C₁-C₂₅alkyl or COO—C₁-C₂₅alkyl each of which is unsubstituted or substituted in its alkyl part by CN, halogen, C₆-C₁₈aryl, and/or, in case that its alkyl part comprises 2 or more carbon atoms, may be interrupted by —CO—, —COO—, —CONR¹¹²—, —O—, —NR¹¹²—, or —S—; where R¹¹² is H; C₆-C₁₈aryl; C₆-C₁₈aryl which is substituted by C₁-C₁₈alkyl, or C₁-C₁₈alkoxy; C₁-C₁₈alkyl; or C₂-C₁₈alkyl which is interrupted by —O—.

A preferred class of DPP polymers for use in the present photovoltaic layers and for combination with the stabilizing agent in accordance with the present invention are those disclosed in the patent application No. PCT/EP2011/057878.

Thus, the DPP polymer used according to the present invention includes a polymer comprising one or more (repeating) unit(s) of the formula

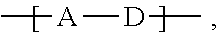

and at least one (repeating) unit(s) which is selected from repeating units of the formula

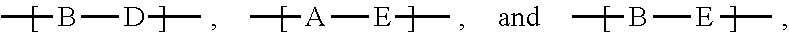

a polymer comprising one or more (repeating) unit(s) of the formula

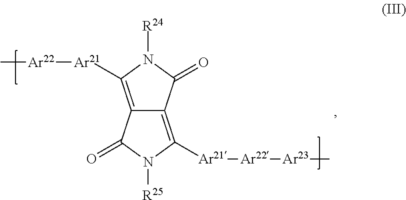

or a polymer comprising (repeating) unit(s) of the formula

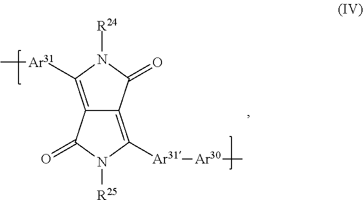

wherein
Ar²³ is a group of formula

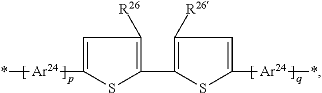

or —Ar²⁵—Ar²⁶—Ar²⁷Ar²⁸—Ar²⁹ₛ,
Ar³⁰ is a group of formula

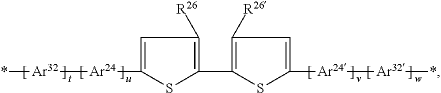

or Ar³⁸—Ar³³—Ar³⁴—Ar³⁵Ar³⁶—Ar³⁷_{y}Ar³⁹, wherein
R²⁶ and R^{26′} are independently of each other a C₄-C₁₈alkyl group, especially a C₄-C₁₈alkyl group,
A is a group of formula

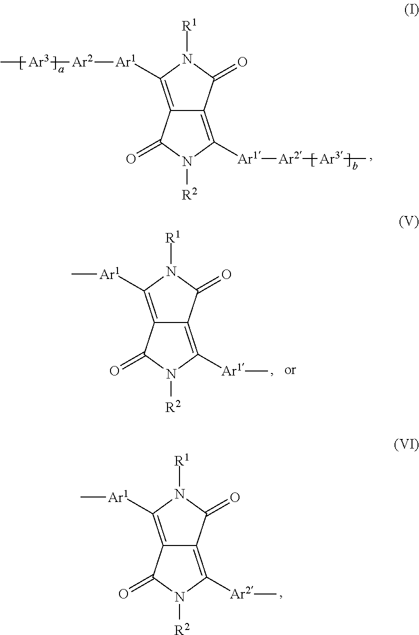

a is 0, or an integer of 1, or 2,
b is 0, or an integer of 1, or 2,
p is 0, or an integer of 1, or 2, y is 0, or 1,
q is 0, or an integer of 1, or 2, s is 0, or 1,
u is an integer of 1, or 2, t is 0, or 1,
v is an integer of 1, or 2, w is 0, or 1,
Ar²¹, Ar^{21′}, Ar²⁴, Ar^{24′}, Ar²⁵, Ar²⁷, Ar²⁹, Ar³¹, Ar^{31′}, Ar³⁸, Ar³⁴, Ar³⁶, Ar³⁹, Ar¹ and Ar¹ are independently of each other a group of formula

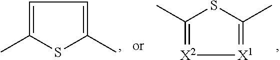

Ar³ and Ar^{3′} independently of each other have the meaning of Ar¹, or are a group of formula

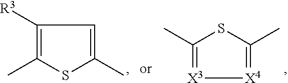

Ar², Ar^{2′}, Ar²⁶, Ar²⁸, Ar³³, Ar³⁵, Ar³⁷, Ar³², Ar^{32′}, Ar²² and Ar^{22′} are independently of each other a group of formula

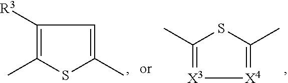

one of X¹ and X² is N and the other is CH,
one of X³ and X⁴ is N and the other is CR³′,
R¹, R², R²⁴ and R²⁵ may be the same or different and are selected from hydrogen, a C₁-C₁₀₀alkyl group, especially a C₆-C₂₄alkyl group, a C₆-C₂₄aryl, in particular phenyl or 1- or 2-naphthyl which can be substituted one to three times with C₁-C₈alkyl, C₁-C₈thioalkoxy, and/or C₁-C₈alkoxy, or pentafluorophenyl,
R³ and R^{3′} are independently of each other a C₁-C₂₅alkyl group, especially a C₄-C₂₅alkyl, which may optionally be interrupted by one or more oxygen atoms, and
B, D and E are independently of each other a group of formula *Ar₄ₖAr⁵ₗAr⁶ᵣAr⁷_{z}*,

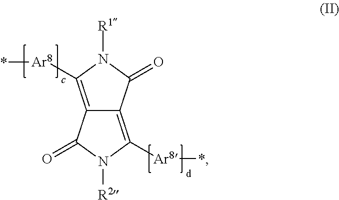

or formula (I), with the proviso that in case B, D and E are a group of formula (I), they are different from A, wherein
k is 1,
l is 0, or 1,
r is 0, or 1,
z is 0, or 1, and
Ar⁴, Ar⁵, Ar⁶ and Ar⁷ are independently of each other a group of formula

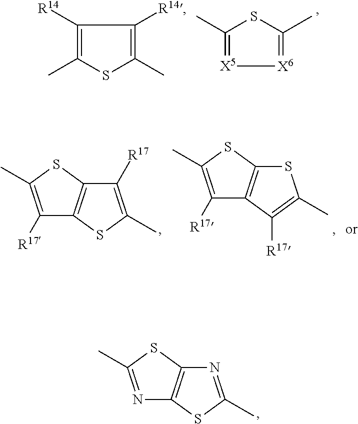

wherein
one of X⁵ and X⁶ is N and the other is CR¹⁴,
c is an integer of 1, 2, or 3,
d is an integer of 1, 2, or 3,
Ar⁸ and Ar^{8′} are independently of each other a group of formula

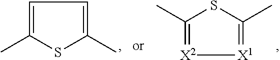

X¹ and X² are as defined above,
R^{1″} and R^{2″} may be the same or different and are selected from hydrogen, a C₁-C₃₆alkyl group, especially a C₆-C₂₄alkyl group, a C₆-C₂₄aryl, in particular phenyl or 1- or 2-naphthyl which can be substituted one to three times with C₁-C₈alkyl, C₁-C₈thioalkoxy, and/or C₁-C₈alkoxy, or pentafluorophenyl,
R¹⁴, R^{14′}, R¹⁷ and R^{17′} are independently of each other H, or a C₁-C₂₅alkyl group, especially a C₆-C₂₅alkyl, which may optionally be interrupted by one or more oxygen atoms.

The polymers of the present invention are preferably prepared (are obtainable) by (Suzuki) polymerisation of a dihalogenide, such as a dibromide or dichloride, especially a dibromide of formula Br-A-Br and Br—B—Br with an (equimolar) amount of a diboronic acid or diboronate of formula X¹¹DX¹¹, and optionally X¹¹EX¹¹, wherein X¹¹ is as defined below. Alternatively a diboronic acid or diboronate of formula X¹¹AX¹¹, and X¹¹bX¹¹, wherein X¹¹ is as defined below, is reacted with an (equimolar) amount of a dihalogenide, such as a dibromide or dichloride, especially a dibromide of formula Br-D-Br and optionally Br-E-Br

The polymers of the present invention are copolymers. A copolymer is a polymer derived from more than one species of monomer, e.g. bipolymer, terpolymer, quaterpolymer, etc.

The term polymer comprises oligomers as well as polymers. The oligomers of this invention have a weight average molecular weight of <4,000 Daltons. The polymers of this invention preferably have a weight average molecular weight of 4,000 Daltons or greater, especially 4,000 to 2,000,000 Daltons, more preferably 10,000 to 1,000,000 and most preferably 10,000 to 100,000 Daltons. Molecular weights are determined according to high-temperature gel permeation chromatography (HT-GPC) using polystyrene standards. The polymers of this invention preferably have a polydispersibility of 1.01 to 10, more preferably 1.1 to 3.0, most preferred 1.5 to 2.5. Polymers are more preferred than oligomers.

R¹ and R² can be hydrogen, but are preferably different from hydrogen.

R¹ and R² can be different, but are preferably the same. Preferably, R¹ and R² independently from each other stand for C₁-C₁₀₀alkyl, C₅-C₁₂cycloalkyl, which can be substituted one to three times with C₁-C₈alkyl and/or C₁-C₈alkoxy, phenyl or 1- or 2-naphthyl which can be substituted one to three times with C₁-C₈alkyl and/or C₁-C₈alkoxy, or —CR³⁰¹R³⁰²—(CH₂)ᵤ-A³, wherein R³⁰¹ and R³⁰² stand for hydrogen, or C₁-C₄alkyl, A³ stands for phenyl or 1- or 2-naphthyl, which can be substituted one to three times with C₁-C₈alkyl and/or C₁-C₈alkoxy, and u stands for 0, 1, 2 or 3. R¹ and R² are more preferably a C₁-C₃₆alkyl group, such as methyl, ethyl, n-propyl, isopropyl, n-butyl, sec.-butyl, isobutyl, tert.-butyl, n-pentyl, 2-pentyl, 3-pentyl, 2,2-dimethylpropyl, 1,1,3,3-tetramethylpentyl, n-hexyl, 1-methylhexyl, 1,1,3,3,5,5-hexamethylhexyl, n-heptyl, isoheptyl, 1,1,3,3-tetramethylbutyl, 1-methylheptyl, 3-methylheptyl, n-octyl, 1,1,3,3-tetramethylbutyl and 2-ethylhexyl, n-nonyl, decyl, undecyl, especially n-dodecyl, tridecyl, tetradecyl, pentadecyl, hexadecyl, 2-ethyl-hexyl, 2-butyl-hexyl, 2-butyl-octyl, 2-hexyldecyl, 2-decyl-tetradecyl, heptadecyl, octadecyl, eicosyl, heneicosyl, docosyl, or tetracosyl. In a particularly preferred embodiment of the present invention R¹ and R² are a 2-hexyldecyl, or 2-decyl-tetradecyl group.

Advantageously, the groups R¹ and R² can be represented by formula

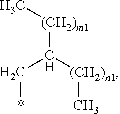

wherein m1=n1+2 and m1+n1≦24. Chiral side chains, such as R¹ and R², can either be homochiral, or racemic, which can influence the morphology of the polymers.

Ar²¹ and Ar^{21′}, Ar²⁴ and Ar^{24′}, Ar³¹ and Ar^{31′}, Ar⁸ and Ar^{8′}, Ar¹ and Ar^{1′} can be the same and can be different, but are preferably the same. Ar²¹, Ar^{21′}, Ar²⁴, Ar^{24′}, Ar²⁵, Ar²⁷, Ar²⁹, Ar³¹, Ar^{31′}, Ar³⁸, Ar³⁴, Ar³⁶, Ar³⁹, Ar⁸, Ar^{8′}, Ar¹ and Ar^{1′} can be a group of formula

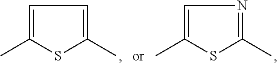

wherein a group of formula

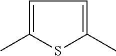

is preferred.

Ar³ and Ar^{3′} have preferably the meaning of Ar¹.

Ar² and Ar^{2′}, Ar³² and Ar^{32′}, Ar²² and Ar^{22′} can be the same and can be different, but are preferably the same. Ar², Ar^{2′}, Ar²⁶, Ar²⁸, Ar³³, Ar³⁵, Ar³⁷, Ar³², Ar^{32′}, Ar²² and Ar^{22′} can be a group of formula

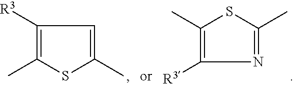

If a is equal to 2, Ar² can be composed of groups of formula

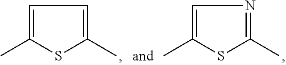

i.e. can, for example, be a group of formula

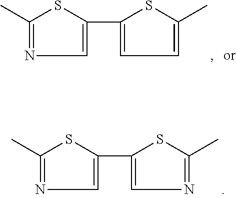

As indicated by the formula

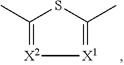

the group

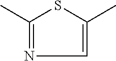

can be attached to the DPP basic unit, or arranged in the polymer chain in two ways

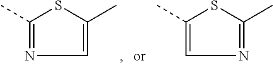

( - - - attachment to the DPP basic structure). The notation

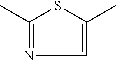

should comprise both possibilities.

The group

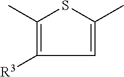

can be attached to the DPP basic unit, or arranged in the polymer chain in two ways

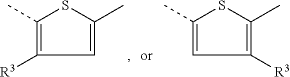

( - - - attachment to the DPP basic structure). The notation

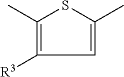

should comprise both possibilities.

The group

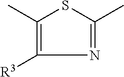

can be attached to the DPP basic unit, or arranged in the polymer chain in two ways

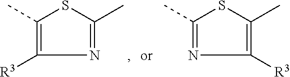

( - - - attachment to the DPP basic structure). The notation

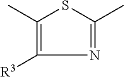

should comprise both possibilities.

R²⁴ and R²⁵, R¹ and R² can be different, but are preferably the same. R²⁴, R²⁵, R¹ and R² can be linear, but are preferably branched. R²⁴, R²⁵, R¹ and R² are preferably a C₈-C₃₆alkyl group, especially a C₁₂-C₂₄alkyl group, such as n-dodecyl, tridecyl, tetradecyl, pentadecyl, hexadecyl, 2-ethyl-hexyl, 2-butyl-hexyl, 2-butyl-octyl, 2-hexyldecyl, 2-decyl-tetradecyl, heptadecyl, octadecyl, eicosyl, heneicosyl, docosyl, or tetracosyl. The C₈-C₃₆alkyl and C₁₂-C₂₄alkyl group can be linear, or branched, but are preferably branched. In a particularly preferred embodiment of the present invention R²⁴, R²⁵, R¹ and R² are a 2-hexyldecyl or 2-decyl-tetradecyl group.

Advantageously, the groups R²⁴, R²⁵, R¹ and R² can be represented by formula

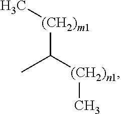

wherein m1=n1+4 and m1+n1≦22.

Chiral side chains, such as R²⁴, R²⁵, R¹ and R², can either be homochiral, or racemic, which can influence the morphology of the polymers.

R^{1″} and R^{2″} may be the same or different and are selected from hydrogen, a C₁-C₃₆alkyl group, especially a C₆-C₂₄alkyl group.

R³ and R³′ are independently of each other a C₁-C₂₅alkyl group. R³ and R^{3′} can be branched, but are preferably linear. R³ and R^{3′} are especially a linear C₄-C₂₅alkyl group, very especially n-hexyl.

If groups R¹⁵ and R³ are present in a polymer of the presence invention, they are preferably identical.

In addition, polymers are preferred, wherein at least 5 thiophenes are present between two DPP structures

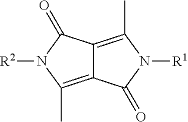

A is preferably a group of formula I, wherein Ar³ and Ar^{3′} have the meaning of Ar¹.

A is preferably a group of formula

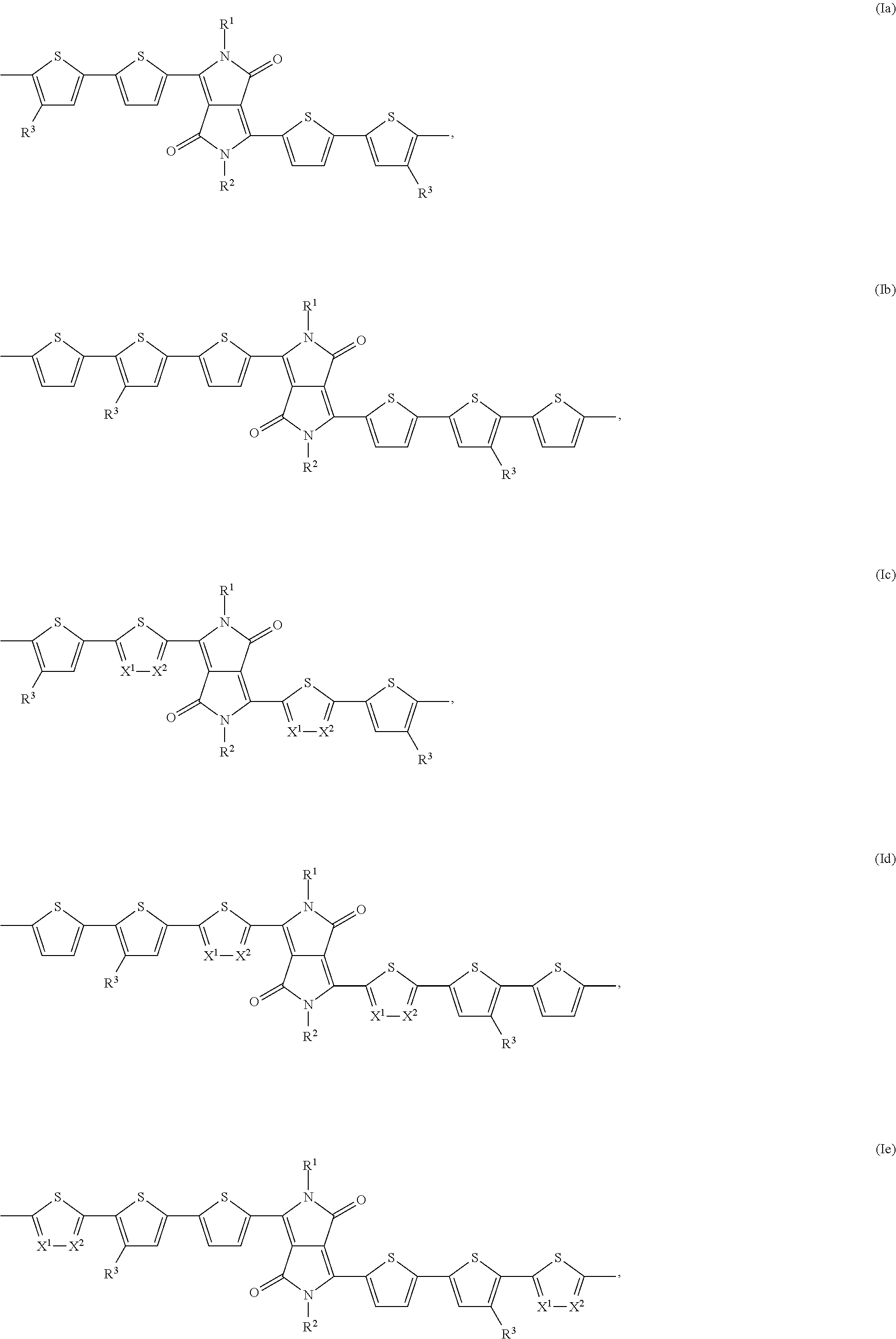

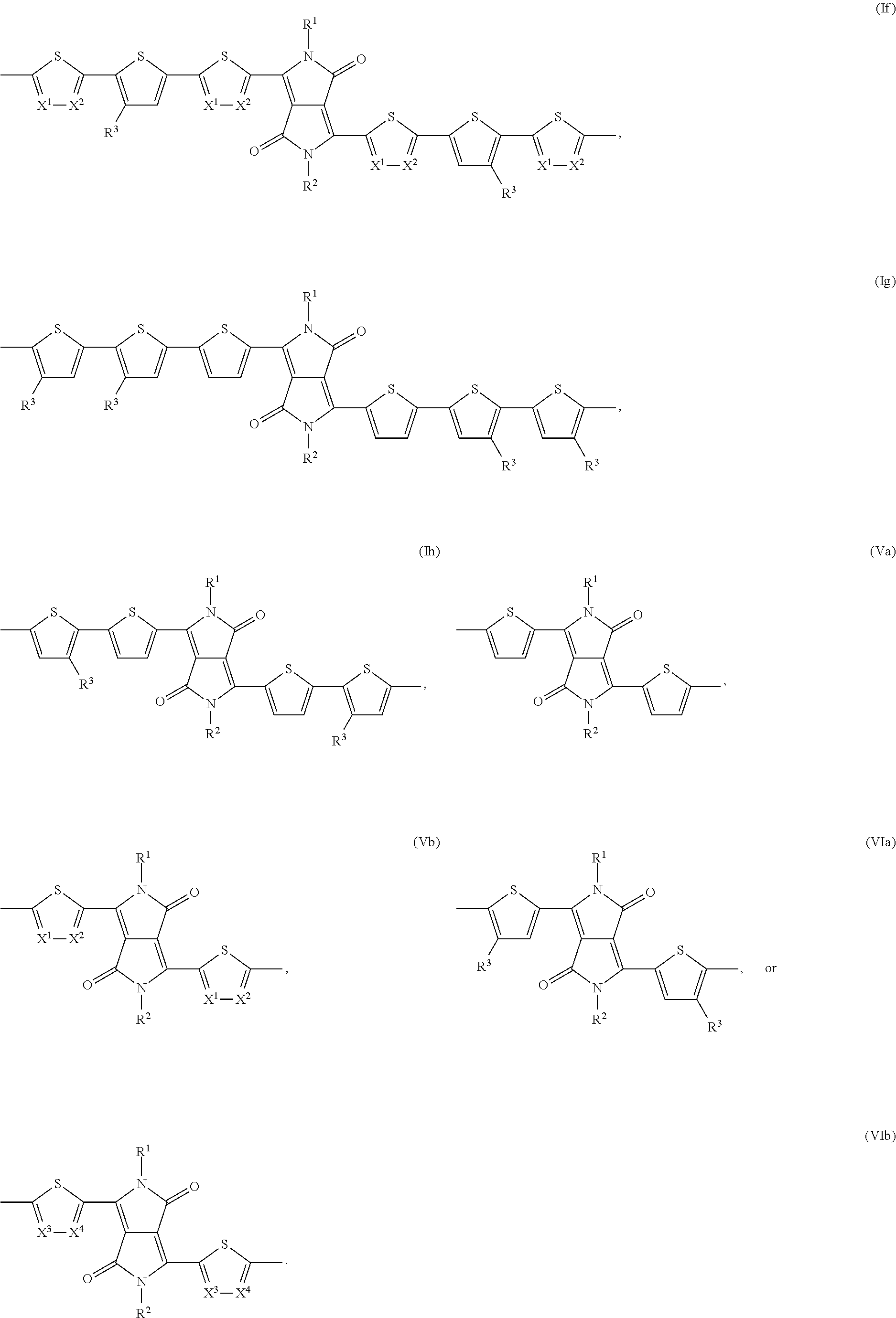

B, D and E are independently of each other a group of formula

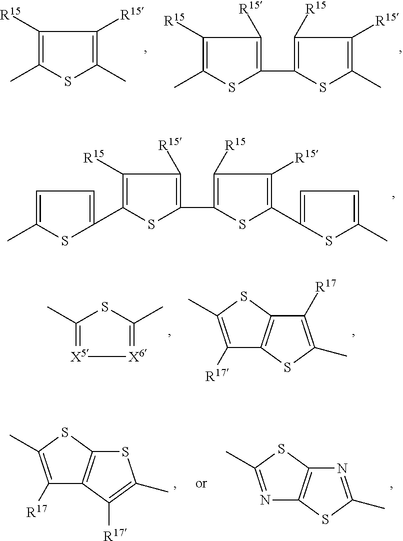

wherein one of X^{5′} and X^{6′} is N and the other is CR¹⁴, or CH,
R¹⁵, R^{15′}, R¹⁷ and R^{17′} are independently of each other H, or a C₁-C₂₅alkyl group, especially a C₆-C₂₅alkyl, which may optionally be interrupted by one or more oxygen atoms, and R¹⁴ is a C₁-C₂₅alkyl group, especially a C₆-C₂₅alkyl, which may optionally be interrupted by one or more oxygen atoms.

B, D and E are more preferably a group of formula

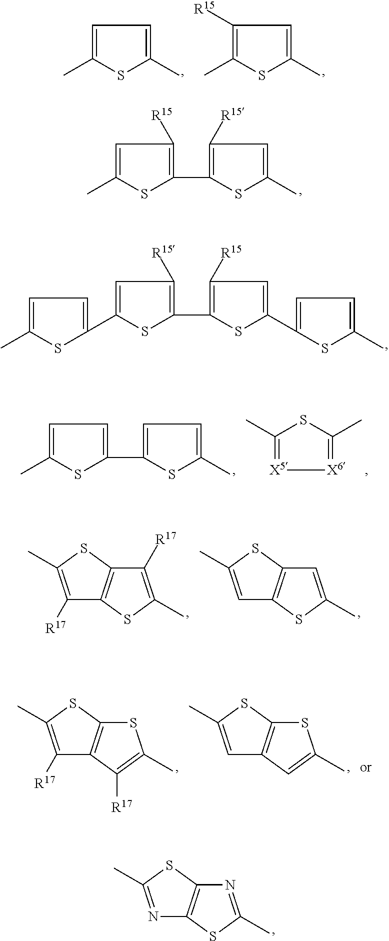

wherein one of X^{5′} and X^{6′} is N and the other is CR¹⁴, or CH, and
R¹⁴, R¹⁵, R^{15′} and R¹⁷ are independently of each other a C₆-C₂₅alkyl.

If B, D and E are a group of formula

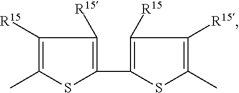

they are preferably a group of formula

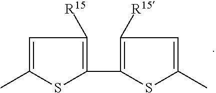

The head to tail arrangement of R¹⁵ is important to introduce more solubility.

B is preferably a group of formula

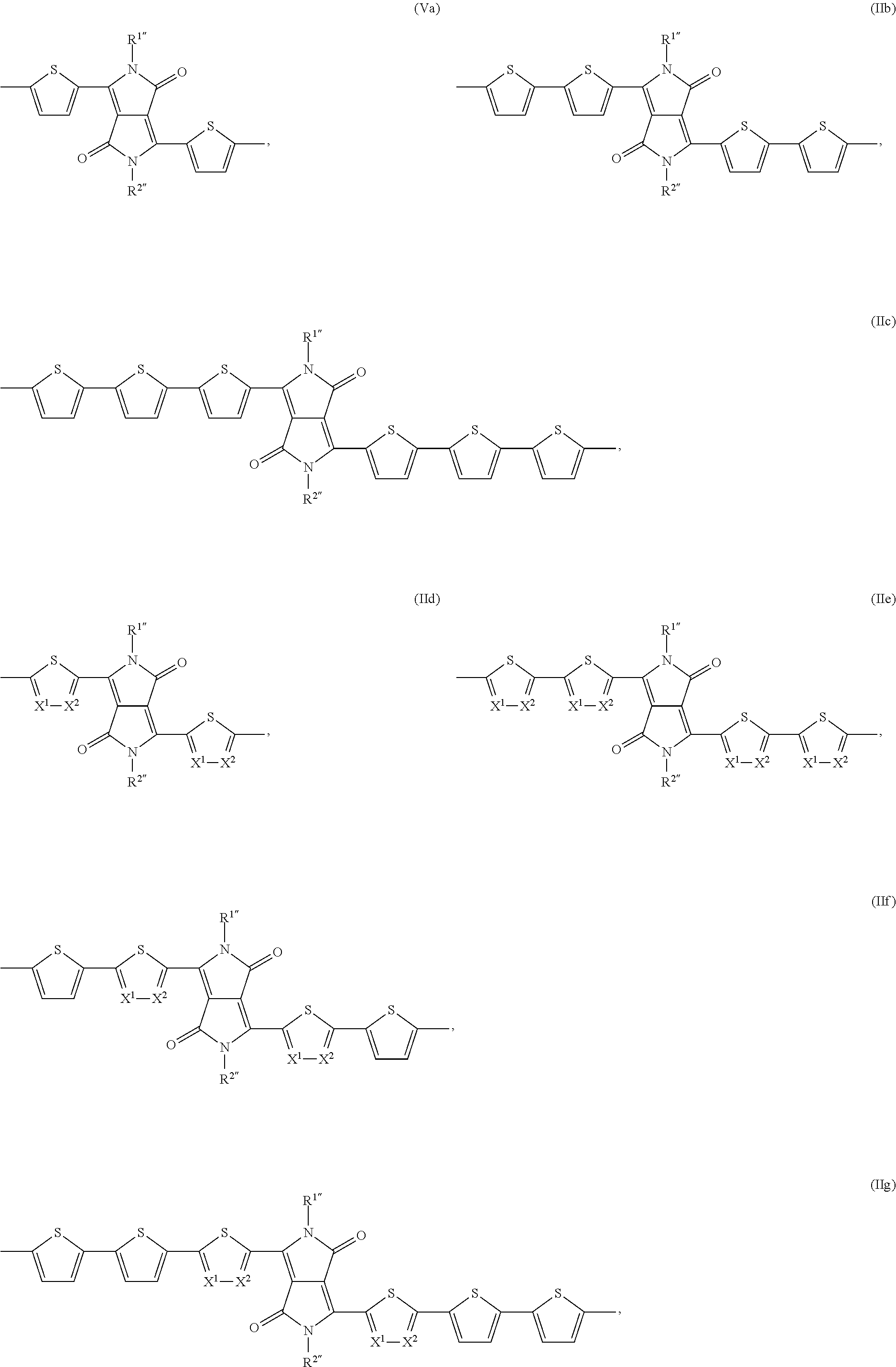

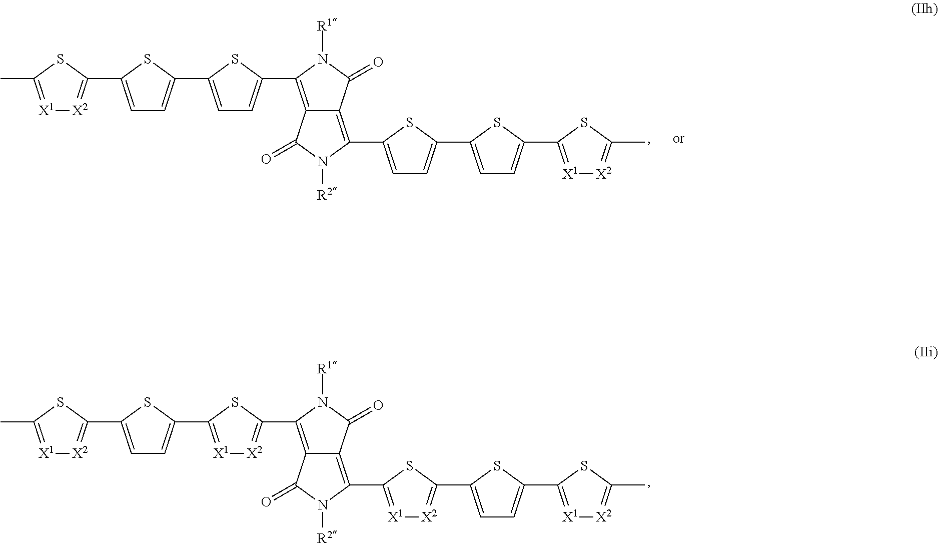

wherein
X¹, X², R^{1″} and R^{2″} are as defined above.

In another preferred embodiment B is a group of formula Ia, Ib, Ic, Id, Ie, If, Ig, or Ih, provided that B is different from A.

In a preferred embodiment of the present invention the polymers comprise repeating units of the formula *A-Dₓ*, and *B-D_{y}*, especially *A-DₓB-D_{y}*, wherein A is a group of formula

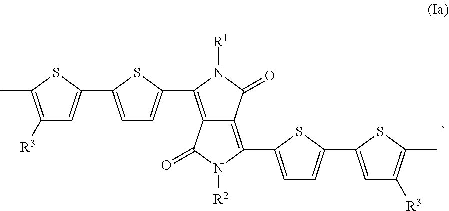

R¹ and R² are a C₈-C₃₅alkyl group,
R³ is a C₁-C₁₈alkyl group,

B is a group of formula

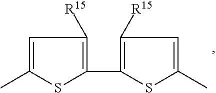

R¹⁵ is a C₄-C₁₈alkyl group,
D is a group of formula

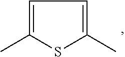

and
x=0.995 to 0.005, y=0.005 to 0.995, especially x=0.4 to 0.9, y=0.6 to 0.1, and wherein x+y=1.

In another preferred embodiment of the present invention the polymers comprise repeating units of the formula *A-Dₓ*, and *B-D_{y}*, especially *A-Dₓ*B-D_{y}*, wherein

A is a group of formula Ia, Ib, Ic, Id, Ie, If, Ig, or Ih,
R¹ and R² are a C₈-C₃₅alkyl group,
R³ is a C₄-C₁₈alkyl group, and
B is a group of formula Va, IIb, IIc, IId, IIe, IIf, IIg, IIh, or IIi, or a group of formula Ia, Ib, Ic, Id, Ie, If, or Ig, with the proviso that B is different from A,
R^{1″} and R^{2″} are a C₈-C₃₅alkyl group,
one of X¹ and X² is N and the other is CH,
D is a group of formula

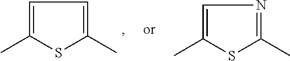

and
x=0.995 to 0.005, y=0.005 to 0.995, and wherein x+y=1.

If A is a group of formula I and B is a group of formula II x is preferably 0.2 to 0.8 and y is preferably 0.8 to 0.2. If A and B are both a group of formula II x is preferably 0.99 to 0.3 and y is preferably 0.01 to 0.7.

Even more preferably, the DPP polymer is a polymer comprising repeating units of the formula *A-Dₓ*and *B-D_{y}*,

wherein A is a group of formula

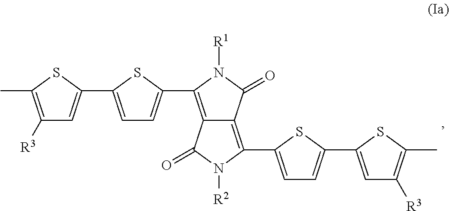

R¹ and R² are a C₈-C₃₅alkyl group,
R³ is a C₁-C₁₈alkyl group,
B is a group of formula

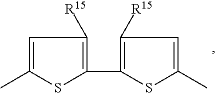

R¹⁵ is a C₄-C₁₈alkyl group,
D is a group of formula

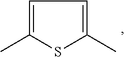

and
x=0.995 to 0.005, y=0.005 to 0.995, especially x=0.4 to 0.9, y=0.6 to 0.1, and wherein x+y=1.

Examples are polymers of the formulae

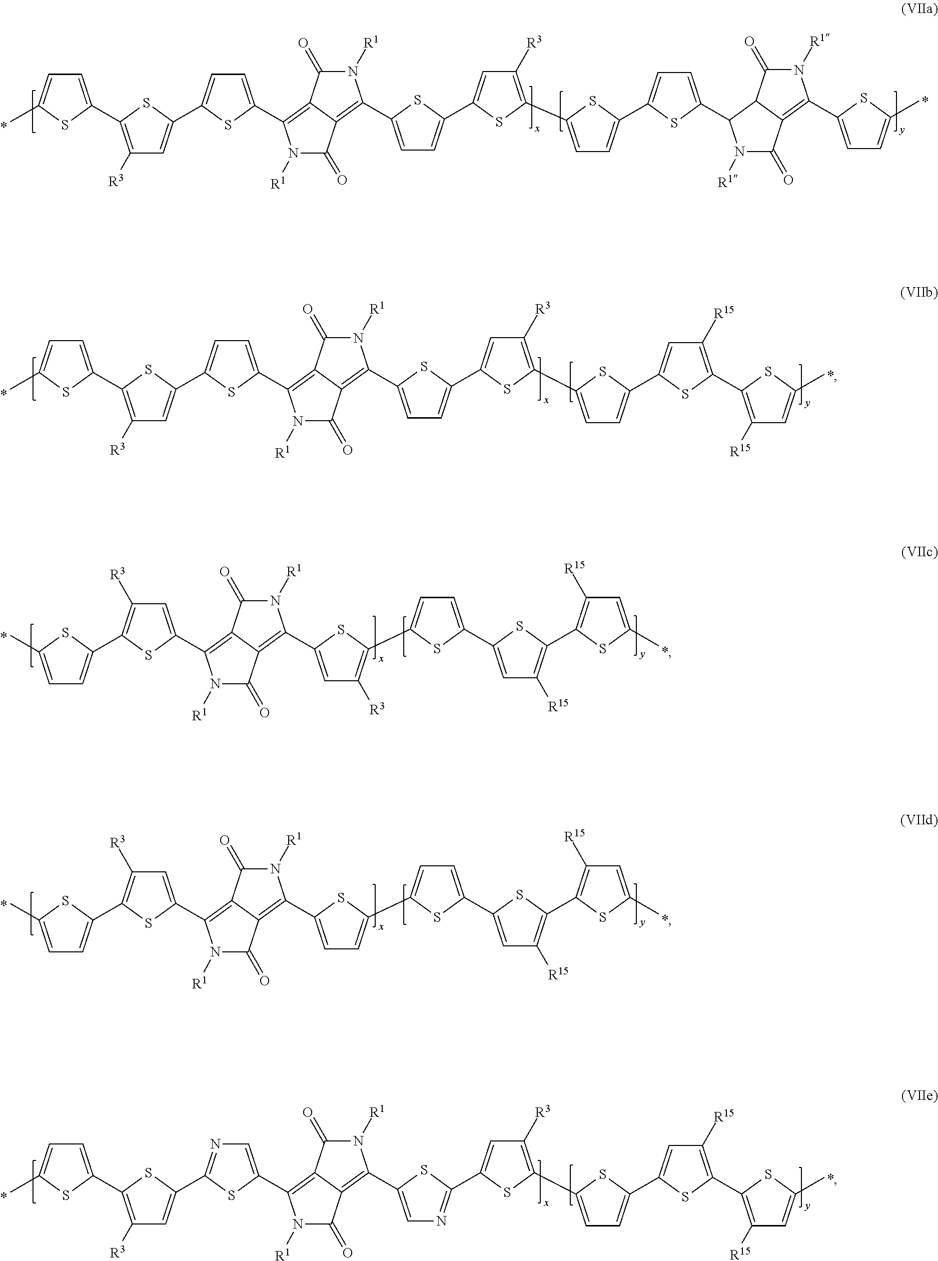

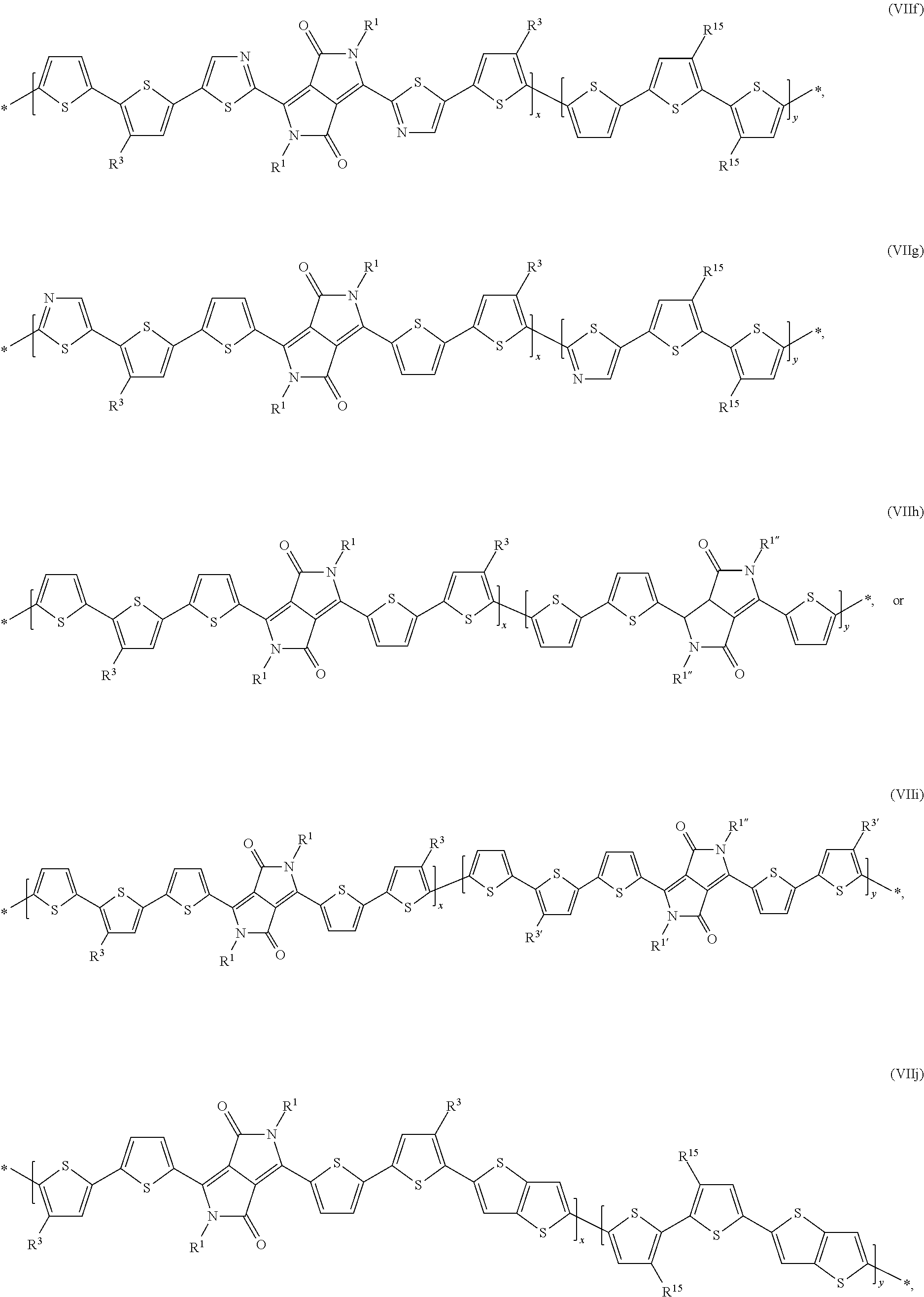

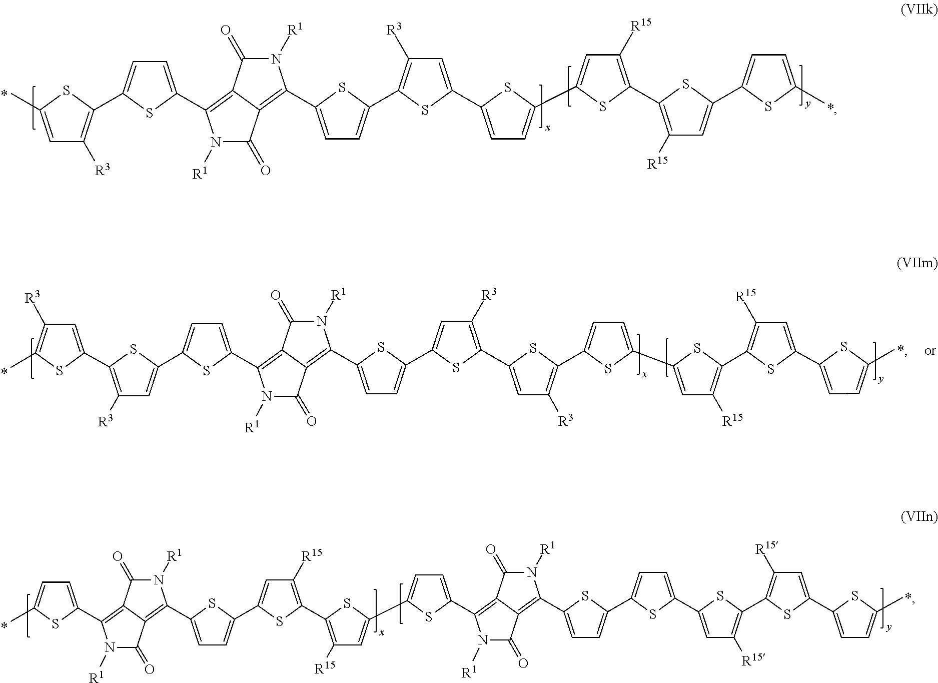

wherein R¹ and R^{1″} are a C₈-C₃₈alkyl group,
R¹⁵, R^{5′}, and R³ are a C₁-C₁₈alkyl group, especially a C₄-C₁₈alkyl group,
R^{1′} is C₈-C₃₆alkyl,
R^{3′} is C₁-C₁₈alkyl, especially a C₄-C₁₈alkyl group, R¹≠R^{1′} and/or R³≠R^{3′},
x is 0.005 to 0.995, preferably 0.01 to 0.99,
y is 0.995 to 0.005, preferably 0.99 to 0.01.

Preferred are polymers comprising (repeating) unit(s) of the formula *A-D* (I′),

or a polymer of formula *A-DₓB-D_{y}* (II′), or *A-DᵣB-DₛA-EₜB-Eᵤ (III′), wherein
x=0.995 to 0.005, y=0.005 to 0.995, especially x=0.2 to 0.8, y=0.8 to 0.2, and wherein x+y=1;
r=0.985 to 0.005, s=0.005 to 0.985, t=0.005 to 0.985, u=0.005 to 0.985, and wherein r+s+t+u=1;

A is a group of formula

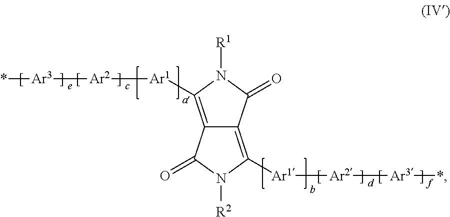

wherein
a′ is an integer of 1, or 2,
b is an integer of 1, or 2,
c is 0, or an integer of 1, or 2,
d is 0, or an integer of 1, or 2,
e is 0, or an integer of 1, or 2,
f is 0, or an integer of 1, or 2,
R¹ and R² may be the same or different and are selected from hydrogen, a C₁-C₁₀₀alkyl group, —COOR²⁰³, a C₁-C₁₀₀alkyl group which is substituted by one or more halogen atoms, hydroxyl groups, nitro groups, —CN, or C₆-C₁₈aryl groups and/or interrupted by —O—, —COO—, —OCO—, or —S—; a C₇-C₁₀₀arylalkyl group, a carbamoyl group, a C₅-C₁₂cycloalkyl group, which can be substituted one to three times with C₁-C₈alkyl and/or C₁-C₈alkoxy, a C₆-C₂₄aryl group, in particular phenyl or 1- or 2-naphthyl which can be substituted one to three times with C₁-C₈alkyl, C₁-C₈thioalkoxy, and/or C₁-C₈alkoxy, or pentafluorophenyl, R²⁰³ is C₁-C₅₀alkyl, especially C₄-C₂₅alkyl;
Ar¹ and Ar^{1′} are independently of each other

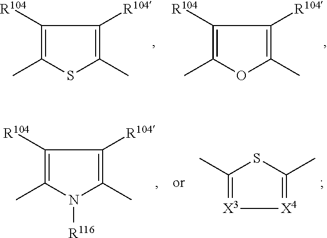

Ar², Ar^{2′}, Ar³ and Ar^{3′} are independently of each other

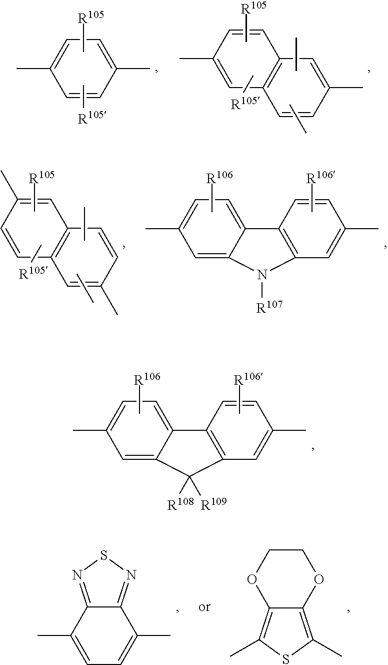

or have the meaning of Ar¹, wherein one of X³ and X⁴ is N and the other is CR⁹⁹,
R⁹⁹, R¹⁰⁴ and R^{104′} are independently of each other hydrogen, halogen, especially F, or a C₁-C₂₅alkyl group, especially a C₄-C₂₅alkyl, which may optionally be interrupted by one or more oxygen or sulphur atoms, C₇-C₂₅arylalkyl, or a C₁-C₂₅alkoxy group,
R¹⁰⁵, R^{105′}, R¹⁰⁶ and R^{106′} are independently of each other hydrogen, halogen, C₁-C₂₅alkyl, which may optionally be interrupted by one or more oxygen or sulphur atoms; C₇-C₂₅arylalkyl, or C₁-C₁₈alkoxy,
R¹⁰⁷ is C₇-C₂₅arylalkyl, C₆-C₁₈aryl; C₆-C₁₈aryl which is substituted by C₁-C₁₈alkyl, C₁-C₁₈ perfluoroalkyl, or C₁-C₁₈alkoxy; C₁-C₂₅alkyl; C₁-C₂₅alkyl which is interrupted by —O—, or —S—; or —COOR¹¹⁹;
R¹¹⁶ is hydrogen, C₇-C₂₅arylalkyl, C₆-C₁₈aryl; C₆-C₁₈aryl which is substituted by C₁-C₁₈alkyl, C₁-C₁₈ perfluoroalkyl, or C₁-C₁₈alkoxy; C₁-C₂₅alkyl; C₁-C₂₅alkyl which is interrupted by —O—, or —S—; or —COOR¹¹⁹;
R¹¹⁹ is C₁-C₂₅alkyl, C₁-C₂₅alkyl which is substituted by E′ and/or interrupted by D′, C₇-C₂₅arylalkyl, C₆-C₂₄aryl, C₆-C₂₄aryl which is substituted by G, or C₇-C₂₅aralkyl,
R¹⁰⁸ and R¹⁰⁹ are independently of each other H, C₁-C₂₅alkyl, C₁-C₂₅alkyl which is substituted by E′ and/or interrupted by D′, C₇-C₂₅arylalkyl, C₆-C₂₄aryl, C₆-C₂₄aryl which is substituted by G, C₂-C₂₀heteroaryl, C₂-C₂₀heteroaryl which is substituted by G, C₂-C₁₈alkenyl, C₂-C₁₈alkynyl, C₁-C₁₈alkoxy, C₁-C₁₈alkoxy which is substituted by E′ and/or interrupted by D′, or C₇-C₂₅aralkyl, or
R¹⁰⁸ and R¹⁰⁹ together form a group of formula ═CR¹¹⁰R¹¹¹, wherein
R¹¹⁰ and R¹¹¹ are independently of each other H, C₁-C₁₈alkyl, C₁-C₁₈alkyl which is substituted by E′ and/or interrupted by D′, C₆-C₂₄aryl, C₆-C₂₄aryl which is substituted by G, or C₂-C₂₀heteroaryl, or C₂-C₂₀heteroaryl which is substituted by G, or
R¹⁰⁸ and R¹⁰⁹ together form a five or six membered ring, which optionally can be substituted by C₁-C₁₈alkyl, C₁-C₁₈alkyl which is substituted by E′ and/or interrupted by D′, C₆-C₂₄aryl, C₆-C₂₄aryl which is substituted by G, C₂-C₂₀heteroaryl, C₂-C₂₀heteroaryl which is substituted by G, C₂-C₁₈alkenyl, C₂-C₁₈alkynyl, C₁-C₁₈alkoxy, C₁-C₁₈alkoxy which is substituted by E′ and/or interrupted by D′, or C₇-C₂₅aralkyl,

### D′ is —CO—, —COO—, —S—, —O—, or —NR¹¹²—,

E′ is C₁-C₈thioalkoxy, C₁-C₈alkoxy, CN, —NR¹¹²R¹¹³, —CONR¹¹²R¹¹³, or halogen,
G is E′, or C₁-C₁₈alkyl, and
R¹¹² and R¹¹³ are independently of each other H; C₆-C₁₈aryl; C₆-C₁₈aryl which is substituted by C₁-C₁₈alkyl, or C₁-C₁₈alkoxy; C₁-C₁₈alkyl; or C₁-C₁₈alkyl which is interrupted by —O—,
B, D and E are independently of each other a group of formula

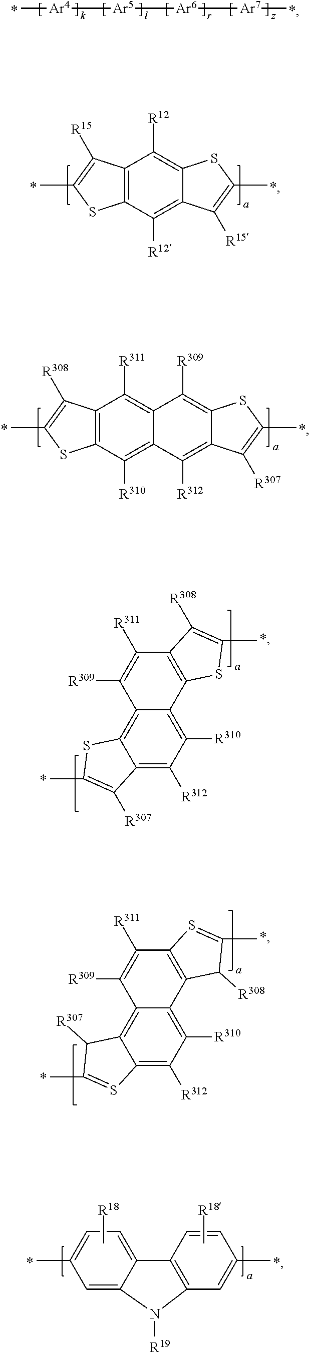

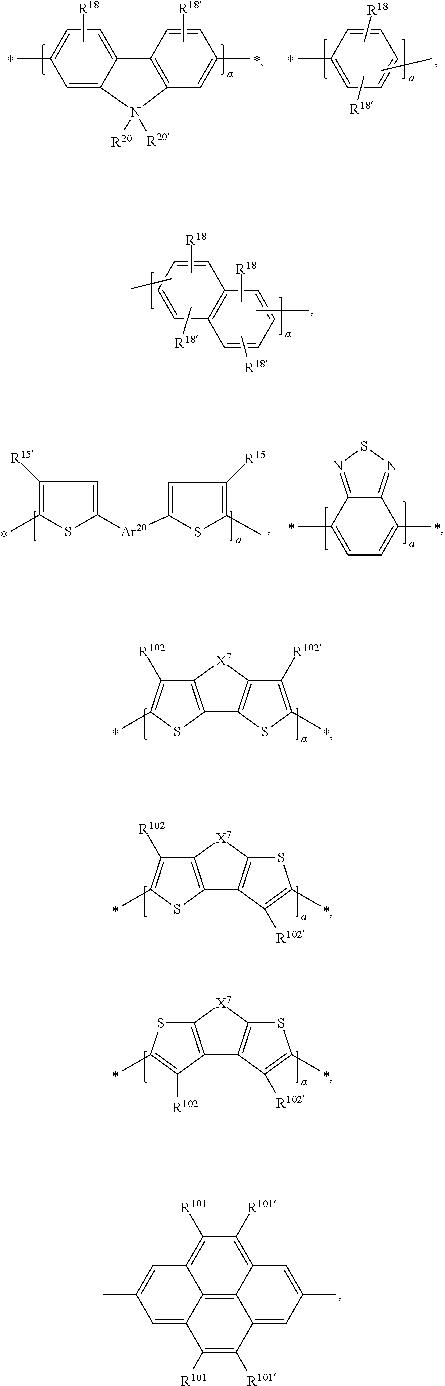

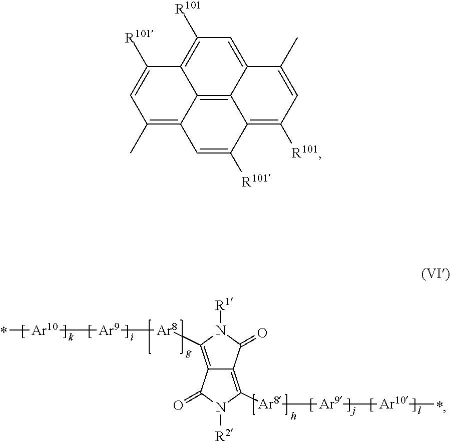

or formula IV′, with the proviso that in case B, D and E are a group of formula IV, they are different from A, wherein
k is 1,
l is 0, or 1,
r is 0, or 1,
z is 0, or 1,
a is an integer of 1 to 5, especially 1 to 3,
g is an integer of 1, or 2,
h is an integer of 1, or 2,
i is 0, or an integer of 1, or 2,
j is 0, or an integer of 1, or 2,
k is 0, or an integer of 1, or 2,
l is 0, or an integer of 1, or 2,
R^{1′} and R^{2′} have independently of each other the meaning of R¹,
Ar⁸, Ar^{8′}, Ar⁹, Ar^{9′}, Ar¹⁰ and Ar^{10′} have independently of each other the meaning of Ar²,
Ar⁴, Ar⁵, Ar⁶ and Ar⁷ are independently of each other a group of formula

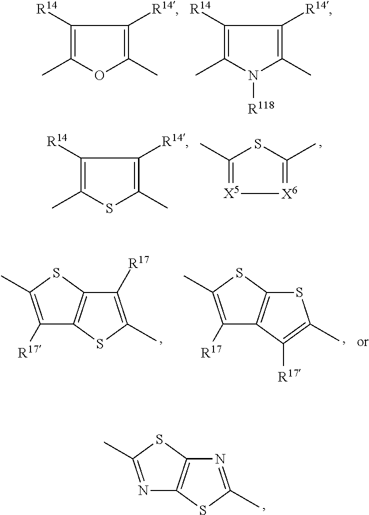

wherein one of X⁵ and X⁶ is N and the other is CR¹⁴,
Ar²⁰ is an arylene group, or a heteroarylene group, each of which may optionally be substituted,
R¹¹⁸ has the meaning of R¹¹⁶
R¹² and R^{12′} are independently of each other hydrogen, halogen, C₁-C₂₅alkyl, especially C₄-C₂₅alkyl, which may optionally be interrupted by one, or more oxygen, or sulphur atoms, C1-C₂₅alkoxy, C₇-C₂₅arylalkyl, or [symbol] ,
R¹³ is a C₁-C₁₀alkyl group, or a tri(C₁-C₈alkyl)silyl group,
R¹⁴, R^{14′}, R¹⁵, R^{15′} R¹⁷ and R^{17′} are independently of each other H, or a C₁-C₂₅alkyl group, especially a C₆-C₂₅alkyl, which may optionally be interrupted by one or more oxygen atoms;
R¹⁸ and R^{18′} independently of each other hydrogen, halogen, C₁-C₂₅alkyl, especially C₄-C₂₅alkyl, which may optionally be interrupted by one or more oxygen or sulphur atoms, C₇-C₂₅aralkyl, or C₁-C₂₅alkoxy;
R¹⁹ is hydrogen, C₇-C₂₅aralkyl, C₆-C₁₈aryl; C₆-C₁₈aryl which is substituted by C₁-C₁₈alkyl, or C₁-C₁₈alkoxy; or C₁-C₂₅alkyl, especially C₄-C₂₅alkyl, which may optionally be interrupted by one or more oxygen or sulphur atoms;
R²⁰ and R^{20′} are independently of each other hydrogen, C₇-C₂₅aralkyl, C₁-C₂₅alkyl, especially C₄-C₂₅alkyl, which may optionally be interrupted by one, or more oxygen, or sulphur atoms,

### X⁷ is —O—, —S—, —NR¹¹⁵—, —Si(R¹¹⁷)(R^{117′})—, —C(R¹²⁰)(R^{120′})—, —C(═O)—,

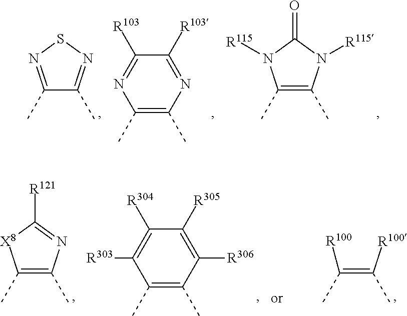

### X⁸ is —O—, or —NR¹⁵—;

R¹⁰⁰ and R^{100′} are independently of each other H, F, C₁-C₁₈alkyl, C₁-C₁₈alkyl which is interrupted by O, C₁-C₁₈alkoxy, C₁-C₁₈alkoxy which is interrupted by O, C₁-C₁₈ perfluoroalkyl, C₆-C₂₄aryl, which may optionally be substituted one to three times with C₁-C₈alkyl and/or C₁-C₈alkoxy, C₂-C₂₀heteroaryl, which may optionally be substituted one to three times with C₁-C₈alkyl and/or C₁-C₈alkoxy;
R³⁰³, R³⁰⁴, R³⁰⁵ and R³⁰⁶ are independently of each other H, F, C₁-C₁₈alkyl, C₁-C₁₈alkyl which is interrupted by O, C₁-C₁₈alkoxy, C₁-C₁₈alkoxy which is interrupted by O, C₁-C₁₈ perfluoroalkyl, C₆-C₂₄aryl, which may optionally be substituted one to three times with C₁-C₈alkyl and/or C₁-C₈alkoxy, C₂-C₂₀heteroaryl, which may optionally be substituted one to three times with C₁-C₈alkyl and/or C₁-C₈alkoxy;
R³⁰⁷ and R³⁰⁸ are independently of each other H, or C₁-C₂₅alkyl, which may optionally be interrupted by one or more oxygen or sulphur atoms;
R³⁰⁹, R³¹⁰, R³¹¹ and R³¹² are independently of each other H, C₁-C₂₅alkoxy, or C₁-C₂₅alkyl, which may optionally be interrupted by one or more oxygen or sulphur atoms;
R¹⁰¹ and R^{11′} are independently of each other H, F, C₁-C₁₈alkyl, C₁-C₁₈alkyl which is interrupted by O, C₁-C₁₈alkoxy, C₁-C₁₈alkoxy which is interrupted by O, C₁-C₁₈ perfluoroalkyl, C₆-C₂₄aryl, which may optionally be substituted one to three times with C₁-C₈alkyl and/or C₁-C₈alkoxy, C₂-C₂₀heteroaryl, which may optionally be substituted one to three times with C₁-C₈alkyl and/or C₁-C₈alkoxy;
R¹⁰² and R^{102′} are independently of each other H, halogen, C₁-C₂₅alkyl, which may optionally be interrupted by one or more oxygen or sulphur atoms; C₇-C₂₅arylalkyl, or C₁-C₂₅alkoxy;
R¹⁰³ and R^{103′} are independently of each other hydrogen, halogen, C₁-C₂₅alkyl, which may optionally be interrupted by one or more oxygen or sulphur atoms; C₆-C₂₄aryl, which may optionally be substituted one to three times with C₁-C₈alkyl and/or C₁-C₈alkoxy; C₇-C₂₅arylalkyl, CN, or C₁-C₂₅alkoxy; or
R¹⁰³ and R^{103′} together form a ring,
R¹¹⁵ and R^{115′} are independently of each other hydrogen, C₆-C₁₈aryl; C₆-C₁₈aryl which is substituted by C₁-C₁₈alkyl, or C₁-C₁₈alkoxy; C₁-C₂₅alkyl, especially C₄-C₂₅alkyl, which may optionally be interrupted by one or more oxygen or sulphur atoms; or C₇-C₂₅arylalkyl,
R¹¹⁷ and R^{117′} are independently of each other C₁-C₃₅alkyl group, C₇-C₂₅arylalkyl, or a phenyl group, which optionally can be substituted one to three times with C₁-C₈alkyl and/or C₁-C₈alkoxy,
R¹²⁰ and R^{120′} are independently of each other hydrogen, C₁-C₃₅alkyl, which may optionally be interrupted by one, or more oxygen, or sulphur atoms; or C₇-C₂₅arylalkyl,
R¹²¹ is H, C₁-C₁₈alkyl, which may optionally be interrupted by one or more oxygen or sulphur atoms, C₁-C₁₈ perfluoroalkyl, C₆-C₂₄aryl, which may optionally be substituted one to three times with C₁-C₈alkyl and/or C₁-C₈alkoxy; C₂-C₂₀heteroaryl, which may optionally be substituted one to three times with C₁-C₈alkyl and/or C₁-C₈alkoxy; or CN,
with the proviso that at least one of the groups Ar¹, Ar^{1′}, Ar², Ar^{2′}, Ar³ and Ar^{3′} is a group

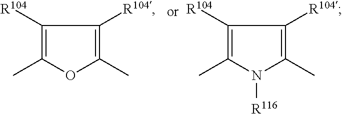

and/or at least one of the groups B, D and E contain a group

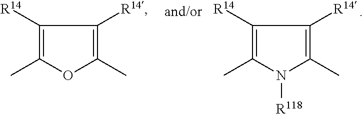

Polymers containing groups

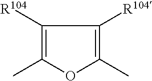

are preferred against polymers containing groups

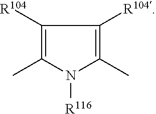

If groups

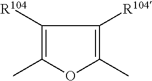

are directly bonded to the DPP skeleton the following preferences apply:

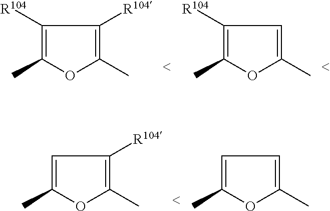

( [symbol] represents the bond to the DPP skeleton). That is, the group

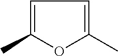

is most preferred.

If the polymer comprises (repeating) unit(s) of the formula *A-D* (I′), wherein A is a group of formula

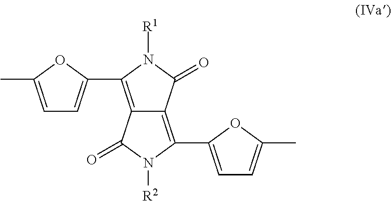

and D is a group of formula

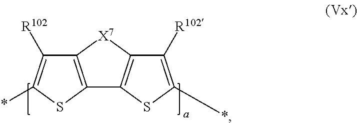

X⁷ is preferably different from —S—, and —C(R¹²⁰)(R^{120′})—.

In case of a group of formula

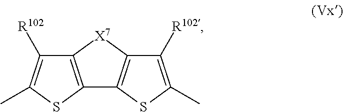

X⁷ is preferably —O—, —NR¹¹⁵—, —Si(R¹¹⁷)(R^{117′})—, —C(═O)—,

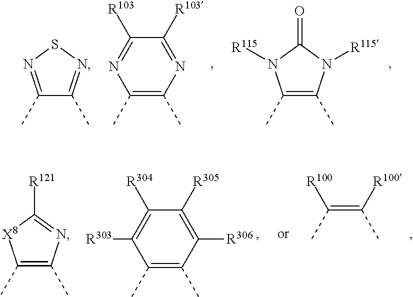

more preferably —C(R¹²⁰)(R^{120′})—,

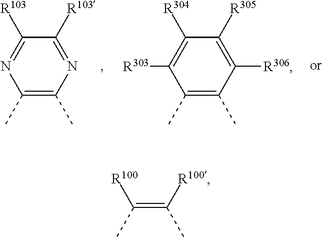

and most preferably a group of formula

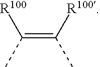

In case of groups of formula (Vy′) and (Vz′), X⁷ is preferably —O—, —S—, —NR¹¹⁵—, —C(R¹²⁰)(R^{120′})—, —Si(R¹¹⁷)(R^{117′})—, —C(═O)—,

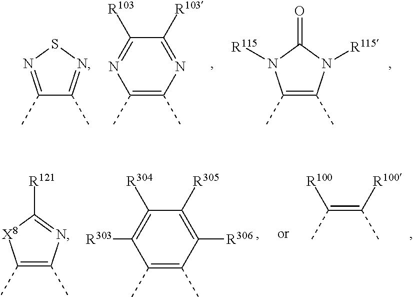

more preferably —C(R¹²⁰)(R^{120′})—,

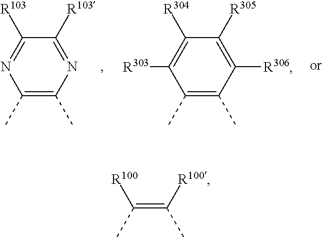

and most preferably a group of formula

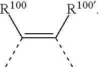

Further preferred according to the present invention are DPP polymers wherein R¹ and R² are an optionally branched C₈-C₃₆alkyl group.

In the DPP polymers to be used in the invention, preferably the aryl moiety in direct vicinity to the DPP skeleton (i.e. Ar¹ or Ar¹ and Ar^{1′}, in the above formulae) are independently of each other

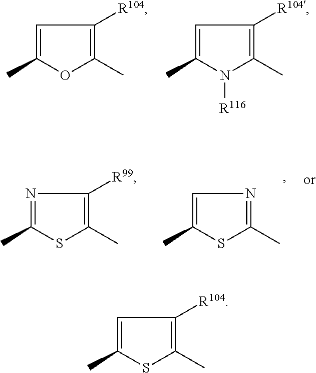

More preferably, Ar¹ or Ar¹ and Ar^{1′}, are independently of each other

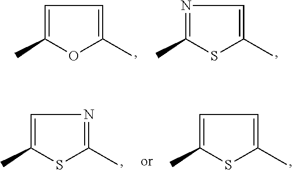

wherein

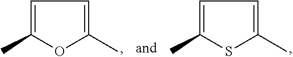

and are most preferred ( [symbol] represents the bond to the DPP skeleton). Ar groups such as Ar¹ and Ar^{1′} can be different, but are preferably the same.

In a preferred embodiment the present invention is directed to polymers, wherein Ar¹ and Ar^{1′} are independently of each other

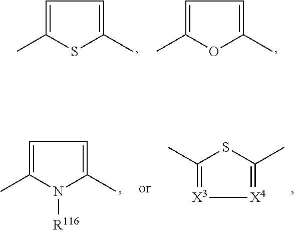

wherein X³ is CH and X⁴ is N, or X³ is N and X⁴ is CH, and R¹¹⁶ is as defined above. R¹¹⁶ is preferably different from H.

In the preferred DPP polymers of formulae (I′), (II′) and (III′), A is preferably a group of formula

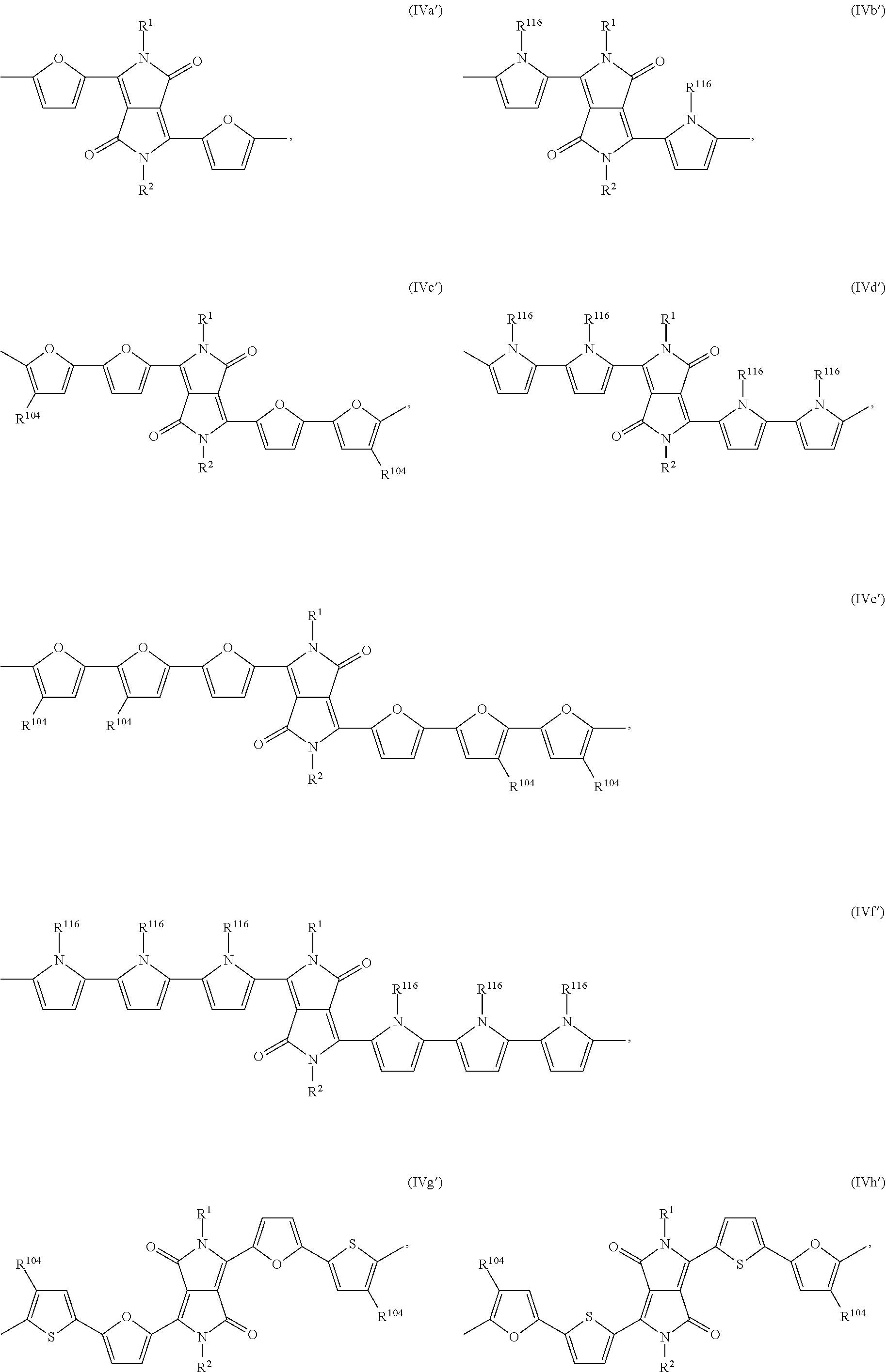

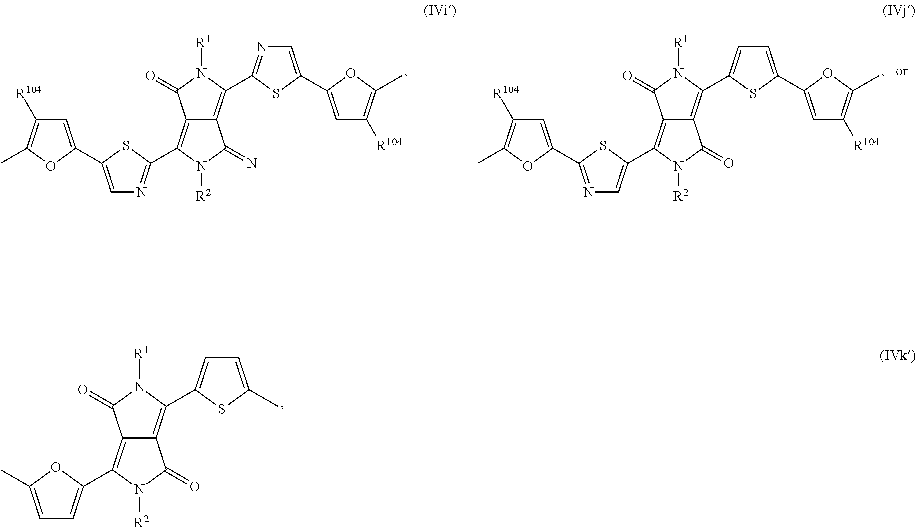

wherein R¹ and R² are independently of each other a C₁-C₃₆alkyl group, especially a C₈-C₃₆alkyl group,
R¹⁰⁴ is a C₁-C₂₅alkyl group, especially a C₄-C₂₅alkyl, which may optionally be interrupted by one or more oxygen or sulphur atoms, and
R¹¹⁶ is H, or C₁-C₂₅alkyl; or C₁-C₂₅alkyl which is interrupted by —O—, or —S—.

A is more preferably a group of formula IVa′, IVc′, IVe′, IVg′, IVh′, IVi′ and IVk′. Groups of formula IVa′, IVc′, IVe′, IVg′, IVh′ and IVi′ are especially preferred.

In the preferred DPP polymers of formula (I′), (II′) and (III′), B, D and E are independently of each other a group of formula

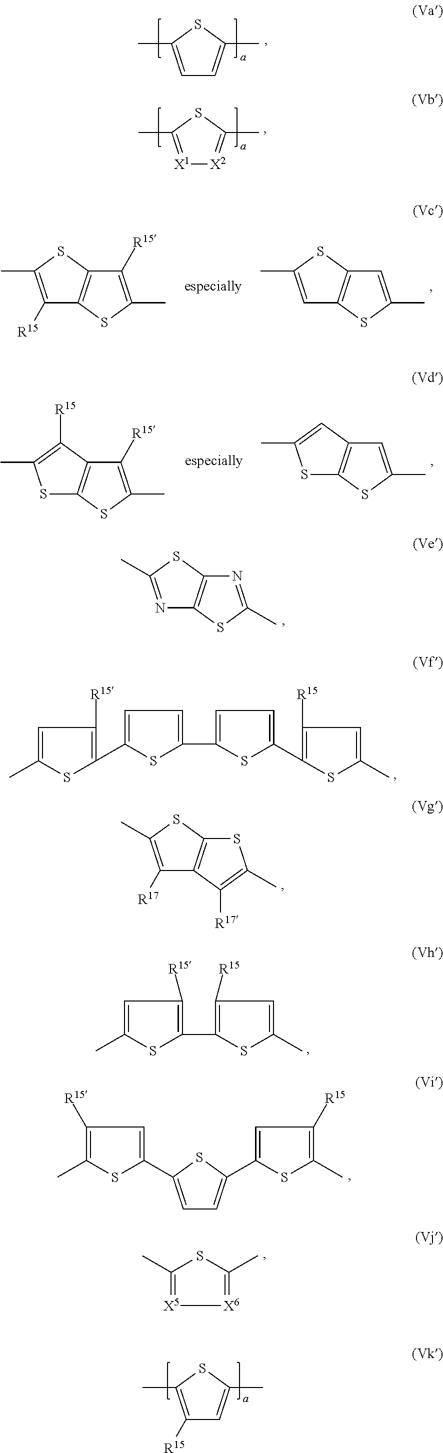

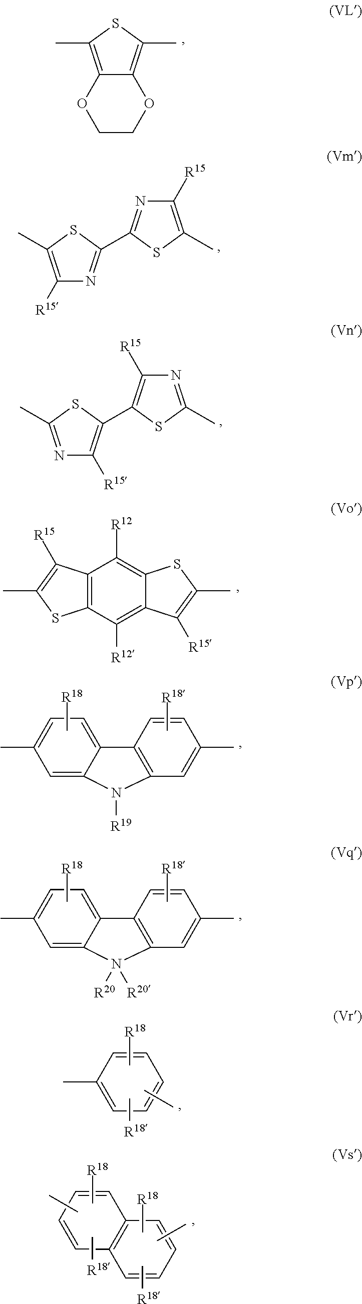

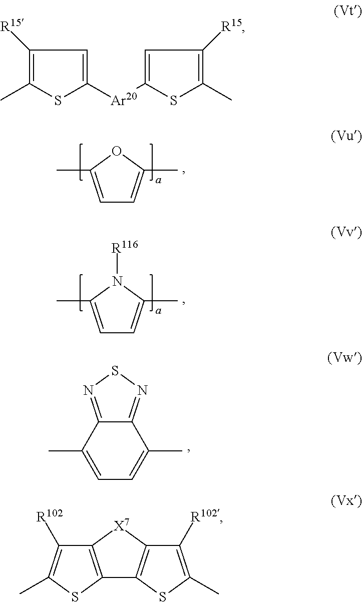

such as, for example,

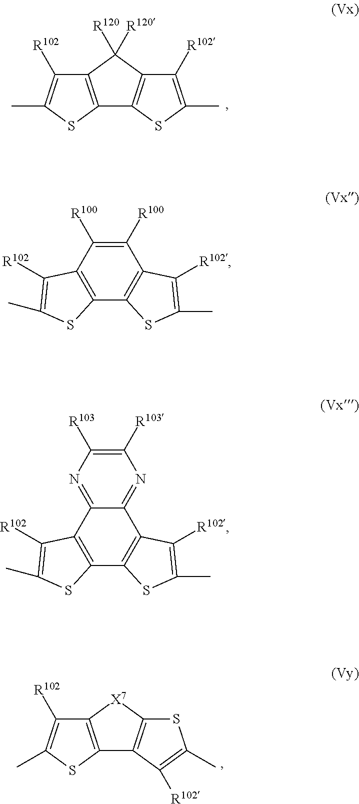

such as, for example,

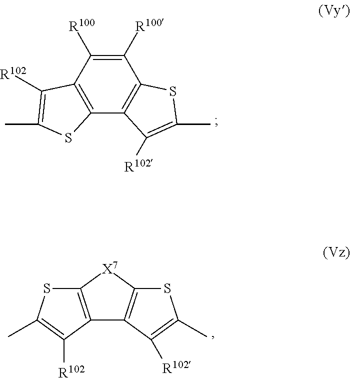

such as, for example,

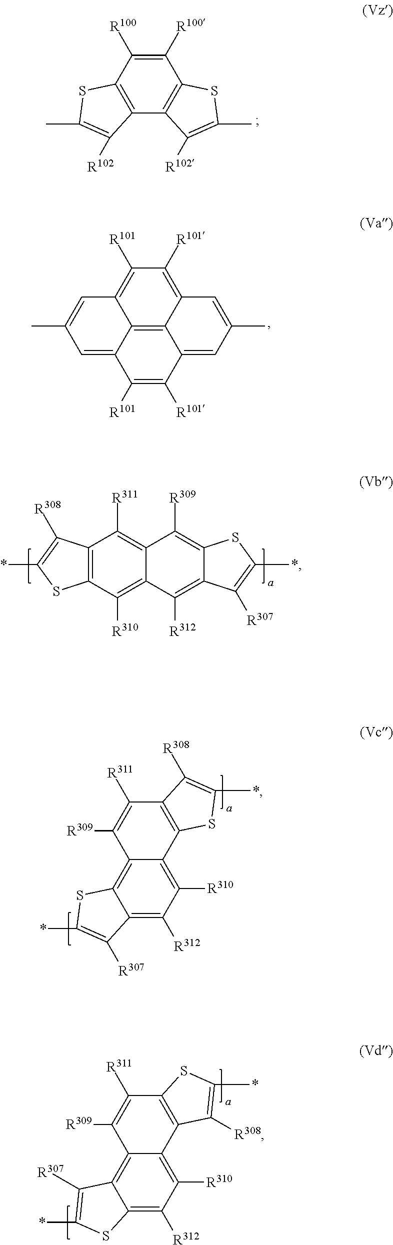

wherein

### X⁷ is —C(R¹²⁰)(R^{120′})—,

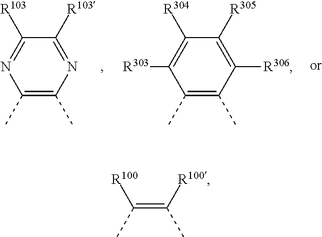

R³⁰³, R³⁰⁴, R³⁰⁵, R³⁰⁶, R³⁰⁷, R³⁰⁸, R³⁰⁹, R³¹⁰, R³¹¹, R³¹², R¹⁰⁰, R^{100′}, R¹⁰¹, R^{101′}, R¹⁰², R^{102′}, R¹⁰³, R^{103′},
R¹²⁰ and R^{120′} are as defined in claim 1,
a is an integer of 1 to 5, especially 1 to 3,
one of X¹ and X² is N and the other is CH,
one of X⁵ and X⁶ is N and the other is CR¹⁴,
Ar²⁰ is an arylene group, which may optionally be substituted, such as

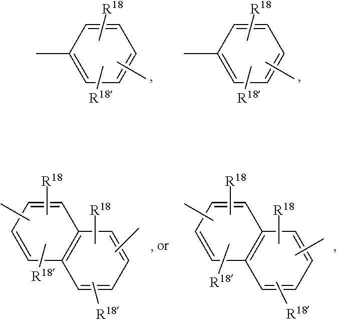

or a heteroarylene group, which may optionally be substituted, such as

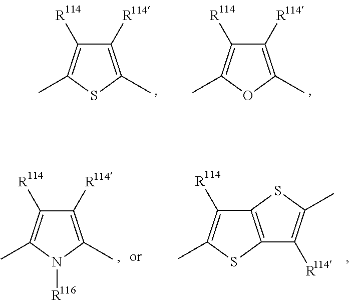

R¹¹⁴ and R^{114′} are independently of each other hydrogen, or C₁-C₁₈alkyl,
R¹¹⁶ is H, or C₁-C₂₅alkyl, R¹¹⁷ is C₁-C₂₅alkyl,
R¹² and R^{12′} are independently of each other hydrogen, halogen, C₁-C₂₅alkyl, especially C₄-C₂₅alkyl, which may optionally be interrupted by one, or more oxygen, or sulphur atoms, C1C₂₅alkoxy, C₇-C₂₅arylalkyl, or [symbol] ,
R¹³ is a C₁-C₁₀alkyl group, or a tri(C₁-C₈alkyl)silyl group,
R¹⁵, R^{15′}, R¹⁷ and R^{17′} are independently of each other H, or a C₁-C₂₅alkyl group, especially a C₆-C₂₅alkyl, which may optionally be interrupted by one or more oxygen atoms,
R¹⁴ is a C₁-C₂₅alkyl group, especially a C₆-C₂₅alkyl, which may optionally be interrupted by one or more oxygen atoms,
R¹⁸ and R^{18′} independently of each other hydrogen, halogen, C₁-C₂₅alkyl, especially C₄-C₂₅alkyl, which may optionally be interrupted by one or more oxygen or sulphur atoms, C₇-C₂₅aralkyl, or C₁-C₂₅alkoxy;
R¹⁹ is hydrogen, C₇-C₂₅aralkyl, C₆-C₁₈aryl; C₆-C₁₈aryl which is substituted by C₁-C₁₈alkyl, or C₁-C₁₈alkoxy; or C₁-C₂₅alkyl, especially C₄-C₂₅alkyl, which may optionally be interrupted by one or more oxygen or sulphur atoms; and
R²⁰ and R^{20′} are independently of each other hydrogen, C₇-C₂₅aralkyl, C₁-C₂₅alkyl, especially C₄-C₂₅alkyl, which may optionally be interrupted by one, or more oxygen, or sulphur atoms.

Preferably, B, D and E are independently of each other a group of formula Va′, Vb′, Vc′, Ve′, Vf′, Vh′, Vi′, Vj′, Vk′, VL′, Vm′, Vn′, Vo′, Vp′, Vq′, Vr′, Vs′, Vu′, Vv′, Vw′, Vx′, Vy, Vz. Groups of formula Va′, Vc′, Vf′, Vh′, Vi′, Vk′, Vo′, Vp′, Vq′, Vr′, Vs′, Vu′, Vw′, Vx′ and Va″ are most preferred. Among groups of formula Vx′ a group of formula Vx″ is most preferred.

The group of formula (Vb′) is preferably a group of formula R

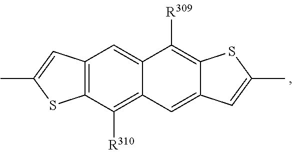

wherein R³⁰⁹ and R³¹⁰ are independently of each other C₁-C₂₅alkoxy.

In a preferred embodiment the present invention is directed to polymers comprising (repeating) unit(s) of the formula I′, especially Ia′, or polymers of formula II′, or III′, wherein A is a group of formula IVa′, and D is a group of formula

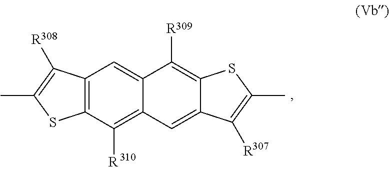

especially

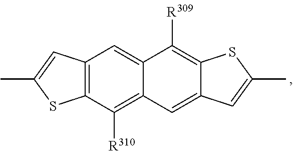

wherein R³⁰⁹ and R³¹⁰ are independently of each other C₁-C₂₅alkoxy.

The group of formula (Vc′) is preferably a group of formula

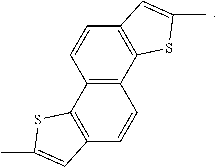

The group of formula (Vd′) is preferably a group of formula

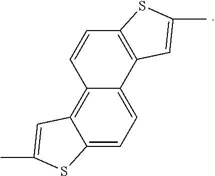

In a preferred embodiment the present invention is directed to polymers, comprising repeating units of the formula *A-D* (I′), wherein

A is a group of formula IVa′, IVc′, IVe′, IVg′, IVh′, IVi′, IVj′, or IVk′,
R¹ and R² are a C₁-C₃₅alkyl group, especially a C₈-C₃₅alkyl group,
R¹⁰⁴ is a C₁-C₂₅alkyl group, especially a C₄-C₂₅alkyl, which may optionally be interrupted by one or more oxygen or sulphur atoms,
D is a group of formula Va′, Vb′, Vc′, especially

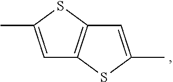

Ve′, Vf′, Vh′, Vi′, Vj′, Vk′, VL′, Vm′, Vn′, Vo′, Vp′, Vq′, Vr′, Vs′, Vu′, Vv′, Vw′, Vx′, especially

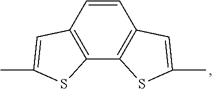

Vy, Vz, or Va″. In said embodiment polymers of the formula *A-Dₙ* (Ia′) are more preferred, wherein n is 4 (especially 10) to 1000, especially 4 to 200, very especially 5 (especially 20) to 100. At present most preferred are polymers, where A is a group of formula IVa′ and D is a group of formula Vx′, especially Vx″, such as, for example,

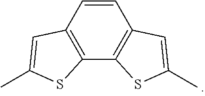

A preferred example of such a polymer is a polymer of formula

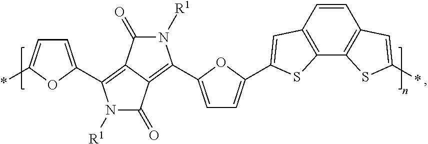

wherein n is 4 (especially 10) to 1000, especially 4 to 200, very especially 5 (especially 20) to 100 and R¹ is a C₁-C₃₅alkyl group, especially a C₈-C₃₅alkyl group.

Said polymers show high efficiency of energy conversion, when used in solar cells.

In another embodiment the present invention is directed to polymers of formula I′, especially of formula Ia′, where A is a group of formula IVa′ and D is a group of formula Vo′, especially

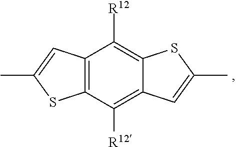

such as, for example,

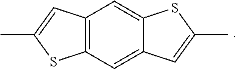

An example of such a polymer is a polymer of formula

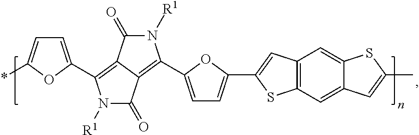

wherein n is 4 (especially 10) to 1000, especially 4 to 200, very especially 5 (especially 20) to 100 and R¹ is a C₁-C₃₅alkyl group, especially a C₈-C₃₅alkyl group. Said polymers show high efficiency of energy conversion, when used in solar cells.

According to one preferred embodiment of the present invention, the DPP polymer is a polymer of structure

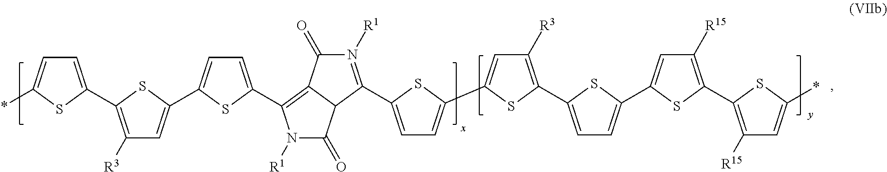

wherein
x is 0.01 to 0.99, especially 0.8 to 0.4 and y is 0.99 to 0.01, especially 0.2 to 0.6,
R¹ is a C₈-C₃₆alkyl group, especially hexyl-decyl, and
R³ and R¹⁵ are a C₁-C₁₈alkyl group, especially n-hexyl.

According to another preferred embodiment of the present invention, the DPP polymer is a polymer of structure

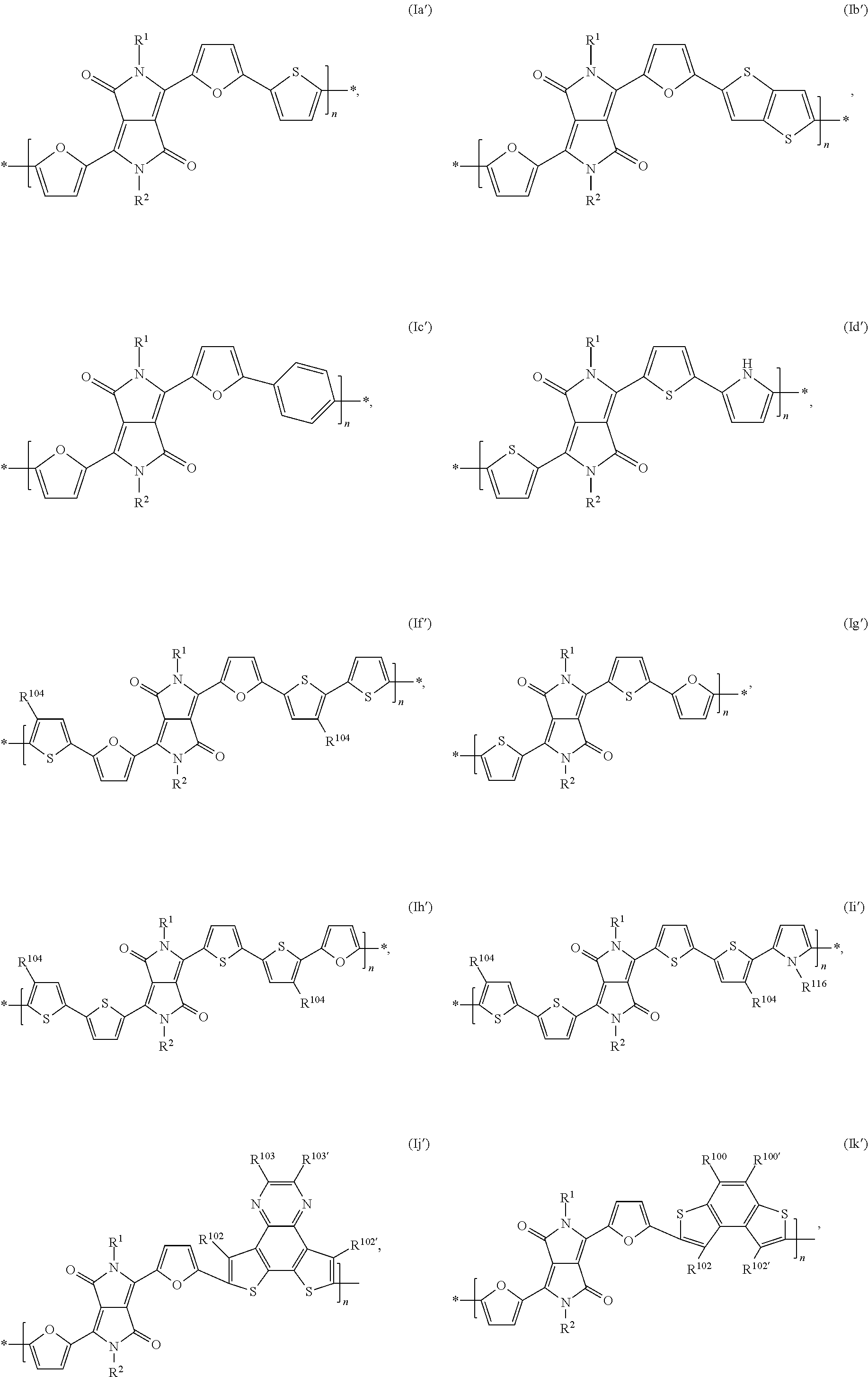

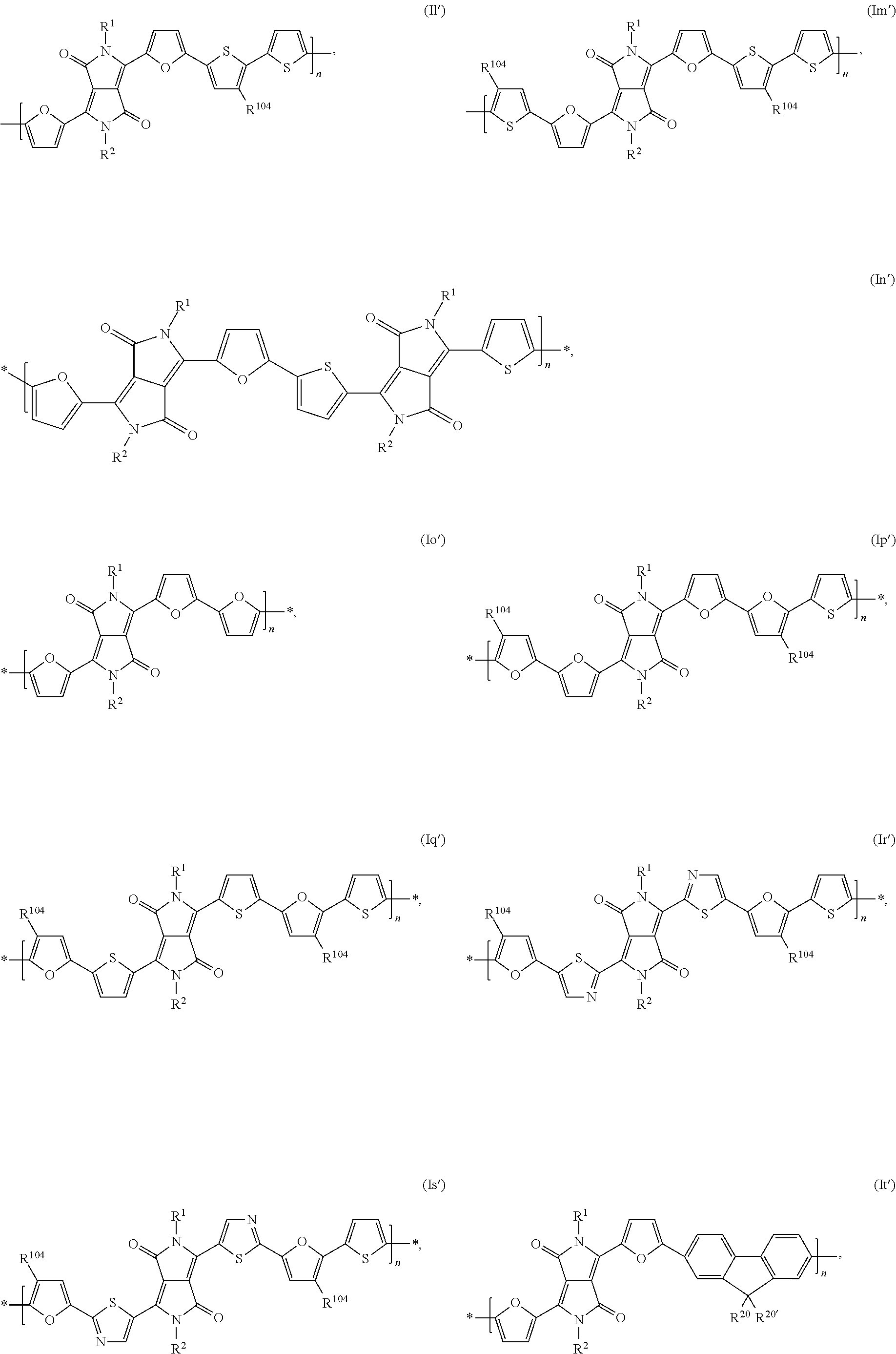

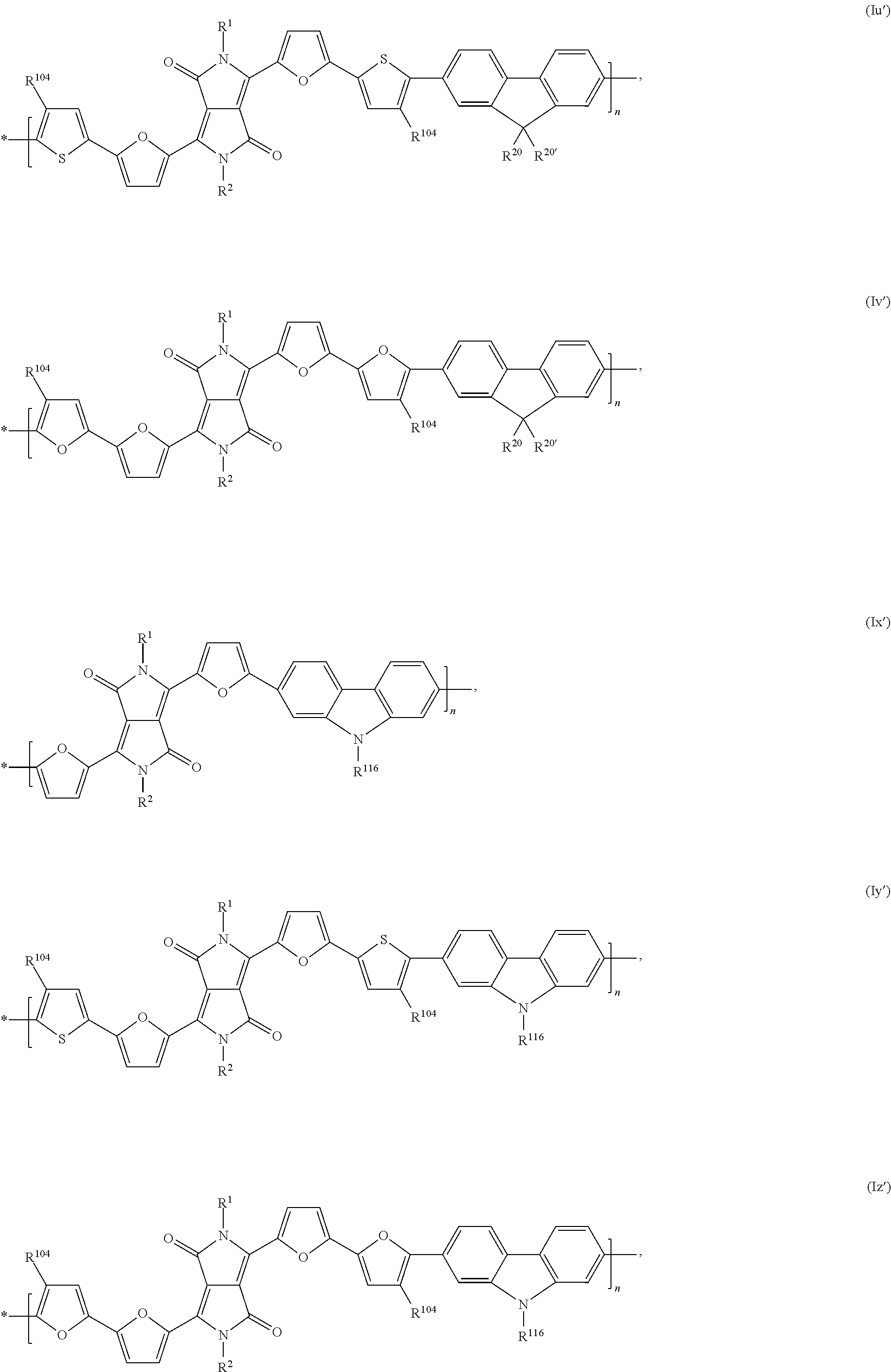

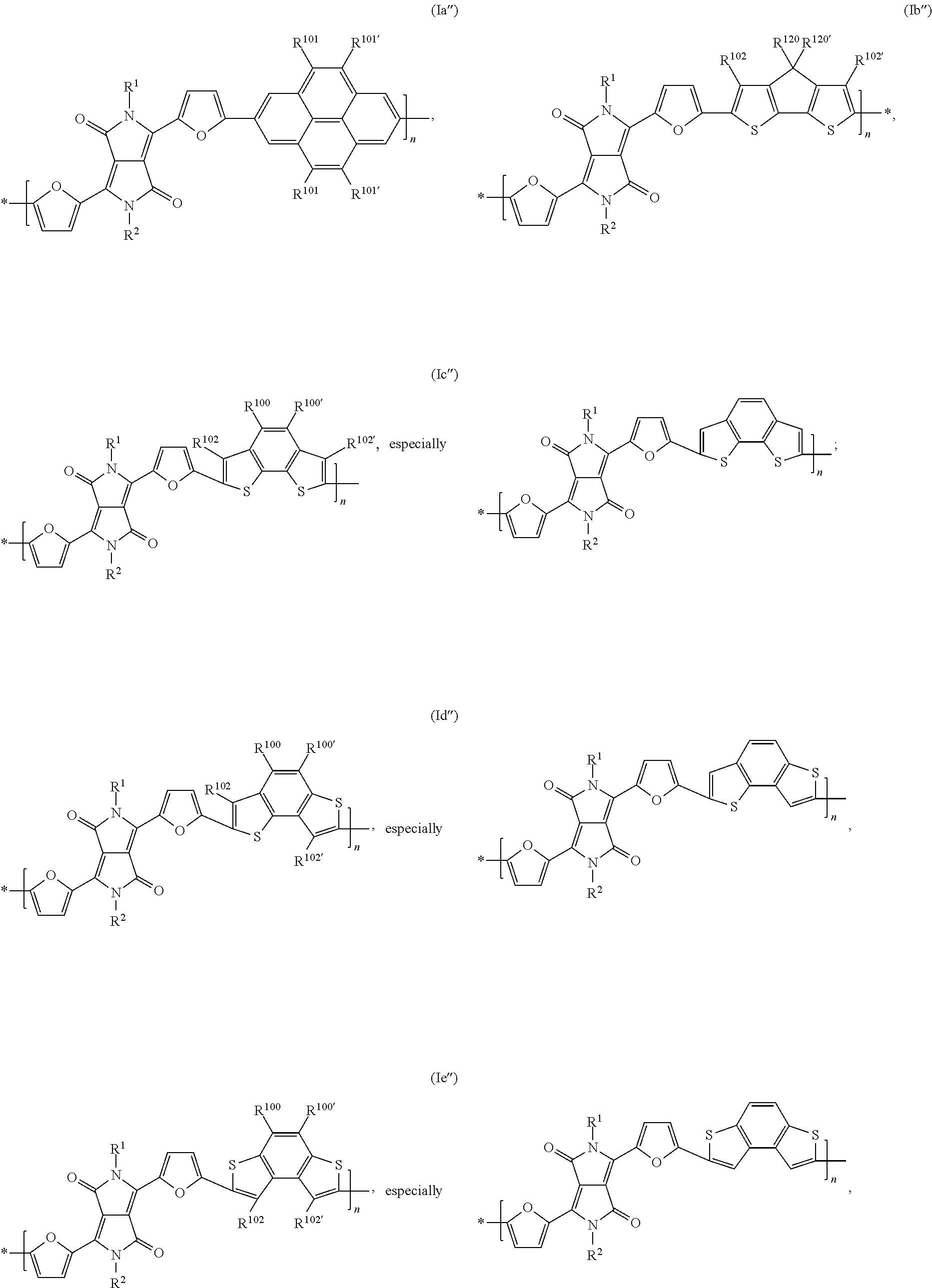

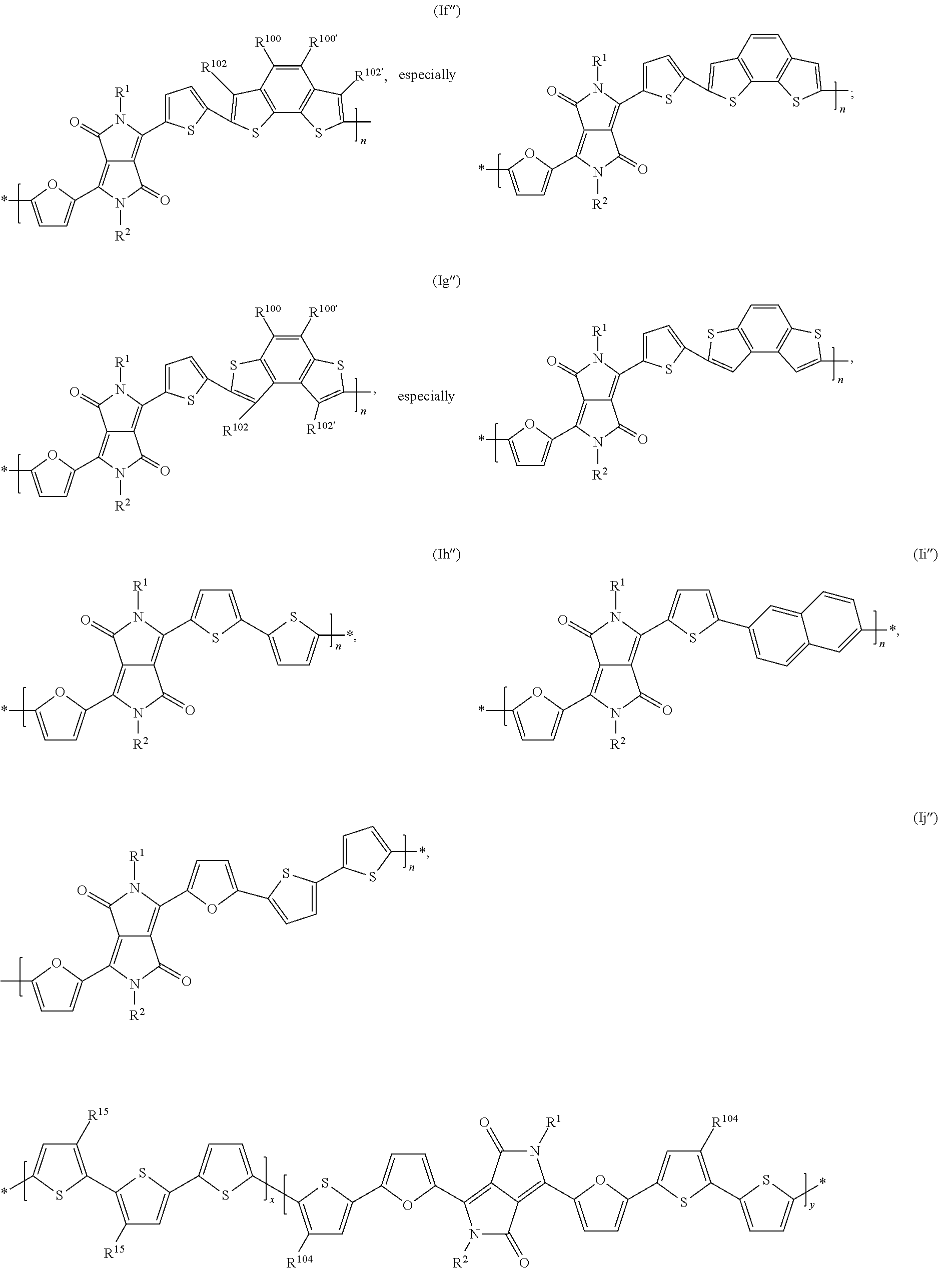

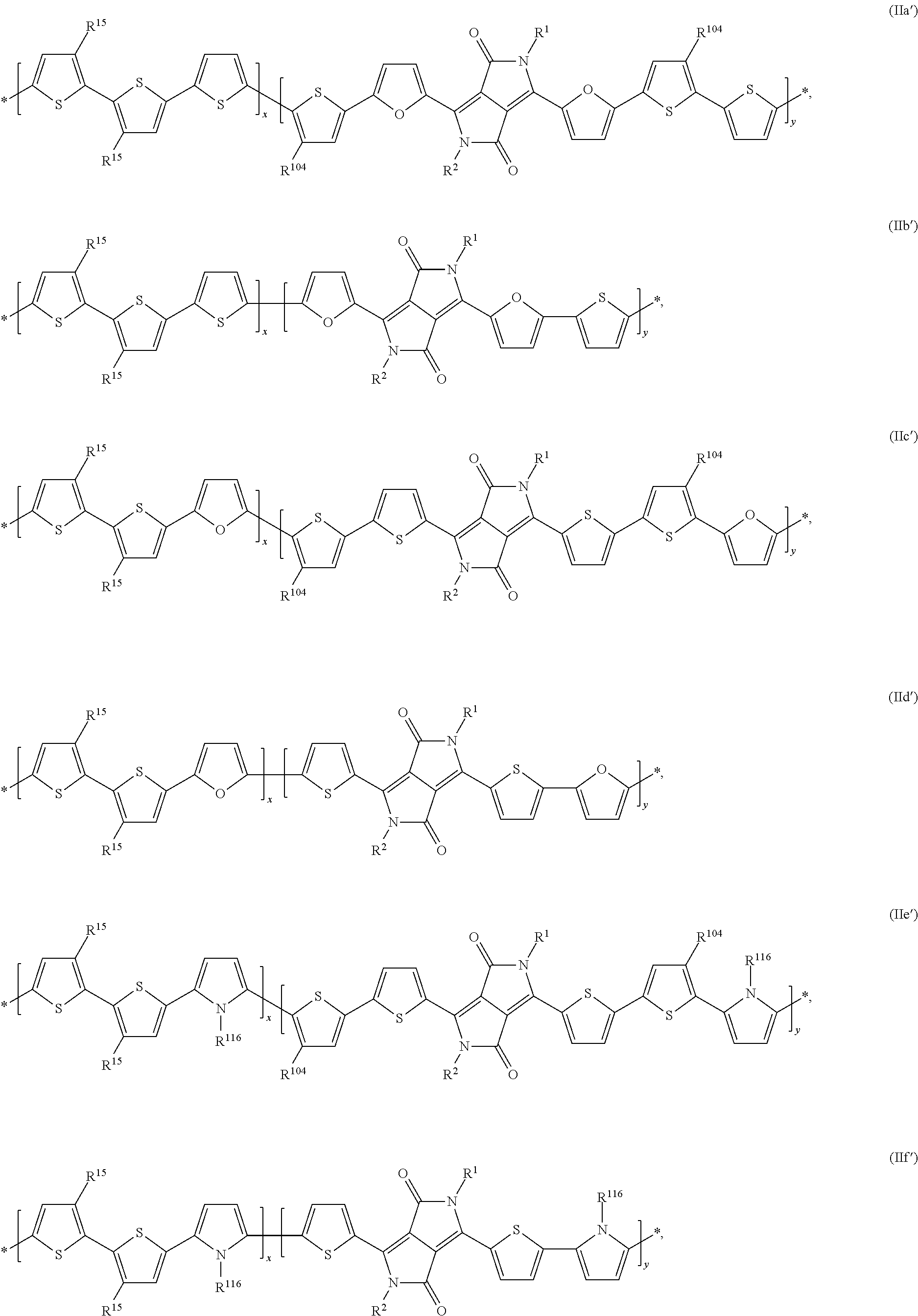

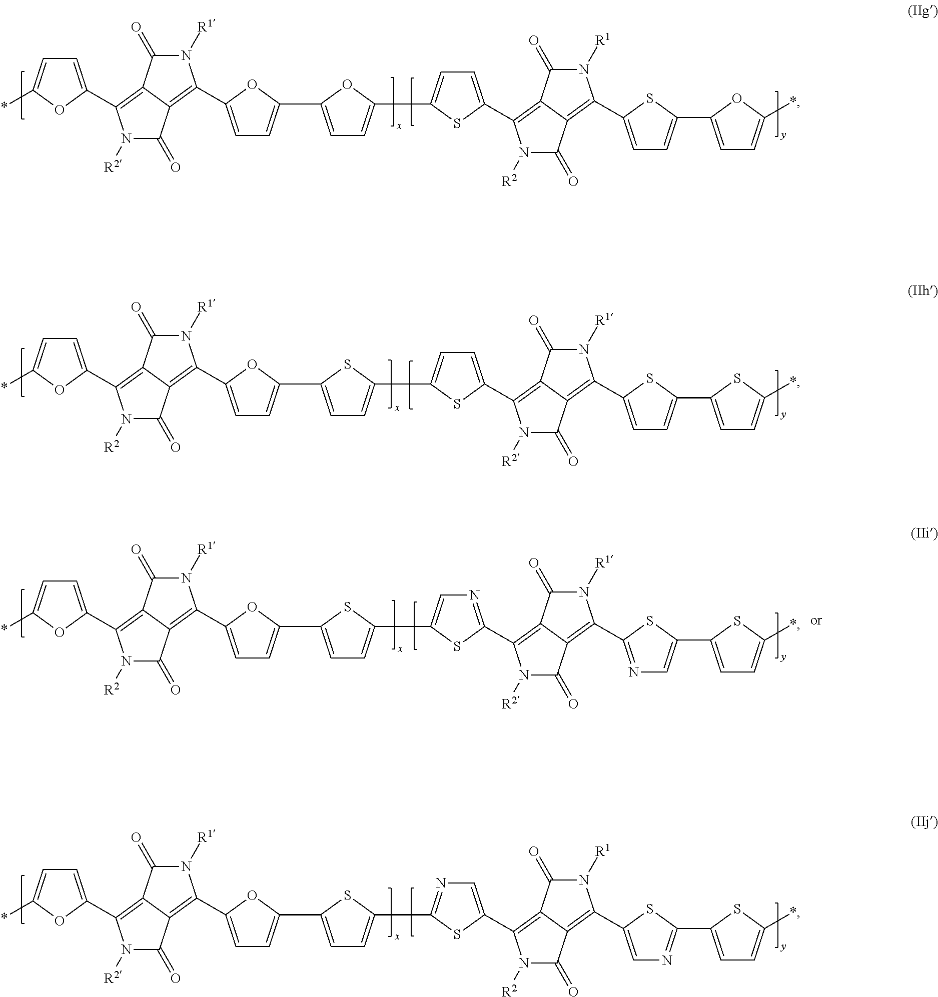

wherein R¹, R², R^{1′} and R^{2′} are independently of each other a C₁-C₃₆alkyl group, especially a C₈-C₃₆alkyl group,
R¹⁰⁴ is a C₁-C₂₅alkyl group, especially a C₄-C₂₅alkyl, which may optionally be interrupted by one or more oxygen or sulphur atoms,
R¹⁵, R^{15′}, R¹⁷ and R^{17′} are independently of each other H, or a C₁-C₂₅alkyl group, especially a C₆-C₂₅alkyl, which may optionally be interrupted by one or more oxygen atoms,
R²⁰ and R^{20′} are independently of each other hydrogen, C₇-C₂₅aralkyl, C₁-C₂₅alkyl, especially C₄-C₂₅alkyl, which may optionally be interrupted by one, or more oxygen, or sulphur atoms,

### R¹⁰⁰ and R^{100′} are H,

R¹⁰¹ and R^{101′} are H, a C₁-C₂₅alkyl group, or a C₁-C₂₅alkoxy group,
R¹⁰² and R^{102′} are H, or a C₁-C₂₅alkyl group,
R¹⁰³ and R^{103′} are H, or a C₁-C₂₅alkyl group,
R¹¹⁶ is H, or a C₁-C₂₅alkyl group,
R¹²⁰ and R¹²⁰ are a C₁-C₃₅alkyl group,
n is 4 to 1000, especially 4 to 200, very especially 5 to 100, and
x=0.995 to 0.005, y=0.005 to 0.995, especially x=0.2 to 0.8, y=0.8 to 0.2, and wherein x+y=1.

DPP copolymers can be obtained, for example, by the Suzuki reaction. The condensation reaction of an aromatic boronate and a halogenide, especially a bromide, commonly referred to as the “Suzuki reaction”, is tolerant of the presence of a variety of organic functional groups as reported by N. Miyaura and A. Suzuki in Chemical Reviews, Vol. 95, pp. 457-2483 (1995). Preferred catalysts are 2-dicyclohexylphosphino-2′,6′-di-alkoxybiphenyl/palladium(II)acetates, tri-alykl-phosphonium salts/palladium (0) derivatives and tri-alkylphosphine/palladium (0) derivatives. Especially preferred catalysts are 2-dicyclohexylphosphino-2′,6′-di-methoxybiphenyl (sPhos)/palladium(II)acetate and, tri-tert-butylphosphonium tetrafluoroborate ((t-Bu)₃P*HBF₄)/tris(dibenzylideneacetone)dipalladium (0) (Pd₂(dba)₃) and tri-tert-butylphosphine (t-Bu)₃P/tris(dibenzylideneacetone)dipalladium (0) (Pd₂(dba)₃). This reaction can be applied to preparing high molecular weight polymers and copolymers.

To prepare polymers corresponding to formula VII a dihalogenide, such as a dibromide or dichloride, especially a dibromide corresponding to formula Br-A-Br and Br—B—Br is reacted with an (equimolar) amount of a diboronic acid or diboronate corresponding to formula X¹¹DX¹¹, wherein X¹¹ is independently in each occurrence —B(OH)₂, —B(OY¹)₂,

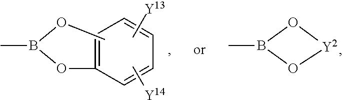

wherein Y¹ is independently in each occurrence a C₁-C₁₀alkyl group and Y² is independently in each occurrence a C₂-C₁₀alkylene group, such as —CY³Y⁴—CY⁵Y⁶—, or —CY⁷Y⁸—CY⁹Y¹⁰—CY¹¹Y¹²—, wherein Y³, Y⁴, Y⁵, Y⁶, Y⁷, Y⁸, Y⁹, Y¹⁰, Y¹¹ and Y¹² are independently of each other hydrogen, or a C₁-C₁₀alkyl group, especially —C(CH₃)₂C(CH₃)₂—, —CH₂C(CH₃)₂CH₂—, or —C(CH₃)₂CH₂C(CH₃)₂—, and Y¹³ and Y¹⁴ are independently of each other hydrogen, or a C₁-C₁₀alkyl group, under the catalytic action of Pd and triphenylphosphine. The reaction is typically conducted at about 0° C. to 180° C. in an aromatic hydrocarbon solvent such as toluene, xylene. Other solvents such as dimethylformamide, dioxane, dimethoxyethan and tetrahydrofuran can also be used alone, or in mixtures with an aromatic hydrocarbon. An aqueous base, preferably sodium carbonate or bicarbonate, potassium phosphate, potassium carbonate or bicarbonate is used as activation agent for the boronic acid, boronate and as the HBr scavenger. A polymerization reaction may take 0.2 to 100 hours. Organic bases, such as, for example, tetraalkylammonium hydroxide, and phase transfer catalysts, such as, for example TBAB, can promote the activity of the boron (see, for example, Leadbeater & Marco; Angew. Chem. Int. Ed. Eng. 42 (2003) 1407 and references cited therein). Other variations of reaction conditions are given by T. I. Wallow and B. M. Novak in J. Org. Chem. 59 (1994) 5034-5037; and M. Remmers, M. Schulze, and G. Wegner in Macromol. Rapid Commun. 17 (1996) 239-252. Control of molecular weight is possible by using either an excess of dibromide, diboronic acid, or diboronate, or a chain terminator.

If desired, a monofunctional aryl halide or aryl boronate may be used as a chain-terminator in such reactions, which will result in the formation of a terminal aryl group.

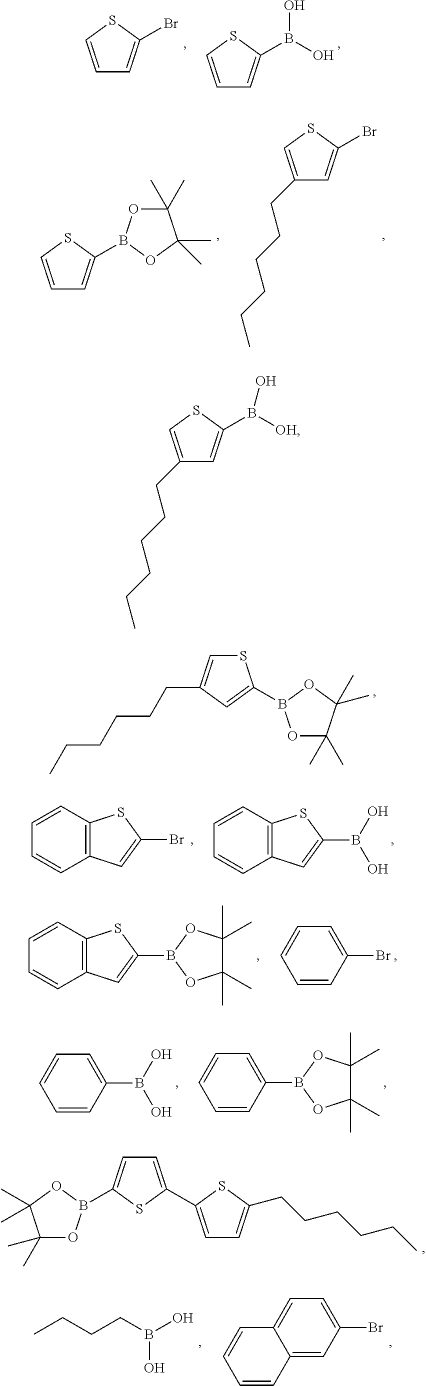

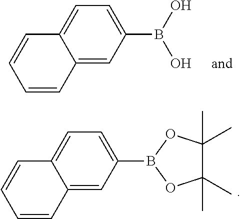

It is possible to control the sequencing of the monomeric units in the resulting copolymer by controlling the order and composition of monomer feeds in the Suzuki reaction.

The polymers of the present invention can also be sythesized by the Stille coupling (see, for example, Babudri et al, J. Mater. Chem., 2004, 14, 11-34; J. K. Stille, Angew. Chemie Int. Ed. Engl. 1986, 25, 508). To prepare polymers corresponding to formula VII a dihalogenide, such as a dibromide or dichloride, especially a dibromide corresponding to formula Br-A-Br and Br—B—Br is reacted with a compound of formula X²¹-D-X²¹, wherein X²¹ is a group —SnR²⁰⁷R²⁰⁸R²⁰⁹, in an inert solvent at a temperature in range from 0° C. to 20° C. in the presence of a palladium-containing catalyst, wherein R²⁰⁷, R²⁰⁸ and R²⁰⁹ are identical or different and are H or C₁-C₆alkyl, wherein two radicals optionally form a common ring and these radicals are optionally branched or unbranched. It must be ensured here that the totality of all monomers used has a highly balanced ratio of organotin functions to halogen functions. In addition, it may prove advantageous to remove any excess reactive groups at the end of the reaction by end-capping with monofunctional reagents. In order to carry out the process, the tin compounds and the halogen compounds are preferably introduced into one or more inert organic solvents and stirred at a temperature of from 0 to 200° C., preferably from 30 to 170° C. for a period of from 1 hour to 200 hours, preferably from 5 hours to 150 hours. The crude product can be purified by methods known to the person skilled in the art and appropriate for the respective polymer, for example repeated re-precipitation or even by dialysis.

Suitable organic solvents for the process described are, for example, ethers, for example diethyl ether, dimethoxyethane, diethylene glycol dimethyl ether, tetrahydrofuran, dioxane, dioxolane, diisopropyl ether and tert-butyl methyl ether, hydrocarbons, for example hexane, isohexane, heptane, cyclohexane, benzene, toluene and xylene, alcohols, for example methanol, ethanol, 1-propanol, 2-propanol, ethylene glycol, 1-butanol, 2-butanol and tert-butanol, ketones, for example acetone, ethyl methyl ketone and isobutyl methyl ketone, amides, for example dimethylformamide (DMF), dimethylacetamide and N-methylpyrrolidone, nitriles, for example acetonitrile, propionitrile and butyronitrile, and mixtures thereof.

The palladium and phosphine components should be selected analogously to the description for the Suzuki variant.

Alternatively, the polymers of the present invention can also be synthesized by the Negishi reaction using zinc reagents A-(ZnX²²)₂ and B—(ZnX²²)₂, wherein X²² is halogen and halides, and D-(X²³)₂, wherein X²³ is halogen or triflate, or using A-(X²²)₂, B—(X²²)₂, and D-(ZnX²³)₂. Reference is, for example, made to E. Negishi et al., Heterocycles 18 (1982) 117-22.

Alternatively, the polymers of the present invention can also be synthesized by the Hiyamai reaction using organosilicon reagents A-(SiR²¹⁰R²¹¹R²¹²)₂ and B—(SiR²¹⁰R²¹¹R²¹²)₂, wherein R²¹⁰, R²¹¹ and R²¹² are identical or different and are halogen, C₁-C₆alkyl and D-(X²³)₂, wherein X²³ is halogen or triflate, or using A-(X²²)₂, B—(X²²)₂, and D-(SiR²¹⁰R²¹¹R²¹²)₂. Reference is, for example, made to T. Hiyama et al., Pure Appl. Chem. 66 (1994) 1471-1478 and T. Hiyama et al., Synlett (1991) 845-853.

The polymers, wherein R¹ and/or R² are hydrogen can be obtained by using a protecting group which can be removed after polymerization (see, for example, EP-A-0 648 770, EP-A-0 648 817, EP-A-0 742 255, EP-A-0 761 772, WO98/32802, WO98/45757, WO98/58027, WO99/01511, WO00/17275, WO00/39221, WO00/63297 and EP-A-1 086 984). Conversion of the pigment precursor into its pigmentary form is carried out by means of fragmentation under known conditions, for example thermally, optionally in the presence of an additional catalyst, for example the catalysts described in WO00/36210.

An example of such a protecting group is group of formula

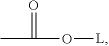

wherein L is any desired group suitable for imparting solubility.

L is preferably a group of formula

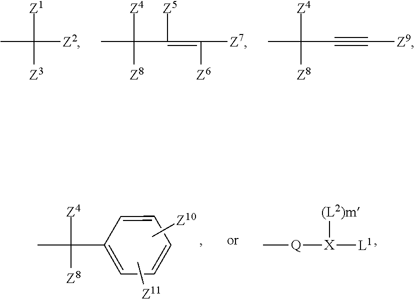

wherein Z¹, Z² and Z³ are independently of each other C₁-C₆alkyl,
Z⁴ and Z⁸ are independently of each other C₁-C₆alkyl, C₁-C₆alkyl interrupted by oxygen, sulfur or N(Z¹²)₂, or unsubstituted or C₁-C₆alkyl-, C₁-C₆alkoxy-, halo-, cyano- or nitro-substituted phenyl or biphenyl,
Z⁵, Z⁶ and Z⁷ are independently of each other hydrogen or C₁-C₆alkyl,
Z⁹ is hydrogen, C₁-C₆alkyl or a group of formula

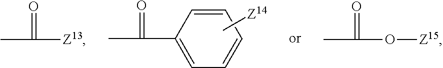

Z¹⁰ and Z¹¹ are each independently of the other hydrogen, C₁-C₆alkyl, C₁-C₆alkoxy, halogen, cyano, nitro, N(Z¹²)₂, or unsubstituted or halo-, cyano-, nitro-, C₁-C₆alkyl- or C₁-C₆alkoxy-substituted phenyl,
Z¹² and Z¹³ are C₁-C₆alkyl, Z¹⁴ is hydrogen or C₁-C₆alkyl, and Z¹⁵ is hydrogen, C₁-C₆alkyl, or unsubstituted or C₁-C₆alkyl-substituted phenyl,
Q is p,q-C₂-C₆alkylene unsubstituted or mono- or poly-substituted by C₁-C₆alkoxy, C₁-C₆alkylthio or C₂-C₁₂dialkylamino, wherein p and q are different position numbers,
X is a hetero atom selected from the group consisting of nitrogen, oxygen and sulfur, m′ being the number 0 when X is oxygen or sulfur and m being the number 1 when X is nitrogen, and
L¹ and L² are independently of each other unsubstituted or mono- or poly-C₁-C₁₂alkoxy-, —C₁-C₁₂alkylthio-, —C₂-C₂₄dialkylamino-, —C₆-C₁₂aryloxy-, —C₆-C₁₂arylthio-, —C₇-C₂₄alkylarylamino- or —C₁₂-C₂₄diarylamino-substituted C₁-C₆alkyl or [-(p′,q′-C₂-C₆alkylene)-Z—]_{n′}—C₁-C₆alkyl, n′ being a number from 1 to 1000, p′ and q′ being different position numbers, each Z independently of any others being a hetero atom oxygen, sulfur or C₁-C₁₂alkyl-substituted nitrogen, and it being possible for C₂-C₆alkylene in the repeating [—C₂-C₆alkylene-Z—] units to be the same or different,
and L₁ and L₂ may be saturated or unsaturated from one to ten times, may be uninterrupted or interrupted at any location by from 1 to 10 groups selected from the group consisting of —(C═O)— and —C₆H₄—, and may carry no further substituents or from 1 to 10 further substituents selected from the group consisting of halogen, cyano and nitro. Most preferred L is a group of formula

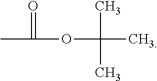

The synthesis of the compounds of formula Br-A-Br is described in WO08/000,664, and WO09/047,104, or can be done in analogy to the methods described therein. The synthesis of N-aryl substituted compounds of formula Br-A-Br can be done in analogy to the methods described in U.S. Pat. No. 5,354,869 and WO03/022848.

A suitable synthesis of the especially preferred compound of formula (VIIb) is disclosed in WO 2010/049323 A1, on page 45, line 24 to page 47, line 9.

Halogen is fluoro, chloro, bromo or iodo, preferably fluoro.

C₁-C₂₅alkyl (C₁-C₁₈alkyl) is typically linear or branched, where possible. Examples are methyl, ethyl, n-propyl, isopropyl, n-butyl, sec.-butyl, isobutyl, tert.-butyl, n-pentyl, 2-pentyl, 3-pentyl, 2,2-dimethylpropyl, 1,1,3,3-tetramethylpentyl, n-hexyl, 1-methylhexyl, 1,1,3,3,5,5-hexamethylhexyl, n-heptyl, isoheptyl, 1,1,3,3-tetramethylbutyl, 1-methylheptyl, 3-methylheptyl, n-octyl, 1,1,3,3-tetramethylbutyl and 2-ethylhexyl, n-nonyl, decyl, undecyl, dodecyl, tridecyl, tetradecyl, pentadecyl, hexadecyl, heptadecyl, octadecyl, eicosyl, heneicosyl, docosyl, tetracosyl or pentacosyl. C₁-C₈alkyl is typically methyl, ethyl, n-propyl, isopropyl, n-butyl, sec.-butyl, isobutyl, tert.-butyl, n-pentyl, 2-pentyl, 3-pentyl, 2,2-dimethyl-propyl, n-hexyl, n-heptyl, n-octyl, 1,1,3,3-tetramethylbutyl and 2-ethylhexyl. C₁-C₄alkyl is typically methyl, ethyl, n-propyl, isopropyl, n-butyl, sec.-butyl, isobutyl, tert.-butyl.

C₂-C₁₈alkenyl groups are straight-chain or branched alkenyl groups, such as e.g. vinyl, allyl, methallyl, isopropenyl, 2-butenyl, 3-butenyl, isobutenyl, n-penta-2,4-dienyl, 3-methyl-but-2-enyl, n-oct-2-enyl, n-dodec-2-enyl, isododecenyl, n-dodec-2-enyl or n-octadec-4-enyl.

C₂₋₁₈alkynyl is straight-chain or branched and preferably C₂₋₈alkynyl, which may be unsubstituted or substituted, such as, for example, ethynyl, 1-propyn-3-yl, 1-butyn-4-yl, 1-pentyn-5-yl, 2-methyl-3-butyn-2-yl, 1,4-pentadiyn-3-yl, 1,3-pentadiyn-5-yl, 1-hexyn-6-yl, cis-3-methyl-2-penten-4-yn-1-yl, trans-3-methyl-2-penten-4-yn-1-yl, 1,3-hexadiyn-5-yl, 1-octyn-8-yl, 1-nonyn-9-yl, 1-decyn-10-yl, or 1-tetracosyn-24-yl.

C₁-C₂₅alkoxy groups (C₁-C₁₈alkoxy groups) are straight-chain or branched alkoxy groups, e.g. methoxy, ethoxy, n-propoxy, isopropoxy, n-butoxy, sec-butoxy, tert-butoxy, amyloxy, isoamyloxy or tert-amyloxy, heptyloxy, octyloxy, isooctyloxy, nonyloxy, decyloxy, undecyloxy, dodecyloxy, tetradecyloxy, pentadecyloxy, hexadecyloxy, heptadecyloxy and octadecyloxy. Examples of C₁-C₈alkoxy are methoxy, ethoxy, n-propoxy, isopropoxy, n-butoxy, sec.-butoxy, isobutoxy, tert.-butoxy, n-pentoxy, 2-pentoxy, 3-pentoxy, 2,2-dimethylpropoxy, n-hexoxy, n-heptoxy, n-octoxy, 1,1,3,3-tetramethylbutoxy and 2-ethylhexoxy, preferably C₁-C₄alkoxy such as typically methoxy, ethoxy, n-propoxy, isopropoxy, n-butoxy, sec.-butoxy, isobutoxy, tert.-butoxy. The term “alkylthio group” means the same groups as the alkoxy groups, except that the oxygen atom of the ether linkage is replaced by a sulfur atom.

C₁-C₁₈ perfluoroalkyl, especially C₁-C₄ perfluoroalkyl, is a branched or unbranched radical such as for example —CF₃, —CF₂CF₃, —CF₂CF₂CF₃, —CF(CF₃)₂, —(CF₂)₃CF₃, and —C(CF₃)₃.

The term “carbamoyl group” is typically a C₁₋₁₈-carbamoyl radical, preferably C₁₋₁₈-carbamoyl radical, which may be unsubstituted or substituted, such as, for example, carbamoyl, methylcarbamoyl, ethylcarbamoyl, n-butylcarbamoyl, tert-butylcarbamoyl, dimethylcarbamoyloxy, morpholinocarbamoyl or pyrrolidinocarbamoyl.

C₅-C₁₂cycloalkyl is typically cyclopentyl, cyclohexyl, cycloheptyl, cyclooctyl, cyclononyl, cyclodecyl, cycloundecyl, cyclododecyl, preferably cyclopentyl, cyclohexyl, cycloheptyl, or cyclooctyl, which may be unsubstituted or substituted. The cycloalkyl group, in particular a cyclohexyl group, can be condensed one or two times by phenyl which can be substituted one to three times with C₁-C₄-alkyl, halogen and cyano. Examples of such condensed cyclohexyl groups are:

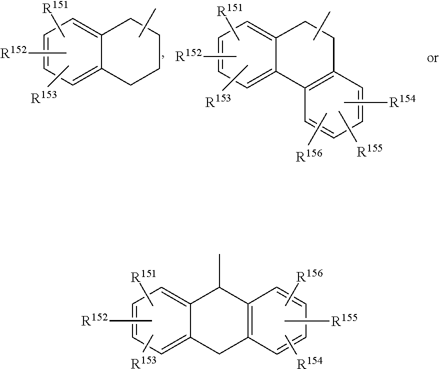

in particular

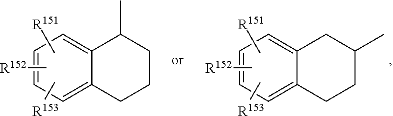

wherein R¹⁵¹, R¹⁵², R¹⁵³, R¹⁵⁴, R¹⁵⁵ and R¹⁵⁶ are independently of each other C₁-C₈-alkyl, C₁-C₈-alkoxy, halogen and cyano, in particular hydrogen.

C₆-C₂₄aryl (C₆-C₁₈aryl) is typically phenyl, indenyl, azulenyl, naphthyl, biphenyl, as-indacenyl, s-indacenyl, acenaphthylenyl, fluorenyl, phenanthryl, fluoranthenyl, triphenlenyl, chrysenyl, naphthacen, picenyl, perylenyl, pentaphenyl, hexacenyl, pyrenyl, or anthracenyl, preferably phenyl, 1-naphthyl, 2-naphthyl, 4-biphenyl, 9-phenanthryl, 2- or 9-fluorenyl, 3- or 4-biphenyl, which may be unsubstituted or substituted. Examples of C₆-C₁₂aryl are phenyl, 1-naphthyl, 2-naphthyl, 3- or 4-biphenyl, 2- or 9-fluorenyl or 9-phenanthryl, which may be unsubstituted or substituted.

C₇-C₂₅aralkyl is typically benzyl, 2-benzyl-2-propyl, β-phenyl-ethyl, α,α-dimethylbenzyl, ω-phenyl-butyl, ω,ω-dimethyl-ω-phenyl-butyl, ω-phenyl-dodecyl, ω-phenyl-octadecyl, ω-phenyl-eicosyl or ω-phenyl-docosyl, preferably C₇-C₁₈aralkyl such as benzyl, 2-benzyl-2-propyl, β-phenyl-ethyl, α,α-dimethylbenzyl, ω-phenyl-butyl, ω,ω-dimethyl-ω-phenyl-butyl, ω-phenyl-dodecyl or ω-phenyl-octadecyl, and particularly preferred C₇-C₁₂aralkyl such as benzyl, 2-benzyl-2-propyl, β-phenyl-ethyl, α,α-dimethylbenzyl, ω-phenyl-butyl, or ω,ω-dimethyl-ω-phenyl-butyl, in which both the aliphatic hydrocarbon group and aromatic hydrocarbon group may be unsubstituted or substituted. Preferred examples are benzyl, 2-phenylethyl, 3-phenylpropyl, naphthylethyl, naphthylmethyl, and cumyl.

Heteroaryl is typically C₂-C₂₀heteroaryl, i.e. a ring with five to seven ring atoms or a condensed ring system, wherein nitrogen, oxygen or sulfur are the possible hetero atoms, and is typically an unsaturated heterocyclic group with five to 30 atoms having at least six conjugated π-electrons such as thienyl, benzo[b]thienyl, dibenzo[b,d]thienyl, thianthrenyl, furyl, furfuryl, 2H-pyranyl, benzofuranyl, isobenzofuranyl, dibenzofuranyl, phenoxythienyl, pyrrolyl, imidazolyl, pyrazolyl, pyridyl, bipyridyl, triazinyl, pyrimidinyl, pyrazinyl, pyridazinyl, indolizinyl, isoindolyl, indolyl, indazolyl, purinyl, quinolizinyl, chinolyl, isochinolyl, phthalazinyl, naphthyridinyl, chinoxalinyl, chinazolinyl, cinnolinyl, pteridinyl, carbazolyl, carbolinyl, benzotriazolyl, benzoxazolyl, phenanthridinyl, acridinyl, pyrimidinyl, phenanthrolinyl, phenazinyl, isothiazolyl, phenothiazinyl, isoxazolyl, furazanyl or phenoxazinyl, which can be unsubstituted or substituted.

Possible substituents of the above-mentioned groups are C₁-C₈alkyl, a hydroxyl group, a mercapto group, C₁-C₈alkoxy, C₁-C₈alkylthio, halogen, halo-C₁-C₈alkyl, a cyano group, a carbamoyl group, a nitro group or a silyl group, especially C₁-C₈alkyl, C₁-C₈alkoxy, C₁-C₈alkylthio, halogen, halo-C₁-C₈alkyl, or a cyano group.

C₁-C₁₈alkyl interrupted by one or more O is, for example, (CH₂CH₂O)₁₋₉R^{x}, where R^{x} is H or C₁-C₁₀alkyl, CH₂—CH(OR^{Y′})—CH₂—O—R^{y}, where R^{y} is C₁-C₁₈alkyl, and R^{y′} embraces the same definitions as R^{y} or is H.

If a substituent, such as, for example R¹⁸, occurs more than one time in a group, it can be different in each occurrence.

The wording “substituted by G” means that one, or more, especially one to three substituents G might be present.

As described above, the aforementioned groups may be substituted by E′ and/or, if desired, interrupted by D′. Interruptions are of course possible only in the case of groups containing at least 2 carbon atoms connected to one another by single bonds; C₆-C₁₈aryl is not interrupted; interrupted arylalkyl contains the unit D′ in the alkyl moiety. C₁-C₁₈alkyl substituted by one or more E′ and/or interrupted by one or more units D′ is, for example, (CH₂CH₂O)₁₋₉R^{x}, where R^{x} is H or C₁-C₁₀alkyl or C₂-C₁₀alkanoyl (e.g. CO—CH(C₂H₅)C₄H₉), CH₂—CH(OR^{Y′})—CH₂—O—R^{y}, where R^{y} is C₁-C₁₈alkyl, C₅-C₁₂cycloalkyl, phenyl, C₇-C₁₅-phenylalkyl, and R^{y′} embraces the same definitions as R^{y} or is H; C₁-C₈alkylene-COO—R^{z}, e.g. CH₂COOR_{z}, CH(CH₃)COOR^{z}, C(CH₃)₂COOR^{z}, where R^{z} is H, C₁-C₁₈alkyl, (CH₂CH₂O)₁₋₉R^{x}, and R^{x} embraces the definitions indicated above; CH₂CH₂—O—CO—CH═CH₂; CH₂CH(OH)CH₂—O—CO—C(CH₃)═CH₂.

A mixture containing a polymer of the present invention results in a semi-conducting layer comprising a polymer of the present invention (typically 5% to 99.9999% by weight, especially 20 to 85% by weight) and at least another material. The other material can be, but is not restricted to a fraction of the same polymer of the present invention with different molecular weight, another polymer of the present invention, a semi-conducting polymer, organic small molecules, carbon nanotubes, a fullerene derivative, inorganic particles (quantum dots, quantum rods, quantum tripods, TiO₂, ZnO etc.), conductive particles (Au, Ag etc.), insulator materials like the ones described for the gate dielectric (PET, PS etc.).

The present DPP polymers can be blended with small molecules described, for example, in European patent application no. 09155919.5, WO09/047,104, U.S. Pat. No. 6,690,029, WO2007082584, WO2008107089.

### The Photovoltaic Layer

According to the present invention, the photovoltaic layer of the present OPV device comprises a mixture which comprises the at least one diketopyrrolopyrrole (DPP) polymer and the at least one stabilizing agent.

Therefore, according to the present invention, said mixture may comprise one or more of above-described DPP polymers and one or more of above-described stabilizing agents. For example, the mixture may comprise one or more DPP polymers and one or more UV absorbing agents and no anti-radical agent. Also, the mixture may comprise one or more DPP polymers and no UV absorbing agent and one or more anti-radical agents. Further, the mixture may comprise one or more DPP polymers and one or more UV absorbing agent and one or more anti-radical agents.

According to one preferred embodiment, the mixture comprises one or more DPP polymers, more preferably one DPP polymer, more preferably one DPP polymer of structure (VII), even more preferably of a structure

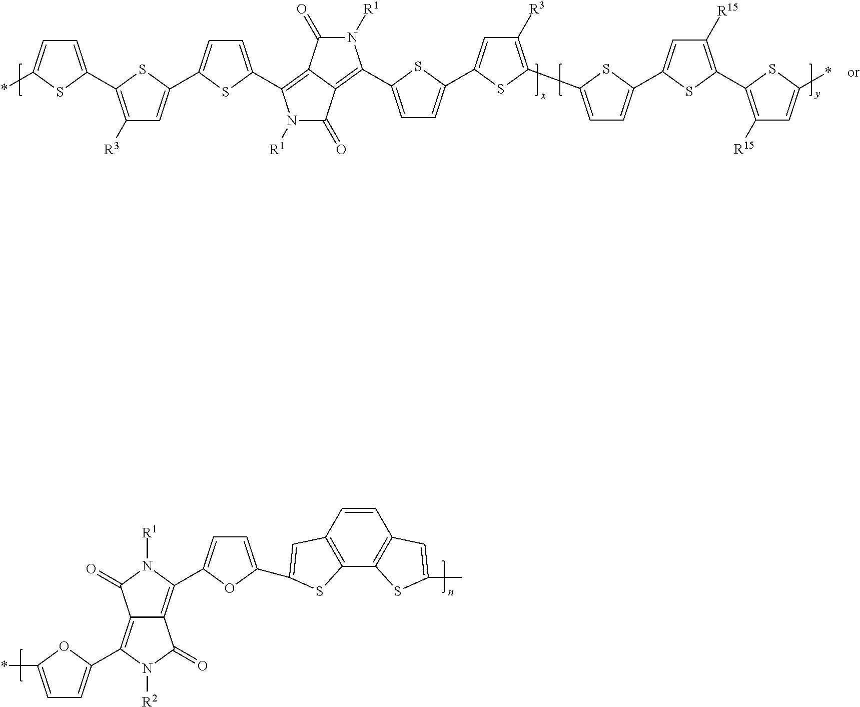

(as of example 16 in PCT/EP2011/057878) where the symbols (R1, R2, R3, R15, x, y, n) are as described above, and no UV absorbing agent and one or more anti-radical agents, preferably one anti-radical agent, more preferably one hindered phenol, more preferably one hindered phenol of structure (23)

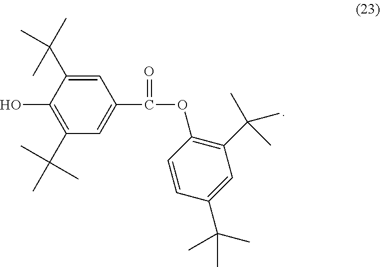 [SMILES: CC(C)(C)c1ccc(OC(=O)c2cc(C(C)(C)C)c(O)c(C(C)(C)C)c2)c(C(C)(C)C)c1]

According to another preferred embodiment, the mixture comprises one or more DPP polymers, more preferably one DPP polymer, more preferably one DPP polymer of structure (VII), even more preferably of structure (VIIb) or (Ic″)

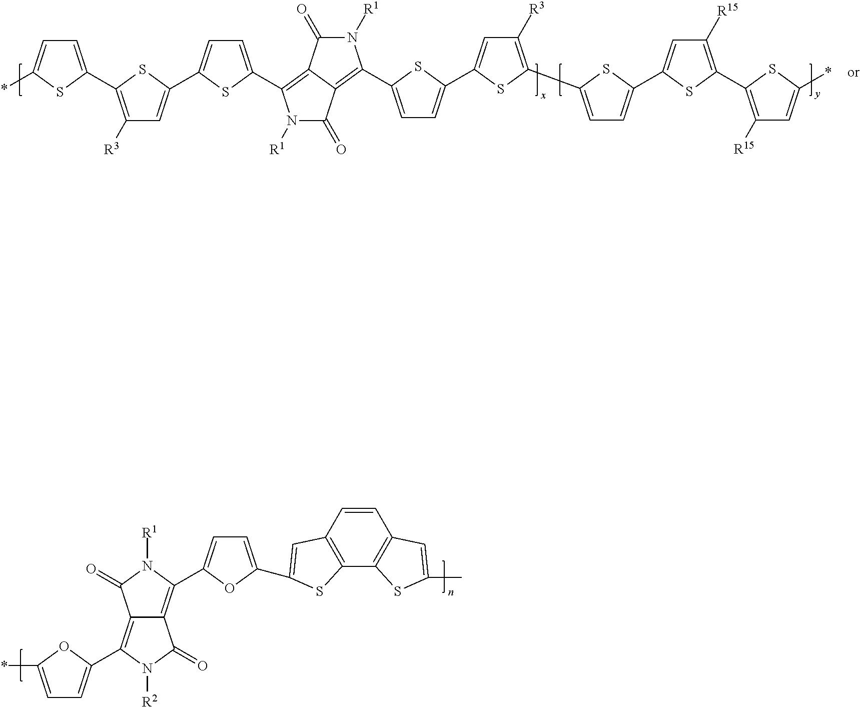

(as of example 16 in PCT/EP2011/057878) where the symbols (R1, R2, R3, R15, x, y, n) are as described above, and one or more UV absorbing agents, preferably one UV absorbing agent, more preferably a UV absorbing agent of formula (IIa), (lib), (IIc) or (III), as described above, more preferably a UV absorbing agent of formula (IIa), and no anti-radical agents. Especially preferred examples of UV absorbing agents are compounds of structures

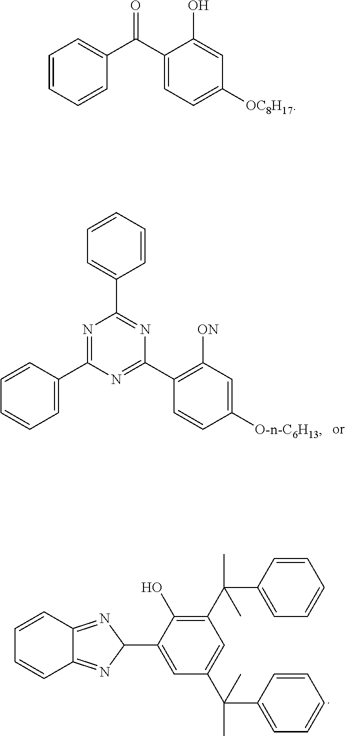

As far as the amounts of respective DPP polymer and stabilizing agent comprised in the mixture are concerned, no specific restrictions exist with the proviso that the stabilization effect is achieved and the mixture is suitable for use in a photovoltaic layer in the inventive OPV device.

Preferably, the mixture comprising the at least one DPP polymer and the at least one stabilizing agent, the weight ratio of stabilizing agent relative to the DPP polymer is in the range of from 0.0005:1 to 0.1:1 to, preferably from 0.001:1 to less than 0.05:1, more preferably from 0.005:1 to 0.025:1. In this context, and in the term “weight ratio of stabilizing agent relative to the DPP polymer”, the term “stabilizing agent” relates to the sum of all stabilizing agents contained in the mixture, and the “DPP polymer” relates to the sum of all DPP polymers contained in the mixture.

In an important embodiment, the stabilizing agent selected from hindered phenols and/or HALS is contained in the mixture in a weight ratio stabilizing agent:DPP polymer ranging from 0.0001:1 to 0.01:1, preferably from 0.0005:1 to 0.005:1, more preferably from 0.0005:1 to 0.002:1.

In an especially important embodiment, the stabilizing agent selected from UV absorbers is contained in the mixture in a weight ratio stabilizing agent:DPP polymer ranging from 0.0005:1 to 0.1:1, preferably from 0.001:1 to less than 0.1:1.

The photovoltaic layer of the present invention comprising the inventive mixture of at least one DPP polymer and at least one stabilizing agent contains the DPP polymer usually as electron donor. Preferably, the photovoltaic layer of the present invention comprising the mixture of the present invention comprising the at least one DPP polymer and the at least one stabilizing agent additionally comprises at least one suitable electron acceptor material.

Generally, there are no specific restrictions as far as the chemical nature of the at least one suitable electron acceptor material is concerned. For example, the acceptor material can be a material selected from the group consisting of a suitable organic polymer such as a suitable DPP polymer or a suitable semiconducting polymer provided that the polymers retain acceptor-type and electron mobility characteristics, suitable organic small molecule, carbon nanotubes, inorganic particles such as quantum dots, quantum rods, quantum tripods, TiO₂, ZnO and the like. Preferably, a fullerene, in particular a suitably modified such a suitably functionalized fullerene is employed as an electron acceptor.

Fullerenes useful in this invention may have a broad range of sizes (number of carbon atoms per molecule). The term fullerene as used herein includes various cage-like molecules of pure carbon, including Buckminsterfullerene (C60) and the related “spherical” fullerenes as well as carbon nanotubes. Fullerenes may be selected from those known in the art ranging from, for example, C20-C1000—Preferably, the fullerene is selected from the range of C60 to C96. Most preferably the fullerene is C60 or C70, such as [60]PCBM, or [70]PCBM wherein [60]PCBM or [70] stands for [6,6]-Phenyl Cₙ butyric acid methyl ester with n=60 or 70. For example, the compound [70]PCBM has the following structure:

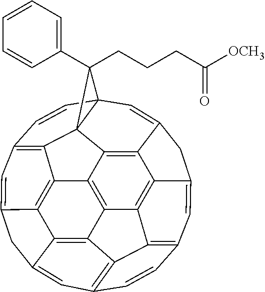 [SMILES: COC(=O)CCCC1(c2ccccc2)C23C=Cc4cc5c6c7c4C21c1c2c4c(cc8ccc9cc(c6c6c9c8c4c6c17)C5)CC2=C3]

It is also permissible to utilize other chemically modified fullerenes, provided that the modified fullerene retains acceptor-type and electron mobility characteristics.

Therefore, the present invention also relates to above-described device wherein the electron acceptor material is an optionally suitably modified fullerene, preferably having from 60 to 96 carbon atoms.

If according to the present invention, at least one electron acceptor material is comprised in the photovoltaic layer, such as in the inventive mixture, the weight ratio of the electron acceptor material relative to the DPP polymer is in the range of from 0.1:1 to 10:1, preferably from 0.5:1 to 3:1, more preferably from 0.8:1 to 2:1. In this context, and in the term “weight ratio of the electron acceptor material relative to the DPP polymer”, the term “electron acceptor material” relates to the sum of all electron acceptor materials contained in the mixture, and the “DPP polymer” relates to the sum of all DPP polymers contained in the mixture.

According to an embodiment of the present invention, the photovoltaic layer consists of the inventive mixture comprising the at least one DPP polymer and the at least one stabilizing agent, and optionally the at least one electron acceptor material. According to a further embodiment of the present invention, the photovoltaic layer consists of the inventive mixture which consists of the at least one DPP polymer and the at least one stabilizing agent, and optionally the at least one electron acceptor material.

### The Organic Photovoltaic Device (OPV Device)

The OPV device of the present invention comprising the inventive mixture generally can be designed according to the respective needs. According to one preferred embodiment, an OPV device of the present invention comprises, most preferably in this order,

(a) a cathode;
(b) optionally a transition layer;
(c) the photovoltaic layer;
(d) optionally a smoothing layer;
(j) an anode;
(k) a substrate.

In this OPV device, the photovoltaic layer (c) is the photovoltaic layer of the present invention which comprises the at least one DPP polymer and the at least one stabilizing agent according to the present invention.

The electrodes, the cathode (a) and the anode (j), are preferably composed of metals or metal substitutes. As used in this context of the present invention, the term “metal” includes both materials composed of an elementally pure metal, for example Mg, and also metal alloys which are materials composed of two or more elementally pure metals, for example Mg and Ag together, denoted Mg:Ag. As used in this context of the present invention, the term “metal substitute” refers to a material that is not a metal within the normal definition, but which has the metal-like properties that are desired in the present OPV device application. Commonly used metal substitutes for electrodes and charge transfer layers would include doped wide-bandgap semiconductors, for example, transparent conducting oxides such as indium tin oxide (ITO), gallium indium tin oxide (GITO), and zinc indium tin oxide (ZITO). Another suitable metal substitute is the transparent conductive polymer polyanaline (PANI) and its chemical relatives, or PEDOT:PSS (poly(3,4-ethylenedioxythiophene)poly(styrenesulfonate)). Metal substitutes may be further selected from a wide range of non-metallic materials, wherein the term “non-metallic” as used in this context of the present invention includes a wide range of materials provided that the material is free of metal in its chemically uncombined form. Highly transparent, non-metallic, low resistance cathodes or highly efficient, low resistance metallic/non-metallic compound cathodes are, for example, disclosed in U.S. Pat. No. 6,420,031 B1 and U.S. Pat. No. 5,703,436 B1.

The substrate can be, for example, a plastic (flexible substrate), or glass substrate. In another preferred embodiment of the invention, a smoothing layer is located between the anode and the photovoltaic layer. A preferred material for this smoothing layer comprises a film of 3,4-polyethylenedioxythiophene (PEDOT), or PEDOT:PSS).

Further, the OPV device of the present invention can also be processed on a fiber as described, for example, in US 20070079867 A1 and US 20060013549 A1.

In a preferred embodiment of the present invention, the OPV device comprises, as described for example, in U.S. Pat. No. 6,933,436 B1, a transparent glass carrier as substrate (k), onto which an electrode layer made of indium/tin oxide (ITO) is applied as anode (j). This electrode layer generally has a comparatively rough surface structure, so that it is covered with a smoothing layer (d) made of a suitable polymer, typically PEDOT, which is made electrically conductive through suitable doping. The photovoltaic layer (c) has a layer thickness of, for example, 100 nm to a few micrometers depending on the specific OPV device design, and is applied onto the smoothing layer (d). Preferably, the photovoltaic layer is made of the mixture comprising the at least one DPP polymer and the at least one stabilizing agent, the DPP polymer preferably acting as an electron donor, and a suitable electron acceptor material, preferably a fullerene, more preferably a functionalized fullerene PCBM.

Between the cathode (a) and the photovoltaic layer (c), a preferably thin transition layer is optionally applied, which must be electrically insulating, and has, for example, a layer thickness of 0.6 nm. According to a preferred embodiment, this transition layer is made of an alkali halogenide, more preferably lithium fluoride. If, for example, ITO is used as a hole-collecting electrode, aluminum, which is preferably vapor deposited onto the electrically insulating transition layer (d), is used as an electron-collecting electrode. The electric insulation properties of the transition layer obviously prevent influences which hinder the crossing of the charge carrier from being effective, particularly in the transition region from the photovoltaic layer to the transition layer.

The OPV device of the present invention can also consist of multiple junction solar cells that are processed on top of each other in order to absorb more of the solar spectrum. Such structures are, for example, described in App. Phys. Let. 90, 143512 (2007), Adv. Funct. Mater. 16, 1897-1903 (2006), and WO 2004/112161.

Therefore, the present invention also relates to above-described OPV device, wherein the transition layer (b) is an alkali halogenide, preferably lithium fluoride; the cathode (a) is a metal or a metal substitute; the anode (j) is a metal or a metal substitute; and the substrate (k) is a plastic or glass substrate.

In case ITO is used as anode as described above, aluminum, which is preferably vapor deposited onto the electrically insulating transition layer, is used as cathode.

According to one embodiment of the present invention which encompasses a so-called tandem solar cell, the device, in addition to the layers described above, further comprises

(e) a middle electrode;
(f) optionally a further electrode;
(g) optionally a transition layer;
(h) a further photovoltaic layer;
(i) optionally a smoothing layer.

Thus, the OPV device comprises, in this order,

(a) a cathode;
(b) optionally a transition layer;
(c) the photovoltaic layer;
(d) optionally a smoothing layer;
(e) a middle electrode;
(f) optionally a further electrode;
(g) optionally a transition layer;
(h) a further photovoltaic layer;
(i) optionally a smoothing layer;
(j) an anode;
(k) a substrate.

Preferably, the middle electrode (e) comprises, preferably consists of a metal or a metal substitute, preferably of a metal such as Au or Al, or other suitable materials such as ZnO, Ti oxides such as TiO2, or the like. Preferably, the optional further electrode (f) comprises, preferably consists of a metal or a metal substitute. As to the optionally transition layer (g), reference is made to the description of the transition layer (b) hereinabove wherein the transition layer (g) may be comprised of the same material(s) as the transition layer (b), or may be different from the transition layer (b).

Therefore, the present invention also relates to above-described OPV device, wherein the middle electrode (e) is a metal or a metal substitute; the further electrode (f) is a metal or a metal substitute; the transition layer (g) is an alkali halogenide, preferably lithium fluoride.

### Process for Producing the OPV Device

As far as the process for the preparation of the organic photovoltaic (OPV) device according to the present invention is concerned, no restrictions exist in general provided that the mixture comprising at least one diketopyrrolopyrrole (DPP) polymer and at least one stabilizing agent which is preferably a UV absorbing agent or an anti-radical agent is suitably incorporated in the device.

According to one preferred embodiment, the present invention relates to such process for the production of an organic photovoltaic (OPV) device as described above, said process comprising
(aa) providing at least one diketopyrrolopyrrole (DPP) polymer, at least one stabilizing agent which is preferably a UV absorbing agent or an anti-radical agent, and preferably at least one electron acceptor material;
(bb) providing a substrate onto which an anode and optionally, onto the anode, a smoothing layer has been applied;
(cc) mixing the compounds provided in (aa) with at least one suitable solvent;
(dd) applying the mixture obtained from (cc) onto the anode, optionally onto the smoothing layer.

### Step (dd)

According to (cc), the two, preferably the three components are mixed with at least one suitable solvent and applied, according to (dd), as a solution onto the anode, optionally onto the smoothing layer applied onto the anode, by a suitable method. Preferably, application according to (dd) is carried out via either at least one suitable coating technique and/or at least one suitable printing technique. Therefore, the present invention also relates to above-described process, wherein applying in (dd) is performed via coating and/or printing, preferably coating or printing.

Suitable coating techniques which can be used according to the present invention are, for example, spin-coating, slot-die coating (also called as extrusion coating), curtain coating, reverse gravure coating, blade coating, spray coating, and dip coating. Preferred coating techniques are, for example, slot-die (extrusion) coating or reverse gravure coating.

Suitable printing techniques which can be used according to the present invention are, for example, inkjet printing, flexography printing, (forward) gravure printing, screen printing, pad printing, offset printing, and reverse offset printing. Preferred printing techniques are, for example, flexography printing or (forward) gravure printing.

Therefore, the present invention also relates to above-described process, wherein applying in (dd) is performed via coating, preferably slot-die (extrusion) coating or reverse gravure coating, or printing, preferably flexography printing or (forward) gravure printing.

From step (dd), the inventive photovoltaic layer is obtained, being located on the anode, optionally on the smoothing layer. Therefore, the present invention also relates to above-described process comprising
(dd) applying the mixture obtained from (cc) onto the anode, optionally onto the smoothing layer to obtain a photovoltaic layer, said layer comprising a mixture which comprises at least one diketopyrrolopyrrole (DPP) polymer and at least one stabilizing agent wherein the stabilizing agent is preferably selected from the group consisting of a UV absorbing agent and an anti-radical agent.

### Step (cc)

According to (cc), at least one suitable solvent is employed. Such suitable solvents for preparing the mixtures according to the present application are all common solvents in which the DPP polymer and stabilizing agents have satisfactory solubility. Examples of common organic solvents include, but are not limited to,

petroleum ethers, aromatic hydrocarbons such as benzene, chlorobenzene, dichlorobenzene, preferably 1,2-dichlorobenzene, trichlorobenzene, cyclohexylbenzene, toluene, anisole, xylene, naphthalene, chloronaphtalene, tetraline, indene, indane, cyclooctadiene, styrene, decaline and mesitylene;
halogenated aliphatic hydrocarbons such as dichloromethane, chloroform and ethylenechloride;
ethers such as dioxane and dioxolane;
ketones such as cyclopentanone and cyclohexanone;
aliphatic hydrocarbons such as hexanes and cyclohexanes;
and suitable mixtures of two or more of said solvents.

Preferred solvents are dichlorobenzene, toluene, xylene, tetraline, chloroform, mesitylene and mixtures of two or more thereof. Therefore, the present invention also relates to above-described process, wherein in (cc), dichlorobenzene, preferably 1,2-dichlorobenzene,l toluene, xylene, tetraline, chloroform, mesitylene and mixtures of two or more thereof is used as solvent.

Usual concentrations of the compounds according to (cc) in the solvent are generally in the range of from 0.01 to 90% by weight, based on the weight of the solvent.

In order to prepare an OPV device as described above comprising, most preferably in this order,

(a) a cathode;
(b) optionally a transition layer;
(c) the photovoltaic layer;
(d) optionally a smoothing layer;
(j) an anode;
(k) a substrate
optionally a transition layer and a cathode are applied onto the photovoltaic layer.

Preferably, before the cathode (a) electrode is applied, a thin transition layer, which must be electrically insulating, having a layer thickness of, for example, 0.6 nm, is applied to photovoltaic layer (c). As to generally suitable and preferred materials of the transition layer, reference is made to the discussion above. Therefore, according to a preferred embodiment, this transition layer is made of an alkali halogenide, most preferably lithium fluoride. Preferably, the alkali halogenide, most preferably lithium fluoride, is vapor deposited in a suitable vacuum such as 2×10⁻⁶ torr at a suitable rate such as 0.2 nm/minute. The electric insulation properties of the transition layer obviously prevent influences which hinder the crossing of the charge carrier from being effective, particularly in the transition region from the photovoltaic layer to the transition layer.

### Steps (ee) and (ff)

Onto the photovoltaic layer (c), preferably onto the transition layer (b) applied onto the photovoltaic layer (c), a suitable cathode (a) is applied. While there are no specific restrictions as far as the respective application method is concerned, it is preferred, for example, to apply the cathode (a) by vapor deposition.

Therefore, the present invention also relates to above-described process comprising steps (aa) to (dd), further optionally comprising the step (ee) and further comprising (ff) of
(ee) applying a transition layer onto the photovoltaic layer;
(ff) applying a cathode onto the photovoltaic layer, optionally onto the transition layer applied onto the photovoltaic layer in (ee).

In a further embodiment on the invention, one or more of the layers may be treated with plasma prior to depositing the next layer. It is particularly advantageous that the smoothing layer, preferably the smoothing layer comprising PEDOT:PSS be subject to a mild plasma treatment prior to deposition of the next layer.

As far as the process for the production of an OPV device comprising, preferably in this order,

(a) a cathode;
(b) optionally a transition layer;
(c) the photovoltaic layer;
(d) optionally a smoothing layer;
(e) a middle electrode;
(f) optionally a further electrode;
(g) optionally a transition layer;
(h) a further photovoltaic layer;
(i) optionally a smoothing layer;
(j) an anode;
(k) a substrate;
is concerned, the same techniques as discussed above may be used.

According to the present invention, it was found that it is not necessary to apply, in addition to a photovoltaic layer comprising a DPP polymer, a further layer which protects the photovoltaic layer and, therefore, the OPV device in total from degradation during using the OPV device; to the contrary, it was found that employing, as photovoltaic layer, a mixture which contains the DPP polymer and, simultaneously, at least one stabilizing agent which is preferably a UV absorbing agent or an anti-radical agent, and which, according to an even more preferred embodiment, is not a hindered amine light stabilizer (HALS), preferably not a hindered amine, it is possible the increase the product life of the organic photovoltaic device.

Therefore, the present invention also relates to the of a mixture comprising at least one stabilizing agent which is preferably a UV absorbing agent or an anti-radical agent, and at least one diketopyrrolopyrrole (DPP) polymer for increasing the product life of an organic photovoltaic (OPV) device containing the mixture in at least one photovoltaic layer.

Accordingly, the present invention also relates to a method of increasing the product life of an organic photovoltaic (OPV) device by using a mixture comprising at least one stabilizing agent which is preferably a UV absorbing agent or an anti-radical agent, and at least one diketopyrrolopyrrole (DPP) polymer as mixture contained in at least one photovoltaic layer of the OPV device.

As already discussed above, application of such additional protecting layer usually requires harsh conditions which have a detrimental impact on the photovoltaic layer onto which the protecting layer is applied. This significant disadvantage of the known technique can be overcome by the process according to the present invention and the OPV devices according to the present invention.

Therefore, the present invention also relates to the use of a mixture comprising at least one stabilizing agent which is preferably a UV absorbing agent or an anti-radical agent, and at least one diketopyrrolopyrrole (DPP) polymer for preventing the at least one DPP polymer from degradation during production of an OPV device containing the mixture in at least one photovoltaic layer.

Accordingly, the present invention also relates to a method of preventing at least one DPP polymer from degradation during production of an OPV device containing said at least one DPP polymer by using a mixture comprising at least one stabilizing agent which is preferably a UV absorbing agent or an anti-radical agent, and said at least one diketopyrrolopyrrole (DPP) polymer, the OPV device containing said mixture in at least one photovoltaic layer.

The present invention is illustrated by the following figures and examples.

### SHORT DESCRIPTION OF THE FIGURES

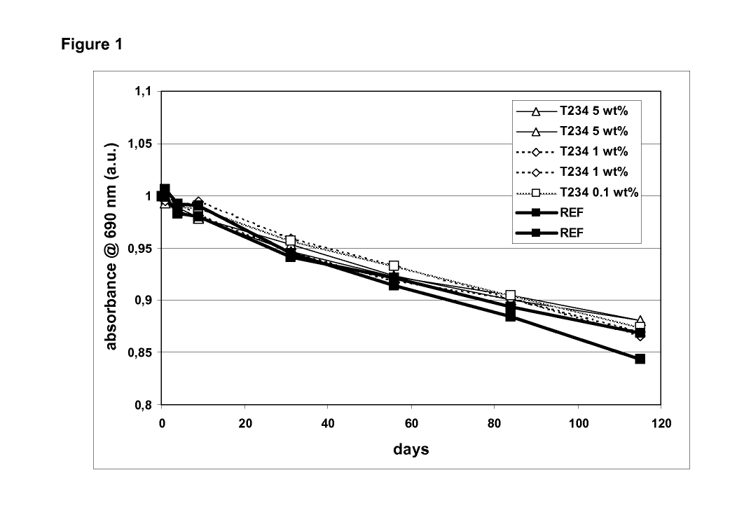

FIG. 1 shows the absorbance at a wavelength of 690 nm of the film prepared according to Example 2 with Tinuvin® 234 as stabilizing agent, dependent on the duration (in days) of exposure of the film to light of said wavelength. In FIG. 1, the followings symbols stand for:
open triangle: values for film containing 5 wt.-% Tinuvin® 234
open diamond: values for film containing 1 wt.-% Tinuvin® 234
open square: values for film containing 0.1 wt.-% Tinuvin® 234
filled square: reference values (no stabilizing agent in film)

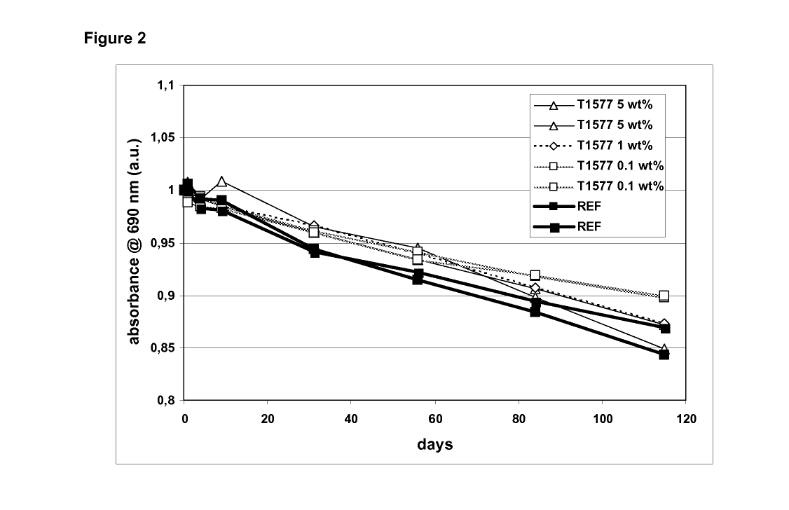

FIG. 2 shows the absorbance at a wavelength of 690 nm of the film prepared according to Example 2 with Tinuvin® 1577 as stabilizing agent, dependent on the duration (in days) of exposure of the film to light of said wavelength. In FIG. 2, the followings symbols stand for:
open triangle: values for film containing 5 wt.-% Tinuvin® 1577
open diamond: values for film containing 1 wt.-% Tinuvin® 1577
open square: values for film containing 0.1 wt.-% Tinuvin® 1577
filled square: reference values (no stabilizing agent in film)

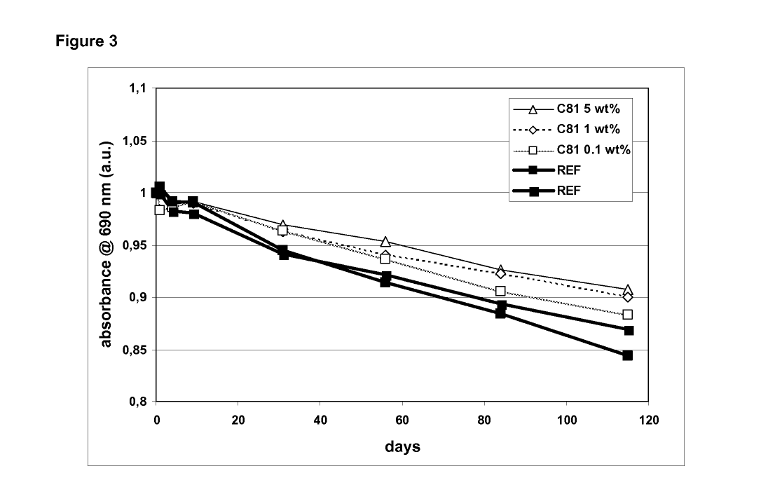

FIG. 3 shows the absorbance at a wavelength of 690 nm of the film prepared according to Example 2 with Chimassorb® 81 as stabilizing agent, dependent on the duration (in days) of exposure of the film to light of said wavelength. In FIG. 3, the followings symbols stand for:
open triangle: values for film containing 5 wt.-% Chimassorb® 81
open diamond: values for film containing 1 wt.-% Chimassorb® 81
open square: values for film containing 0.1 wt.-% Chimassorb® 81
filled square: reference values (no stabilizing agent in film)

### EXAMPLES

### Synthesis of DPP Polymer 8 (Formula Ic″, According to Example 16 of PCT/EP2011/057878):

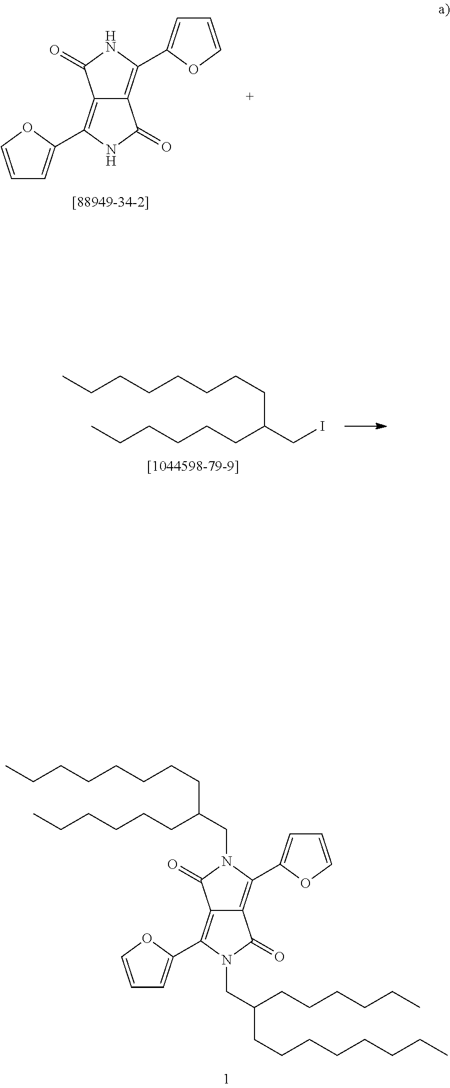 [SMILES: O=C1NC(c2ccco2)=C2C(=O)NC(c3ccco3)=C12 ; CCCCCCCCC(CI)CCCCCC ; CCCCCCCCC(CCCCCC)CN1C(=O)C2=C(c3ccco3)N(CC(CCCCCC)CCCCCCCC)C(=O)C2=C1c1ccco1]

20 g of the compound of CAS-No. 88949-34-2 and 25.76 g of potassium carbonate are suspended in 300 ml of dry dimethylformamide and the mixture is heated to 90° C. under nitrogen. Then 79 g of the compound of CAS-No. 1044598-79-9 are added drop wise. The reaction mixture is then stirred for 6 h at 90° C. After cooling to room temperature ethylacetate is added and the mixture is washed with water. The organic phase is dried over magnesium sulfate and the solvent is evaporated. The product is purified by column chromatography over silica to obtain a compound of formula 1. ¹H-NMR data (ppm, CDCl₃): 8.33 2H d, 7.60 2H d, 6.68 2H dxd, 4.03 4H d, 1.85-1.75 2H m, 1.45-1.15 48H m, 0.88 6H t, 0.86 6H t.

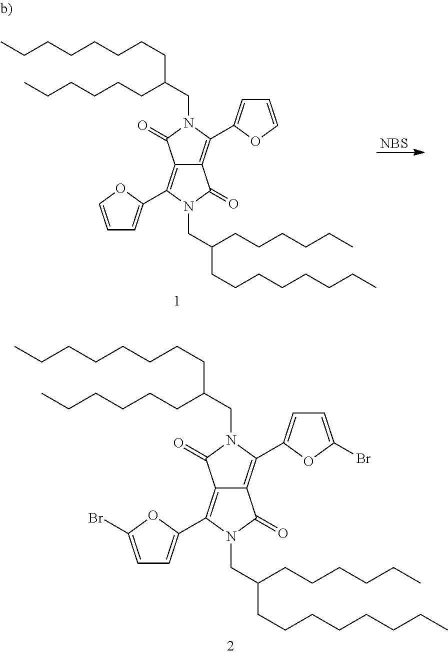

6.44 g of compound 1 are dissolved in 100 ml of chloroform. The mixture is cooled to −10° C. and then 1.99 g of N-bromo-succinimid (NBS) are added and the mixture is stirred for 2 hours at −10° C. The reaction mixture is washed with water, dried with magnesium sulfate and the solvent is evaporated. The crude product is purified by column chromatography over silica to obtain a compound of formula 2. ¹H-NMR data (ppm, benzene-D₆): 8.72 2H d, 6.05 2H d, 4.13 4H d, 2.06-2.02 2H m, 1.65-1.30 48H m, 1.01 6H t, 1.00 6H t.

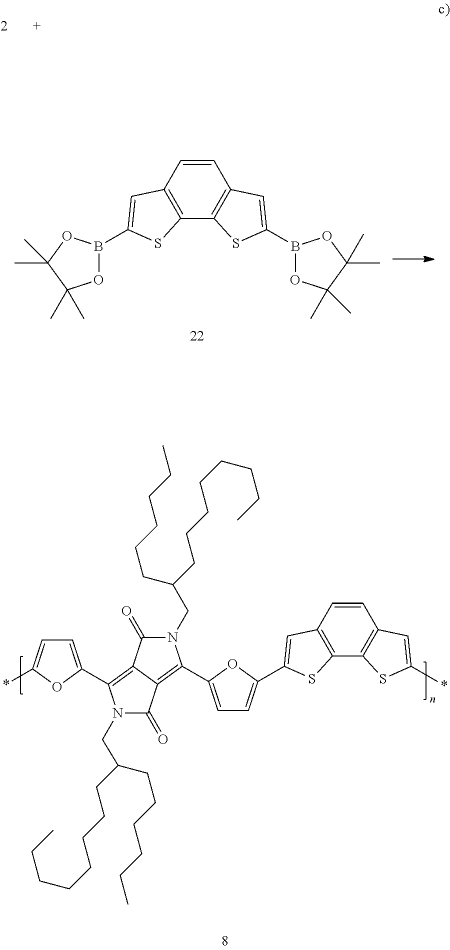

0.5 g of compound 2, 0.265 g of compound 22, and 51 mg of palladium acetate are added to a three necked reaction flask under an argon atmosphere. 15 ml of degassed THF is added to the reaction flask and the mixture is heated to dissolve the starting materials. After further degassing with Argon 27 mg of 2-(di-tert-butyl-phosphino)-1-phenyl-1H-pyrrole is added and the reaction mixture is heated to reflux. Then 146 mg of lithium hydroxide hydrate are added and the reaction mixture is stirred for 2 hours at reflux. The reaction mixture is then cooled to room temperature and the product is precipitated with methanol, filtered and washed with methanol. The polymer is purified by Soxhlet extraction using different solvents: tetrahydrofurane, chloroform and ortho-dichlorobenzene. 720 mg of the ortho-dichlorobenzene fraction contains the above polymer 8 of Mw of 100'000 and a polydispersity of 2.59 (measured by high temperature GPC).

Random copolymer 7 is prepared according to WO 2010/049323 A1 (Example 1, page 45, line 24 to page 47, line 9):

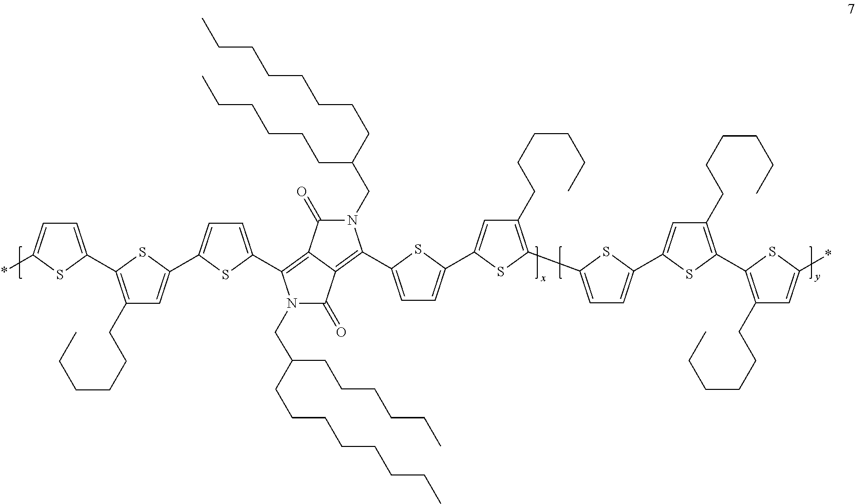

### Example 1

### Polymer Based Bulk Heterojunction Solar Cells

### Structure of the Solar Cells

The solar cells used have the following structures (in brackets: layer thickness):
(a) cathode: Al electrode (100 nm)
(b) transition layer: LiF layer (1 nm)
(c) photovoltaic layer: organic layer, comprising as DPP polymer the random copolymer 7-described in WO 2010/049323 A1; and [70]PCBM (95%, Solene BV) with or without stabilizing additives according to the table hereinunder;
(d) smoothing layer: [poly(3,4-ethylenedioxy-thiophene) (PEDOT) in admixture with poly(styrenesulfonic acid) (PSS)](70 nm, Clevios® AL4083, H.C.Starck)
(j) anode: ITO electrode (120 nm)
(k) substrate: glass substrate (1.1 mm)

The solar cells are made by spin coating a layer of the PEDOT-PSS on a pre-patterned ITO on the glass substrate. Then, a 1:1.5:“X” mixture of the random copolymer 7 (1% by weight): [70]PCBM:stabilizing additive is spin coated from o-dichlorobenzene (organic layer). Samples containing no stabilizing agent are used as reference. As to the amount of stabilizing agent (“X”), reference is made to the tables hereinunder. Different sets of experiments are made using the above procedure and the same type of DPP copolymer 7 but with slightly different molecular weight: batch (a) producing reference 1 and the samples containing Tinuvin® 234 or Tinuvin® 1577, batch (b) producing reference 2 and the samples containing Chimassorb® 81, Tinuvin® 120 or Tinuvin® 780; batch (c) producing reference 3 and the samples containing Tinuvin® 312 or Tinuvin® 622 or a UV absorber of the merocyanine class of CAS-No. 1243654-84-3 (all structures of stabilizing agents are shown further below). LiF and Al are sublimed under high vacuum through a shadow-mask.

### Solar Cell Performance

The solar cell is measured under a solar light simulator. Then, with the External Quantum Efficiency (EQE) graph, the current is estimated under AM1.5 conditions. This leads to a values reported in the tables below. In this table, the abbreviations stand for: short current density (Jsc); open circuit voltages (Voc); fill factor (FF); maximum power point (MPP).

The results show the functioning of the photoelectric cells in spite of the presence of stabilizing agent within the photosensitive layer. Similar results are obtained when using polymer 8 as the DPP polymer.

TABLE a

| Stabilizing | | Jsc | | | MPP |
|---|---|---|---|---|---|
| Additive | X [%] | [mA/cm²] | Voc [V] | FF [%] | [mW/cm²] |
| Reference 1 | 0 | 14.7 | 0.61 | 47.9 | 4.3 |
| Tinuvin ® 234 | 0.1 | 14.7 | 0.61 | 47.9 | 4.3 |
| | 1 | 13.5 | 0.61 | 50.0 | 4.15 |
| | 5 | 12.6 | 0.61 | 46.8 | 3.6 |
| Tinuvin ® 1577 | 0.1 | 14.7 | 0.61 | 50.7 | 4.55 |
| | 1 | 14.9 | 0.61 | 48.9 | 4.45 |
| | 5 | 13.4 | 0.61 | 42.8 | 3.5 |

TABLE b

| Stabilizing | | Jsc | | | MPP |
|---|---|---|---|---|---|
| Additive | X [%] | [mA/cm²] | Voc [V] | FF [%] | [mW/cm²] |
| Reference 2 | 0 | 13.9 | 0.61 | 41.2 | 3.5 |
| Chimassorb ® | 0.1 | 13.4 | 0.61 | 46.4 | 3.8 |
| 81 | 1 | 13.8 | 0.61 | 42.7 | 3.6 |
| | 5 | 9.4 | 0.61 | 27.9 | 1.6 |
| Tinuvin ® 120 | 0.1 | 14.0 | 0.61 | 49.1 | 4.2 |
| | 1 | 13.2 | 0.61 | 44.7 | 3.6 |
| | 5 | 11.2 | 0.61 | 3.8 | 2.6 |
| Tinuvin ® 780 | 0.1 | 12 | 0.61 | 21.8 | 1.6 |
| | 1 | 1.2 | 0.61 | 6.8 | 0.05 |
| | 5 | 0 | 0.61 | 0 | 0 |

TABLE c

| | | Jsc | | | MPP |
|---|---|---|---|---|---|
| Additive | X [%] | [mA/cm²] | Voc [V] | FF [%] | [mW/cm²] |
| Reference 3 | 0 | 14.2 | 0.61 | 56.3 | 4.9 |
| Tinuvin ® 312 | 0.1 | 13.5 | 0.61 | 53.1 | 4.4 |
| | 1 | 14.6 | 0.61 | 55.9 | 5.0 |
| | 5 | 13.5 | 0.63 | 45.2 | 3.8 |
| Tinuvin ® 622 | 0.1 | 14.4 | 0.6 | 44.7 | 3.9 |
| | 1 | 0.5 | 0.11 | 18.7 | 0 |
| | 5 | 0 | 0.27 | 17.6 | 0 |
| Merocyanine | 0.1 | 14.5 | 0.62 | 58.0 | 5.2 |
| | 1 | 7.7 | 0.60 | 51.7 | 2.4 |
| | 5 | 9.9 | 0.63 | 46.6 | 2.9 |

### Structures of the Stabilizing Agents Used

Tinuvin® 234: 2-(2H-benzotriazol-2-yl)-4,6-bis(1-methyl-1-phenylethyl)phenol

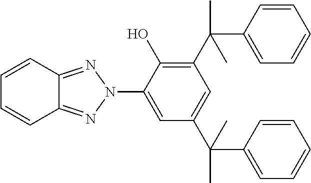 [SMILES: CC(C)(c1ccccc1)c1cc(-n2nc3ccccc3n2)c(O)c(C(C)(C)c2ccccc2)c1]

Tinuvin® 1577: 2-(2-hydroxy-4-hexyloxy)phenyl-4,6-diphenyl-1,3,5-triazine

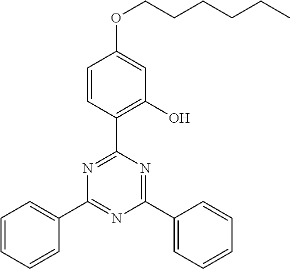 [SMILES: CCCCCCOc1ccc(-c2nc(-c3ccccc3)nc(-c3ccccc3)n2)c(O)c1]

Chimassorb® 81: 2-hydroxy-4-octyloxy-benzophenone

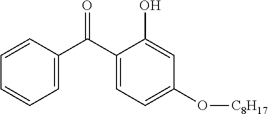

Tinuvin® 120: 2′,4′-Di-tert-butylphenyl 3,5-di-tert-butyl-4-hydroxybenzoate

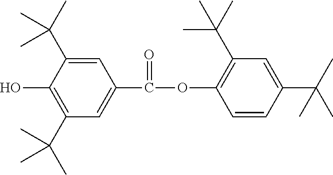 [SMILES: CC(C)(C)c1ccc(OC(=O)c2cc(C(C)(C)C)c(O)c(C(C)(C)C)c2)c(C(C)(C)C)c1]

Tinuvin® 780: bis(2,2,6,6-tetramethylpiperidin-4-yl) butanedioate

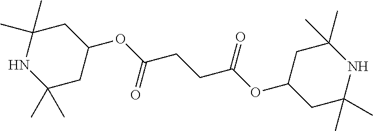

Tinuvin® 312: 2-ethoxy-2′-ethyl-oxanilide:

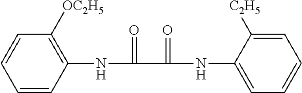 [SMILES: CCOc1ccccc1NC(=O)C(=O)Nc1ccccc1CC]

Tinuvin® 622 is a polymer with the repeating unit:

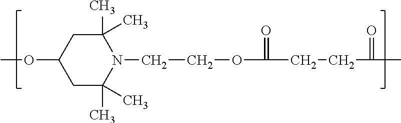

(CAS-No. 65447-77-0)

Merocyanine CAS-No. 1243654-84-3:

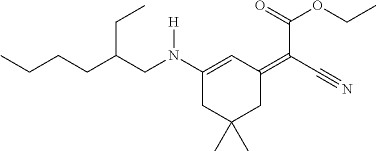 [SMILES: CCCCC(CC)CNC1=C/C(=C(/C#N)C(=O)OCC)CC(C)(C)C1]

(compound MC-03 of WO 09/027,258)

### Example 2

### Photo-Oxidation Stability Tests for Films

### Films Used

The photo-oxidation stability of films is tested, said films containing as DPP polymer the random copolymer 7—described in and prepared according to WO 2010/049323 A1, Example 1, page 45, line 24 to page 47, line 9.

The films are made by spin-coating (600 rpm, 2 min.) the DPP polymer (1% by weight) in o-dichlorobenzene onto glass substrates (50×50×1 mm microscope slides), together with the specified amount “X” of stabilizing agent (wt % with respect to the weight of the DPP polymer). Stabilizing agents are as identified in below Tables d and e (see also FIG. 3).

Subsequently, after drying of the film, a protective layer of poly(methyl methacrylate) (PMMA, 4% by weight in butylacetate) is spin-coated (1000 rpm, 30 s) on top. The sample films are left in air and normal atmosphere and the degradation of the films is followed by UV-VIS spectroscopy (Varian Cary® 100 Scan). The results are shown in FIGS. 1 to 3 and below tables d and e.

### Results

By following the slopes of the degradation in FIGS. 1 to 3, it can be seen that by addition of each of the stabilizing agents the film stability may be improved. Best results are achieved using UV absorbers, especially the benzophenone-type UV absorber (Chimassorb® 81) whose addition inhibits degradation very well and whose effect is concentration dependent (higher=better).

Photooxidation is determined numerically by measuring the absorbance of the DPP polymer at 690 nm. The absorption peak decreases upon exposure to oxidation. Results are shown in the below Tables d and e for exposure times of 115 days and 56 days, respectively. UV-absorbers provide good protection against photo-oxidation. An effect is further achieved by addition of phenolic antioxidant (Tinuvin® 120) or hindered amine light stabilizer (HALS; Tinuvin® 780), especially in low concentration.

TABLE d

| | | Absorption at 690 nm after |
|---|---|---|
| Additive | X [%] | 115 days [%] |
| none | 0 | 86.9 |
| Chimassorb ® | 0.1 | 88.3 |
| 81 | 1 | 90.0 |
| | 5 | 90.8 |
| Tinuvin ® 234 | 0.1 | 87.4 |
| Tinuvin ® 1577 | 0.1 | 89.9 |
| Tinuvin ® 120 | 0.1 | 87.8 |
| Tinuvin ® 780 | 0.1 | 87.4 |

TABLE e

| | | Absorption at 690 nm after |
|---|---|---|
| Additive | X [%] | 56 days [%] |
| Tinuvin ® 312 | 0.1 | 96.3 |
| Tinuvin ® 622 | 0.1 | 94.4 |
| Merocyanine | 0.1 | 95.6 |
| | 1 | 95.8 |
| | 5 | 96.9 |

Similar results are obtained when using polymer 8 as the DPP polymer.

### CITED DOCUMENTS

WO 2008/000664 A1
WO 2010/049321 A1
WO 2010/049323 A1
WO 96/28431 A1
EP 0 323 408 A1
EP 0 057 160 A1
U.S. Pat. No. 5,736,597
EP 0 434 608 A1
U.S. Pat. No. 4,619,956
DE 31 35 810 A1
GB 1 336 391 A
N. Miyaura and A. Suzuki in Chemical Reviews, Vol. 95, pp. 457-2483 (1995)
Leadbeater & Marco; Angew. Chem. Int. Ed. Eng. 42 (2003) 1407
T. I. Wallow and B. M. Novak in J. Org. Chem. 59 (1994) 5034-5037
M. Remmers, M. Schulze, G. Wegner, Macromol. Rapid Commun. 17 (1996) 239-252
Babudri et al, J. Mater. Chem., 2004, 14, 11-34
J. K. Stille, Angew. Chemie Int. Ed. Engl. 1986, 25, 508
T. Hiyama et al., Pure Appl. Chem. 66 (1994) 1471-1478
T. Hiyama et al., Synlett (1991) 845-853
EP 0 648 770 A
EP 0 648 817 A
EP 0 742 255 A
EP 0 761 772 A
WO 98/32802
WO 98/45757
WO 98/58027
WO 99/01511
WO 00/17275
WO 00/39221
WO 00/63297
EP 1 086 984 A
WO 00/36210
WO 2009/047104
U.S. Pat. No. 5,354,869
WO 03/022848
U.S. Pat. No. 6,420,031 B1
U.S. Pat. No. 5,703,436 B1
US 20070079867 A1
US 20060013549 A1
U.S. Pat. No. 6,933,436 B1
App. Phys. Let. 90, 143512 (2007)
Adv. Funct. Mater. 16, 1897-1903 (2006)
WO 2004/112161.

1. An organic photovoltaic device comprising at least one photovoltaic layer, said layer comprising a mixture which comprises at least one diketopyrrolopyrrole polymer and at least one stabilizing agent.

2. The device of claim 1, wherein the mixture comprises at least one stabilizing agent selected from the group consisting of UV absorbing agents and anti-radical agents, which agents are selected from the group consisting of hydroxybenzophenones, hydroxyphenyl benzotriazoles, oxalic acid anilides, hydroxyphenyl triazines, merocyanines, hindered phenols and mixtures of two or more thereof.

3. The device of claim 2, wherein the mixture comprises at least one UV absorbing agent selected from the group consisting of
2-hydroxybenzophenones of formula I; 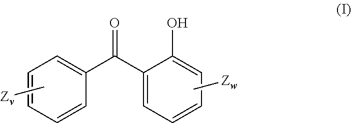
2-hydroxyphenylbenzotriazoles of formula IIa, IIb or IIc; 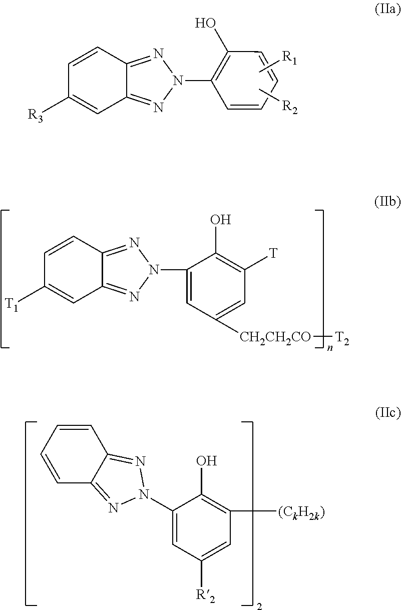
2-hydroxyphenyltriazines of formula III; 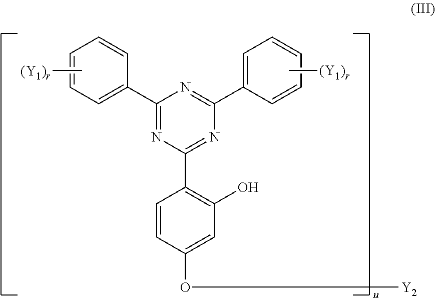
oxanilides of formula (IV) 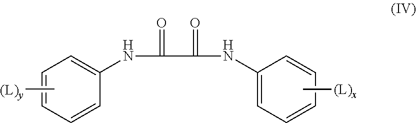
and
merocyanines of formula V; 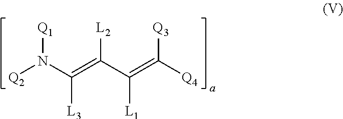
including E,E-, E,Z- and Z,Z-geometrical isomers thereof;
wherein
in the compounds of the formula (I),
v is an integer from 1 to 3 and w is 1 or 2 and the substituents Z independently of one another are hydrogen, halogen, hydroxyl or alkoxy having 1 to 12 carbon atoms;
in the compounds of the formula (IIa),
R₁ is hydrogen, alkyl having 1 to 24 carbon atoms, phenylalkyl having 1 to 4 carbon atoms in the alkyl moiety, cycloalkyl having 5 to 8 carbon atoms or a radical of formula 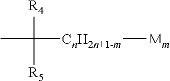
in which
R₄ and R₅ independently of one another are alkyl having in each case 1 to 5 carbon atoms or R₄, together with the radical CₙH₂ₙ₊₁₋ₘ, forms a cycloalkyl radical having 5 to 12 carbon atoms,
m is 1 or 2, n is an integer from 2 to 20 and
M is a radical of the formula —COOR₆ in which
R₆ is hydrogen, alkyl having 1 to 12 carbon atoms, alkoxyalkyl having in each case 1 to 20 carbon atoms in the alkyl moiety and in the alkoxy moiety or phenylalkyl having 1 to 4 carbon atoms in the alkyl moiety,
R₂ is hydrogen, halogen, alkyl having 1 to 18 carbon atoms, alkyl of 2 to 4 carbon atoms substituted by C₂-C₆alkanoyloxy or C₃-C₆alkenoyloxy or phenylalkyl having 1 to 4 carbon atoms in the alkyl moiety and
R₃ is hydrogen, chlorine, alkyl or alkoxy having in each case 1 to 4 carbon atoms or —COOR₆ in which R₆ is as defined above, with at least one of the radicals R₁ and R₂ being other than hydrogen;
in the compounds of the formula (IIb),
T is hydrogen or alkyl having 1 to 6 carbon atoms,
T₁ is hydrogen, chloro or alkyl or alkoxy having in each case 1 to 4 carbon atoms,
n is 1 or 2 and
if n is 1,
T₂ is chloro or a radical of the formula —OT₃ or 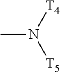
and
if n is 2, T₂ is a radical of the formula 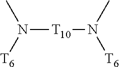
in which
T₃ is hydrogen, alkyl which has 1 to 18 carbon atoms and which is unsubstituted or is substituted by 1 to 3 hydroxyl groups or by —OCOT₆, alkyl which has 3 to 18 carbon atoms which is interrupted once or several times by —O— or —NT₆- and is unsubstituted or substituted by hydroxyl or —OCOT₆, cycloalkyl which has 5 to 12 carbon atoms and is unsubstituted or substituted by hydroxyl and/or alkyl having 1 to 4 carbon atoms, alkenyl which has 2 to 18 carbon atoms and is unsubstituted or substituted by hydroxyl, phenylalkyl having 1 to 4 carbon atoms in the alkyl moiety or a radical of formula —CH₂CH(OH)-T₇ or 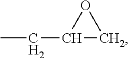
T₄ and T₅ independently of one another are hydrogen, alkyl having 1 to 18 carbon atoms, alkyl which has 3 to 18 carbon atoms and is interrupted once or several times by —O— or
—NT₆-, cycloalkyl having 5 to 12 carbon atoms, phenyl, phenyl which is substituted by alkyl having 1 to 4 carbon atoms, alkenyl having 3 to 8 carbon atoms, phenylalkyl having 1 to 4 carbon atoms in the alkyl moiety or hydroxyalkyl having 2 to 4 carbon atoms,
T₆ is hydrogen, alkyl having 1 to 18 carbon atoms, cycloalkyl having 5 to 12 carbon atoms, alkenyl having 3 to 8 carbon atoms, phenyl, phenyl which is substituted by alkyl having 1 to 4 carbon atoms or phenylalkyl having 1 to 4 carbon atoms in the alkyl moiety,
T₇ is hydrogen, alkyl having 1 to 18 carbon atoms, phenyl which is unsubstituted or substituted by hydroxyl, phenylalkyl having 1 to 4 carbon atoms in the alkyl moiety or —CH₂OT₈,
T₈ is alkyl having 1 to 18 carbon atoms, alkenyl having 3 to 8 carbon atoms, cycloalkyl having 5 to 10 carbon atoms, phenyl, phenyl which is substituted by alkyl having 1 to 4 carbon atoms or phenylalkyl having 1 to 4 carbon atoms in the alkyl moiety,
T₉ is alkylene having 2 to 8 carbon atoms, alkenylene having 4 to 8 carbon atoms, alkynylene having 4 carbon atoms, cyclohexylene, alkylene which has 2 to 8 carbon atoms and is interrupted once or several times by —O— or a radical of the formula —CH₂CH(OH)CH₂OT₁₁OCH₂CH(OH)CH₂— or —CH₂—C(CH₂OH)₂—CH₂—,
T₁₀ is alkylene which has 2 to 20 carbon atoms and can be interrupted once or several times by —O— or cyclohexylene and
T₁₁ is alkylene having 2 to 8 carbon atoms, alkylene which has 2 to 18 carbon atoms and is interrupted once or several times by —O—, 1,3-cyclohexylene, 1,4-cyclohexylene, 1,3-phenylene or 1,4-phenylene or
T₁₀ and T₆, together with the two nitrogen atoms, are a piperazine ring;
in the compounds of formula (IIc),
R′₂ is C₁-C₁₂alkyl and k is a number from 1 to 4;
in the compounds of the formula (III),
u is 1 or 2 and r is an integer from 1 to 3, the substituents
Y₁ independently of one another are hydrogen, hydroxyl, phenyl or halogen, halogenomethyl, alkyl having 1 to 12 carbon atoms, alkoxy having 1 to 18 carbon atoms or alkoxy having 1 to 18 carbon atoms which is substituted by a group —COO(C₁-C₁₈alkyl) and
if u is 1,
Y₂ is alkyl having 1 to 18 carbon atoms, phenyl which is unsubstituted or substituted by hydroxyl, halogen or alkyl or alkoxy having 1 to 18 carbon atoms; alkyl which has 1 to 12 carbon atoms and is substituted by —COOH, —COOY₈, —CONH₂, —CONHY₉, —CONY₉Y₁₀, —NH₂, —NHY₉, —NY₉Y₁₀, —NHCOY₁₁, —CN and/or —OCOY₁₁; alkyl which has 4 to 20 carbon atoms which is interrupted by one or more oxygen atoms and is unsubstituted or substituted by hydroxyl or alkoxy having 1 to 12 carbon atoms, alkenyl having 3 to 6 carbon atoms, glycidyl, cyclohexyl which is unsubstituted or substituted by hydroxyl, alkyl having 1 to 4 carbon atoms and/or —OCOY₁₁, phenylalkyl which has 1 to 5 carbon atoms in the alkyl moiety and is unsubstituted or substituted by hydroxyl, chlorine and/or methyl, —COY₁₂ or —SO₂Y₁₃ or
if u is 2,
Y₂ is alkylene having 2 to 16 carbon atoms, alkenylene having 4 to 12 carbon atoms, xylylene, alkylene which has 3 to 20 carbon atoms which is interrupted by one or more —O— atoms and/or is substituted by hydroxyl, —CH₂CH(OH)CH₂—O—Y₁₅—OCH₂CH(OH)CH₂, —CO—Y₁₆—CO—, —CO—NH—Y₁₇—NH—CO— or —(CH₂)ₘ—CO₂—Y₁₈—OCO—(CH₂)ₘ, in which
m is 1, 2 or 3,
Y₈ is alkyl having 1 to 18 carbon atoms, alkenyl having 3 to 18 carbon atoms, alkyl which has 3 to 20 carbon atoms which is interrupted by one or more oxygen or sulfur atoms or —NT₆- and/or is substituted by hydroxyl, alkyl which has 1 to 4 carbon atoms and is substituted by —P(O)(OY₁₄)₂, —NY₉Y₁₀ or —OCOY₁₁ and/or hydroxyl, glycidyl or phenylalkyl having 1 to 5 carbon atoms in the alkyl moiety,
Y₉ and Y₁₀ independently of one another are alkyl having 1 to 12 carbon atoms, alkoxyalkyl having 3 to 12 carbon atoms, dialkylaminoalkyl having 4 to 16 carbon atoms or cyclohexyl having 5 to 12 carbon atoms, or Y₉ and Y₁₀ together are alkylene, oxaalkylene or azaalkylene having in each case 3 to 9 carbon atoms,
Y₁₁ is alkyl having 1 to 18 carbon atoms, alkenyl having 2 to 18 carbon atoms or phenyl,
Y₁₂ is alkyl having 1 to 18 carbon atoms, alkenyl having 2 to 18 carbon atoms, phenyl, alkoxy having 1 to 12 carbon atoms, phenoxy, alkylamino having 1 to 12 carbon atoms or phenylamino,
Y₁₃ is alkyl having 1 to 18 carbon atoms, phenyl or alkylphenyl having 1 to 8 carbon atoms in the alkyl radical,
Y₁₄ is alkyl having 1 to 12 carbon atoms or phenyl,
Y₁₅ is alkylene having 2 to 10 carbon atoms, phenylene or a group -phenylene-M-phenylene- in which M is —O—, —S—, —SO₂—, —CH₂— or —C(CH₃)₂—,
Y₁₆ is alkylene, oxaalkylene or thiaalkylene having in each case 2 to 10 carbon atoms, phenylene or alkenylene having 2 to 6 carbon atoms,
Y₁₇ is alkylene having 2 to 10 carbon atoms, phenylene or alkylphenylene having 1 to 11 carbon atoms in the alkyl moiety and
Y₁₈ is alkylene having 2 to 10 carbon atoms or alkylene which has 4 to 20 carbon atoms and is interrupted once or several times by oxygen;
in the compounds of the formula (IV),
x is an integer from 1 to 3 and the substituents L independently of one another are hydrogen, alkyl, alkoxy or alkylthio having in each case 1 to 22 carbon atoms, phenoxy or phenylthio and
in the compounds of formula (V),
Q₁ and Q₂ independently of each other are hydrogen; C₁-C₂₂alkyl; C₂-C₂₂ alkenyl, C₂-C₂₂alkinyl, C₃-C₁₂cycloalkyl, C₃-C₁₂cycloalkenyl, C₇-C₂₀aralkyl, C₁-C₂₀heteroalkyl, C₃-C₁₂cycloheteroalkyl, C₅-C₁₁heteroaralkyl, C₆-C₂₀aryl, C₄-C₉heteroaryl, COQ₁₃ or CONQ₁₃Q₁₄;
Q₃ is CN; —COOQ₅; —CONHQ₅; —COQ₅; —SO₂Q₅; —CONQ₅Q₆; C₆-C₂₀aryl or C₄-C₉ heteroaryl;
Q₄ is CN; —COOQ₇; —CONHQ₇; —COQ₇; —SO₂Q₇; —CONQ₇Q₈; C₁-C₂₂ alkyl; C₂-C₂₂alkenyl; C₂-C₂₂ alkinyl; C₃-C₁₂cycloalkyl; C₃-C₁₂cycloalkenyl; C₇-C₂₀aralkyl; C₁-C₂₀heteroalkyl; C₃-C₁₂cycloheteroalkyl; C₅-C₁₁ heteroaralkyl; C₆-C₂₀ aryl or C₄-C₉ heteroaryl;
Q₅, Q₆, Q₇ and Q₈ independently of each other are hydrogen; C₁-C₂₂alkyl; C₂-C₂₂alkenyl; C₂-C₂₂ alkinyl; C₃-C₁₂cycloalkyl; C₃-C₁₂cycloalkenyl; C₇-C₂₀aralkyl; C₁-C₂₀heteroalkyl, C₃-C₁₂cycloheteroalkyl; C₅-C₁₁heteroaralkyl; C₆-C₂₀aryl; C₄-C₉heteroaryl; SiQ₁₅Q₁₆Q₁₇; Si(OQ₁₅)(OQ₁₆)(OQ₁₇); SiQ₁₅(OQ₁₆)(OQ₁₇); SiQ₁₅Q₁₆(OQ₁₇) or a radical —XS;
L₁, L₂ and L₃ independently of each other are hydrogen, C₁-C₂₂alkyl; C₂-C₂₂alkenyl, C₂-C₂₂alkinyl; C₃-C₁₂cycloalkyl; C₃-C₁₂cycloalkenyl; C₇-C₂₀aralkyl; C₁-C₂₀heteroalkyl; C₃-C₁₂cycloheteroalkyl; C₅-C₁₁heteroaralkyl; C₆-C₂₀aryl; C₄-C₉heteroaryl; CN; OH; OQ₉ or COOQ₉;
Q₉ is hydrogen; C₁-C₂₂alkyl; C₂-C₂₂alkenyl; C₂-C₂₂alkinyl; C₃-C₁₂cycloalkyl; C₃-C₁₂cycloalkenyl; C₇-C₂₀aralkyl; C₁-C₂₀heteroalkyl; C₃-C₁₂cycloheteroalkyl; C₅-C₁₁heteroaralkyl; C₆-C₂₀ aryl or C₄-C₉heteroaryl;
L₁ and L₂, L₁ and L₃, L₂ and L₃, L₁ and Q₄, L₂ and Q₄, L₁ and Q₁, L₂ and Q₁, L₃ and Q₁, L₃ and Q₅, Q₃ and Q₄, Q₁ and Q₂, Q₇ and Q₈ and Q₅ and Q₆ may be linked together to form 1, 2, 3 or 4 carbocyclic or N, O and/or S-heterocyclic rings, which may be further fused with other aromatic rings;
Q₁₀ represents Q₁₃; COQ₁₃; COOQ₁₃; CONH₂; CONHQ₁₃ or CONQ₁₃Q₁₄;
Q₁₁ represents halogen; OH; NH₂; NHQ₁₅; NQ₁₅Q₁₆; NQ₁₅OQ₁₆; O-Q₁₅; O—CO-Q₁₅; S-Q₁₅; CO-Q₁₅; oxo; thiono; CN; COOH; CONH₂; COOQ₁₅; CONHQ₁₅; CONQ₁₅Q₁₆; SO₂NH₂; SO₂NHQ₁₅; SO₂NQ₁₅Q₁₆;
SO₂Q₁₅; SO₃Q₁₅; SiQ₁₅Q₁₆Q₁₇; SiOQ₁₅(OQ₁₆)(OQ₁₇); SiQ₁₅(OQ₁₆)(OQ₁₇); SiQ₁₅Q₁₆(OQ₁₇); O—Si-Q₁₅Q₁₆Q₁₇; O—Si—OQ₁₅(OQ₁₆)(OQ₁₇); O—Si-Q₁₅Q₁₆(OQ₁₇); O—SiQ₁₅(OQ₁₆)(OQ₁₇); PO(OQ₁₅)(OQ₁₆) or a radical *—XS;
Q₁₂ represents halogen, CN, SH, OH, CHO, Q₁₈; OQ₁₈; SQ₁₈; C(Q₁₈)=CQ₁₉Q₂₀; O—CO-Q₁₉; NHQ₁₉; NQ₁₈Q₁₉; CONH₂; CONHQ₁₈; CONQ₁₈Q₁₉; SO₂NH₂; SO₂NHQ₁₈; SO₂NQ₁₈Q₁₉; SO₂Q₁₈; COOH; COOQ₁₈; OCOOQ₁₈; NHCOQ₁₈; NQ₁₈COQ₁₉; NHCOOQ₁₉; NQ₁₉COOQ₂₀; SiQ₁₅Q₁₆Q₁₇; SiOQ₁₅(OQ₁₆)(OQ₁₇); SiQ₁₅(OQ₁₆)(OQ₁₇); SiQ₁₅Q₁₆(OQ₁₇); OSi Q₁₅Q₁₆Q₁₇; OSiOQ₁₅(OQ₁₆)(OQ₁₇); OSiQ₁₅Q₁₆(OQ₁₇); OSiQ₁₅(OQ₁₆)(OQ₁₇); P(═O)OQ₁₉Q₂₀; P(═O)Q₁₉OQ₂₀; P(═O)Q₁₉Q₂₀; or a radical —XS; or is selected from the group consisting of C₁-C₂₂alkyl; C₃-C₁₂cycloalkyl; C₁-C₁₂alkenyl; C₃-C₁₂cycloalkenyl; C₁-C₁₂alkylthio; C₃-C₁₂cycloalkylthio; C₁-C₁₂alkenylthio; C₃-C₁₂cycloalkenylthio; C₁-C₁₂alkoxy; C₃-C₁₂cycloalkoxy; C₁-C₁₂alkenyloxy; or C₃-C₁₂cycloalkenyloxy, which may be unsubstituted or substituted by one or more, identical or different Q₁₁;
Q₁₃, Q₁₄, Q₁₅, Q₁₆, Q₁₇, Q₁₈, Q₁₉ and Q₂₀ independently of each other are C₁-C₂₂alkyl; C₃-C₁₂cycloalkyl; C₂-C₁₂alkenyl; C₃-C₁₂cycloalkenyl; C₆-C₁₄aryl; C₄-C₁₂heteroaryl; C₇-C₁₈aralkyl or C₅-C₁₆heteroaralkyl; or
Q₁₃ and Q₁₄, Q₁₅ and Q₁₆, Q₁₆ and Q₁₇ and/or Q₁₈ and Q₁₉ may be linked together to form unsubstituted or with C₁-C₄alkyl substituted pyrrolidine, piperidine, piperazine or morpholine;
X represents a linker;
S signifies a silane-, oligosiloxane- or polysiloxane-moiety
where the term “oligosiloxane” denotes a group of formula Si(Q₁₅)ₘ[OSi(Q₁₆)]ₒ wherein
m has a value of 0, 1 or 2,
o has a value of 3, 2 or 1 and m+o have a value of 3, or refers to groups of formula 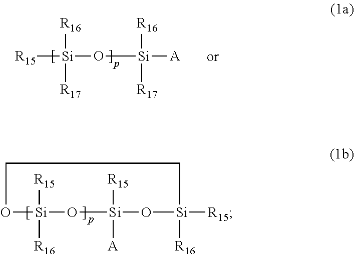
wherein
A represents a bond to the linker X and
p has a value of 1 to 9;
the term “polysiloxane” refers to groups of formula 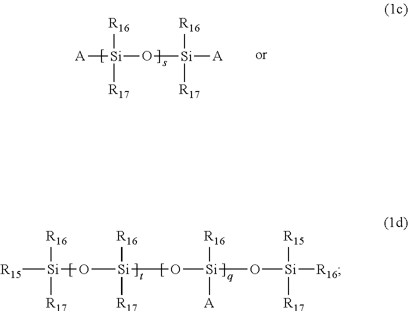
wherein
A represents a bond to the linker X;
s has a value of 4 to 250;
t has a value of 5 to 250;
q has a value of 1 to 30; and
a is from 1 to 4;
when a=2, Q₁, Q₅ or Q₄ is a bivalent alkyl group; or Q₁ and Q₂ together with the 2 nitrogen atoms linking them form a unsubstituted or alkyl-substituted 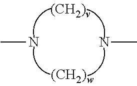
ring where
v is from 1 to 4 and
w is from 1 to 4;
when a=3, Q₁, Q₅ or Q₄ is a trivalent alkyl group and
when a=4, Q₁, Q₅ or Q₄ is a tetravalent alkyl group; and
Q₁ and Q₂ in formula V are not simultaneously hydrogen.

4. The device of claim 3, wherein
the 2-hydroxybenzophenones are selected from group consisting of 4-hydroxy, 4-methoxy, 4-octyloxy, 4-decyloxy, 4-dodecyloxy, 4-benzyloxy and 2′-hydroxy-4,4′-dimethoxy derivatives of 2-hydroxybenzophenone;
the 2-hydroxyphenylbenzotriazoles are selected from the group consisting of 2-(2′-hydroxy-5′-methylphenyl)-benzotriazole, 2-(3′,5′-di-tert-butyl-2′-hydroxyphenyl)benzotriazole, 2-(5′-tert-butyl-2′-hydroxyphenyl)benzotriazole, 2-(2′-hydroxy-5′-(1,1,3,3-tetramethylbutyl)phenyl)benzotriazole, 2-(3′,5′-di-tert-butyl-2′-hydroxyphenyl)-5-chloro-benzotriazole, 2-(3′-tert-butyl-2′-hydroxy-5′-methylphenyl)-5-chloro-benzotriazole, 2-(3′-sec-butyl-5′-tert-butyl-2′-hydroxyphenyl)benzotriazole, 2-(2′-hydroxy-4′-octyloxyphenyl)benzotriazole, 2-(3′,5′-di-tert-amyl-2′-hydroxyphenyl)benzotriazole, 2-(3′,5′-bis-(alpha,alpha-dimethylbenzyl)-2′-hydroxyphenyl)benzotriazole, 2-(3′-tert-butyl-2′-hydroxy-5′-(2-octyloxycarbonylethyl)phenyl)-5-chloro-benzotriazole, 2-(3′-tert-butyl-5′-[2-(2-ethylhexyloxy)-carbonylethyl]-2′-hydroxyphenyl)-5-chloro-benzotriazole, 2-(3′-tert-butyl-2′-hydroxy-5′-(2-methoxycarbonylethyl)phenyl)-5-chloro-benzotriazole, 2-(3′-tert-butyl-2′-hydroxy-5′-(2-meth-oxycarbonylethyl)phenyl)benzotriazole, 2-(3′-tert-butyl-2′-hydroxy-5′-(2-octyloxycarbonyl-ethyl)phenyl)benzotriazole, 2-(3′-tert-butyl-5′-[2-(2-ethylhexyloxy)carbonylethyl]-2′-hydroxy-phenyl)benzotriazole, 2-(3′-dodecyl-2′-hydroxy-5′-methylphenyl)benzotriazole, 2-(3′-tert-butyl-2′-hydroxy-5′-(2-isooctyloxycarbonylethyl)phenylbenzotriazole, 2,2′-methylene-bis[4-(1,1,3,3-tetramethylbutyl)-6-benzotriazole-2-ylphenol]; the transesterification product of 2-[3′-tert-butyl-5′-(2-methoxycarbonylethyl)-2′-hydroxyphenyl]-2H-benzotriazole with polyethylene glycol 300;
[R—CH₂CH₂—COO—CH₂CH₂CH₂₂ where R=3′-tert-butyl-4′-hydroxy-5′-2H-benzotriazol-2-ylphenyl, 2-[2′-hydroxy-3′-(alpha,alpha-dimethylbenzyl)-5′-(1,1,3,3-tetramethylbutyl)-phenyl]benzotriazole; 5-trifluoromethyl-2-(2-hydroxy-3-alpha-cumyl-5-tert-octylphenyl)-2H-benzotriazole and 2-[2′-hydroxy-3′-(1,1,3,3-tetramethylbutyl)-5′-(alpha,alpha-dimethylbenzyl)-phenyl]benzotriazole;
the 2-hydroxyphenyltriazines are selected from the group consisting of 2,4,6-tris(2-hydroxy-4-octyloxyphenyl)-1,3,5-triazine, 2-(2-hydroxy-4-octyloxyphenyl)-4,6-bis(2,4-dimethylphenyl)-1,3,5-triazine, 2-(2,4-dihydroxyphenyl)-4,6-bis(2,4-dimethylphenyl)-1,3,5-triazine, 2,4-bis-(2-hydroxy-4-propyloxyphenyl)-6-(2,4-dimethylphenyl)-1,3,5-triazine, 2-(2-hydroxy-4-octyloxyphenyl)-4,6-bis(4-methylphenyl)-1,3,5-triazine, 2-(2-hydroxy-4-dodecyloxyphenyl)-4,6-bis(2,4-dimethylphenyl)-1,3,5-triazine, 2-(2-hydroxy-4-tridecyloxyphenyl)-4,6-bis(2,4-dimethylphenyl)-1,3,5-triazine, 2-[2-hydroxy-4-(2-hydroxy-3-butyloxy-propoxy)phenyl]-4,6-bis(2,4-dimethylphenyl)-1,3,5-triazine, 2-[2-hydroxy-4-(2-hydroxy-3-octyloxy-propyloxy)phenyl]-4,6-bis(2,4-dimethylphenyl)-1,3,5-triazine, 2-[4-(3-dodecyloxy/tridecyloxy-2-hydroxypropoxy)-2-hydroxy-phenyl]-4,6-bis(2,4-dimethylphenyl)-1,3,5-triazine, 2-[2-hydroxy-4-(2-hydroxy-3-dodecyloxy-propoxy)phenyl]-4,6-bis(2,4-dimethylphenyl)-1,3,5-triazine, 2-(2-hydroxy-4-hexyloxy)phenyl-4,6-diphenyl-1,3,5-triazine, 2-(2-hydroxy-4-methoxyphenyl)-4,6-diphenyl-1,3,5-triazine, 2,4,6-tris[2-hydroxy-4-(3-butoxy-2-hydroxy-propoxy)phenyl]-1,3,5-triazine, 2-(2-hydroxyphenyl)-4-(4-methoxyphenyl)-6-phenyl-1,3,5-triazine, 2-{2-hydroxy-4-[3-(2-ethylhexyl-1-oxy)-2-hydroxypropyloxy]phenyl}-4,6-bis(2,4-dimethylphenyl)-1,3,5-triazine, 2-(2-hydroxy-4-(2-ethyl-hexyl)oxy)phenyl-4,6-di(4-phenyl)phenyl-1,3,5-triazine, 2,4-bis-[(4-(2-ethylhexyloxy)-2-hydroxyphenyl)]-6-(4-methoxyphenyl)-1,3,5-triazine), 2,4-bis-[(4-(2-hydroxyethyloxy)-2-hydroxyphenyl)]-6-(4-chlorophenyl)-1,3,5-triazine), 2,4-bis-(4-butyloxy-2-hydroxyphenyl)-6-(2,4-dibutyloxyphenyl)-1,3,5-triazine), 2-(2-hydroxy-4-[2-ethylhexyloxy]phenyl)-4,6-di(4-phenyl)phenyl-1,3,5-triazine, 2-(2-hydroxy-4-[1-octyloxycarbonyl-ethyl]oxy-phenyl)-4,6-di(4-phenyl)phenyl-1,3,5-triazine, 2,4-bis-(4-[1-octyloxycarbonyl]-ethyloxy-2-hydroxyphenyl)-6-(2,4-dihydroxyphenyl)-1,3,5-triazine), 2,4,6-tris-(4-[1-octyloxycarbonyl]-ethyloxy-2-hydroxyphenyl)-1,3,5-triazine) and 2,4-bis-(4-[1-octyloxycarbonyl]-ethyloxy-2-hydroxyphenyl)-6-(4-[1-octyloxycarbonyl]-ethyloxy-2-hydroxyphenyl)-1,3,5-triazine) and
the merocyanines are selected from the group consisting of 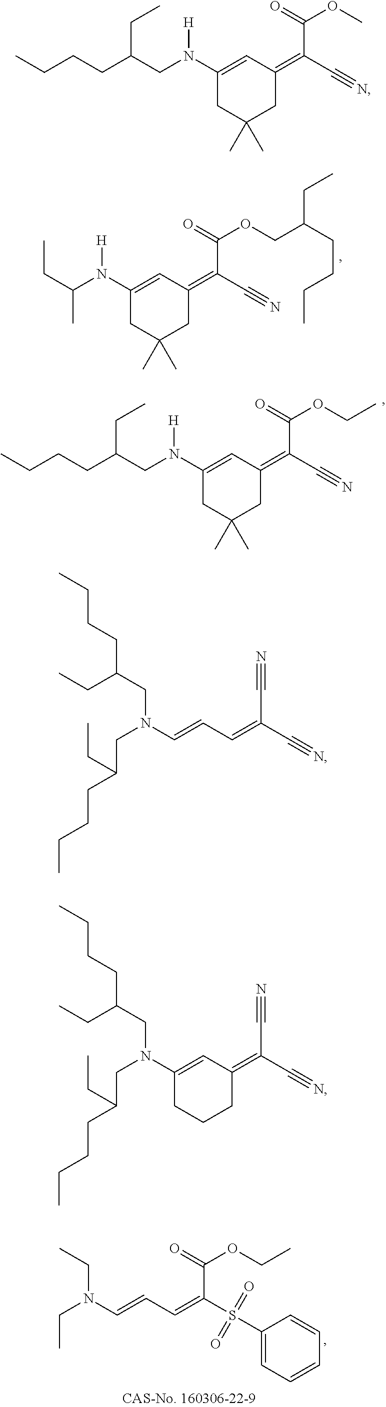 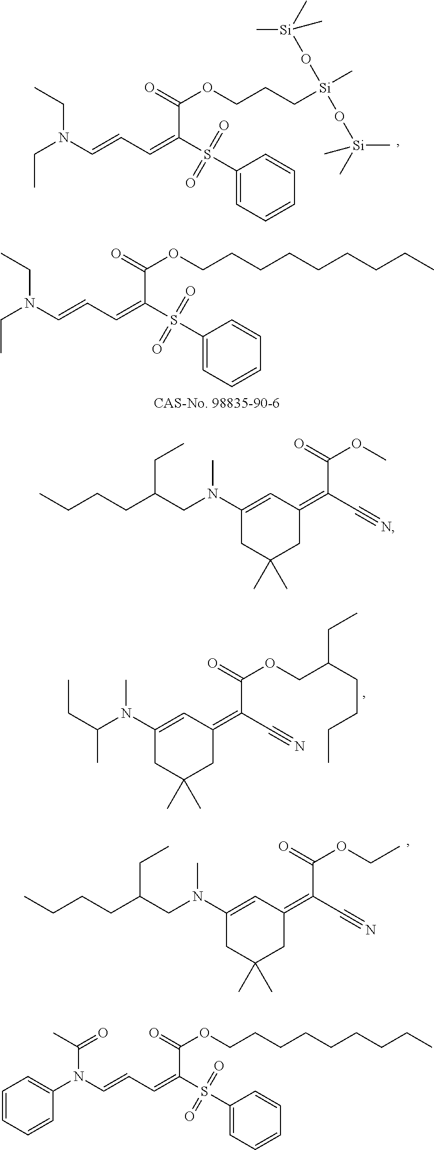
and E/Z-isomers thereof.

5. The device of claim 2, wherein the mixture comprises at least one anti-radical agent of formula (1) 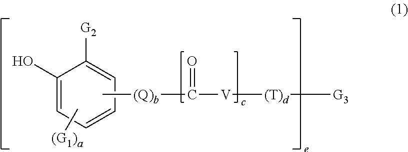
wherein
G₁ is hydrogen; C₁-C₂₂alkyl; C₁-C₂₂alkylthio; C₂-C₂₂alkylthioalkyl; C₅-C₇cycloalkyl; phenyl; C₇-C₉-phenylalkyl or SO₃M;
G₂ is C₁-C₂₂alkyl; C₅-C₇cycloalkyl; phenyl or C₇-C₉-phenylalkyl;
Q is —CₘH₂ₘ—; 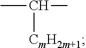
—CₘH₂ₘ—NH or a radical of formula (1a) or (1b) 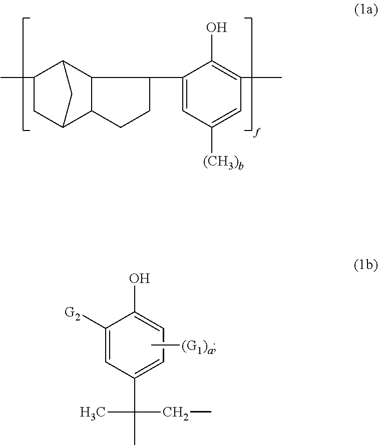
T is —CₙH₂ₙ—; —(CH₂)ₙ—O—CH₂—; phenylene; 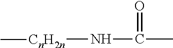
or a radical of 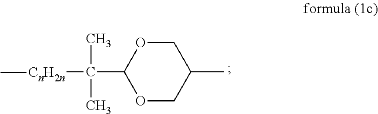
V is —O— or —NH—;
a is 0; 1 or 2;
b, c, d and g are each independently of one another 0 or 1;
e is an integer from 1 to 4;
f is an integer from 1 to 3 and
m, n and p are each independently of one another an integer from 1 to 3;
q is 0 or an integer from 1 to 3;
if e=1,
G₃ is hydrogen; C₁-C₂₂alkyl; C₅-C₇cycloalkyl; C₁-C₂₂alkylthio; C₂-C₂₂alkylthioalkyl; C₂-C₁₈alkenyl; C₁-C₁₈-phenylalkyl; M; SO₃M or a radical of formula 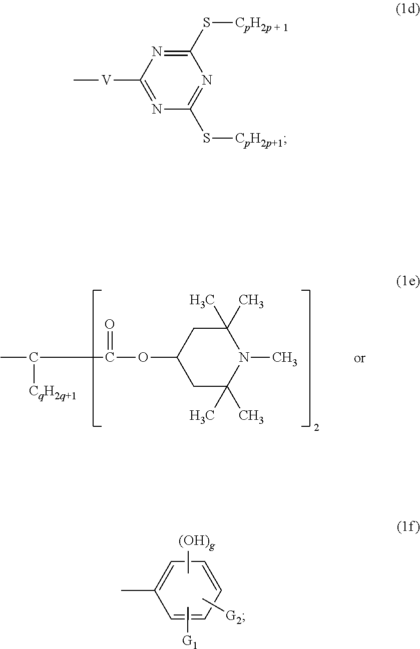
or
G₃ is propyl substituted by OH and/or by C₂-C₂₂alkanoyloxy and
M is alkali; ammonium or H;
if e=2, then each of b and c independently are selected from 0 and 1 and
G₃ is a direct bond; —CH₂—; 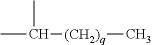
or —S—; or G₃ is propyl substituted by OH or C₂-C₂₂alkanoyloxy;
if e=3, then each of b and c independently are selected from 0 and 1 and
G₃ is aradical of formula 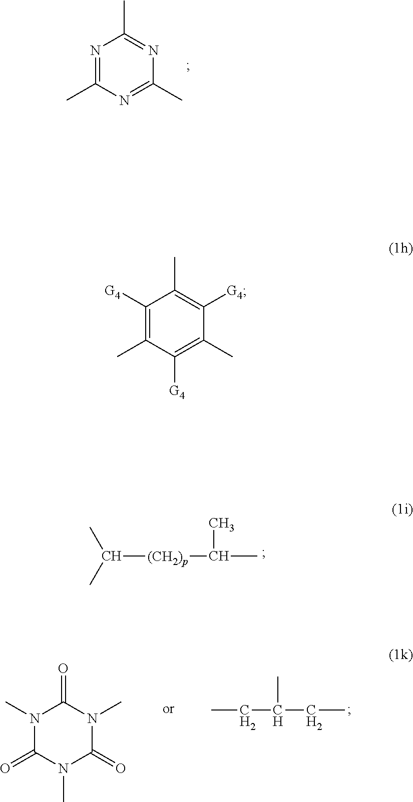
where
G₄ are each independently of the other hydrogen or C₁-C₂₂alkyl
and
if e=4, then each of b and c independently are selected from 0 and 1 and
G₃ is

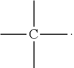

6. The device of claim 1, wherein the diketopyrrolopyrrole polymer is characterized by one or more DPP skeletons of formula 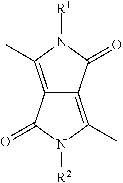
in the repeating unit, wherein R¹ and R² are the same or different from each other and are selected from the group consisting of hydrogen; a C₁-C₁₀₀ alkyl group; —COOR¹⁰⁶; a C₁-C₁₀₀ alkyl group which is substituted by one or more halogen atoms, hydroxyl groups, nitro groups, —CN or C₆-C₁₈ aryl groups and/or which is interrupted by —O—, —COO—, —OCO— or —S—; a C₇-C₁₀₀ arylalkyl group; a carbamoyl group; a C₅-C₁₂ cycloalkyl group which can be substituted one to three times with a C₁-C₈ alkyl group and/or a C₁-C₈ alkoxy group; a C₆-C₂₄ aryl group which can be substituted one to three times with a C₁-C₈ alkyl group, a C₁-C₂₅ thioalkoxy group and/or a C₁-C₂₅ alkoxy group; and pentafluorophenyl; with R¹⁰⁶ being a C₁-C₅₀ alkyl group.

7. The device of claim 1, wherein the diketopyrrolopyrrole polymer comprises at least one repeating unit of formula 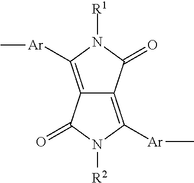
wherein
R¹ and R² independently are selected from the group consisting of hydrogen, a C₁-C₁₀₀alkyl group, said alkyl group which is substituted by one or more halogen atoms, hydroxyl groups, nitro groups, —CN or C₆-C₁₈aryl groups and/or which is interrupted by —O—, —COO—, —OCO— or —S—; COO—C₁-C₅₀alkyl; a C₇-C₁₀₀arylalkyl group; a carbamoyl group; C₅-C₁₂cycloalkyl which can be substituted one to three times with C₁-C₈alkyl and/or C₁-C₈alkoxy; C₆-C₂₄aryl which can be substituted one to three times with C₁-C₈alkyl,
C₁-C₈thioalkoxy and/or C₁-C₈alkoxy; and pentafluorophenyl;
Ar independently is a group of formula 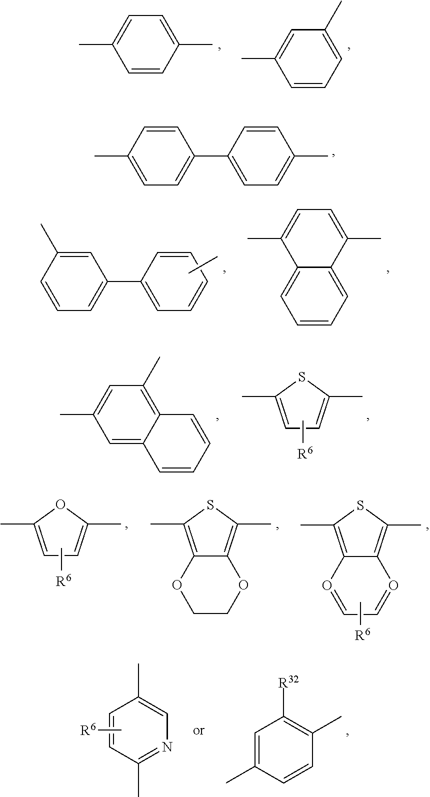
wherein R⁶ is hydrogen, C₁-C₁₈alkyl or C₁-C₁₈alkoxy and R³² is methyl, Cl or methoxy or Ar is a divalent residue selected from the group consisting of 2,5-thienylene and 2,5-furylene, each of which may be unsubstituted or substituted by R^{3′} or a divalent thiophene or thiazole moiety of formula 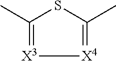
or for a divalent pyrrol moiety of formula 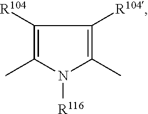
wherein one of X³ and X⁴ is N and the other is CH or CR^{3′}, where R^{3′} independently is halogen, C₁-C₂₅alkyl, C₇-C₂₅arylalkyl, C₁-C₂₅alkoxy or C₄-C₂₅alkyl group which is interrupted by one or more oxygen or sulphur atoms;
R¹⁰⁴ and R^{104′} independently are hydrogen or are as defined for R^{3′}; and
R¹¹⁶ is hydrogen, C₆-C₁₈aryl; C₆-C₁₈aryl which is substituted by C₁-C₁₈alkyl, C₁-C₁₈ perfluoroalkyl or C₁-C₁₈alkoxy; or C₁-C₂₅alkyl or COO—C₁-C₂₅alkyl each of which is unsubstituted or substituted in its alkyl part by CN, halogen or C₆-C₁₈aryl and/or in case that its alkyl part comprises 2 or more carbon atoms, may be interrupted by —CO—, —COO—, —CONR¹¹²—, —O—, —NR¹¹²— or —S—; where R¹¹² is H; C₆-C₁₈aryl; C₆-C₁₈aryl which is substituted by C₁-C₁₈alkyl or C₁-C₁₈alkoxy; C₁-C₁₈alkyl; or C₂-C₁₈alkyl which is interrupted by —O—.

8. The device of claim 1, wherein the diketopyrrolopyrrole polymer is of formula 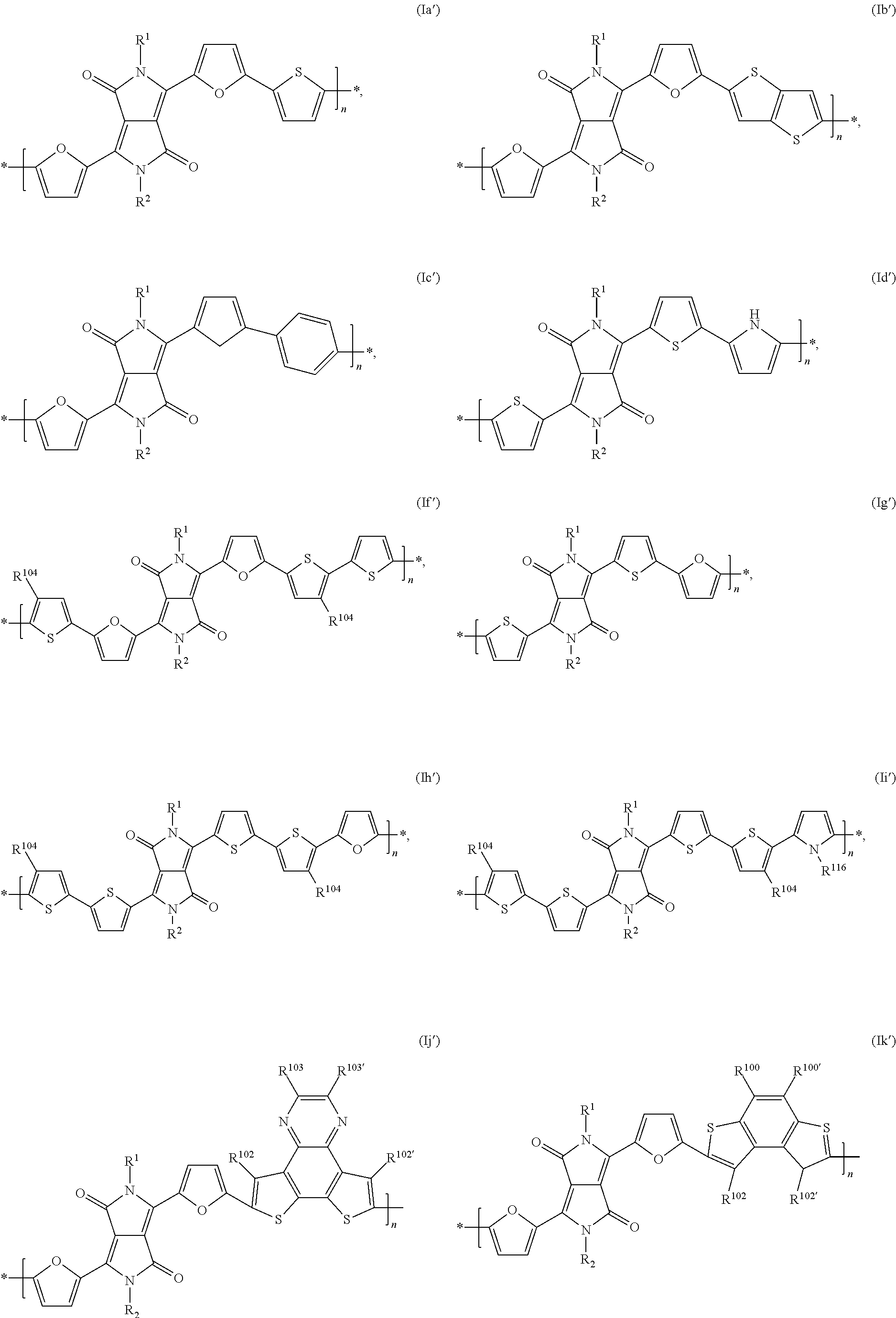 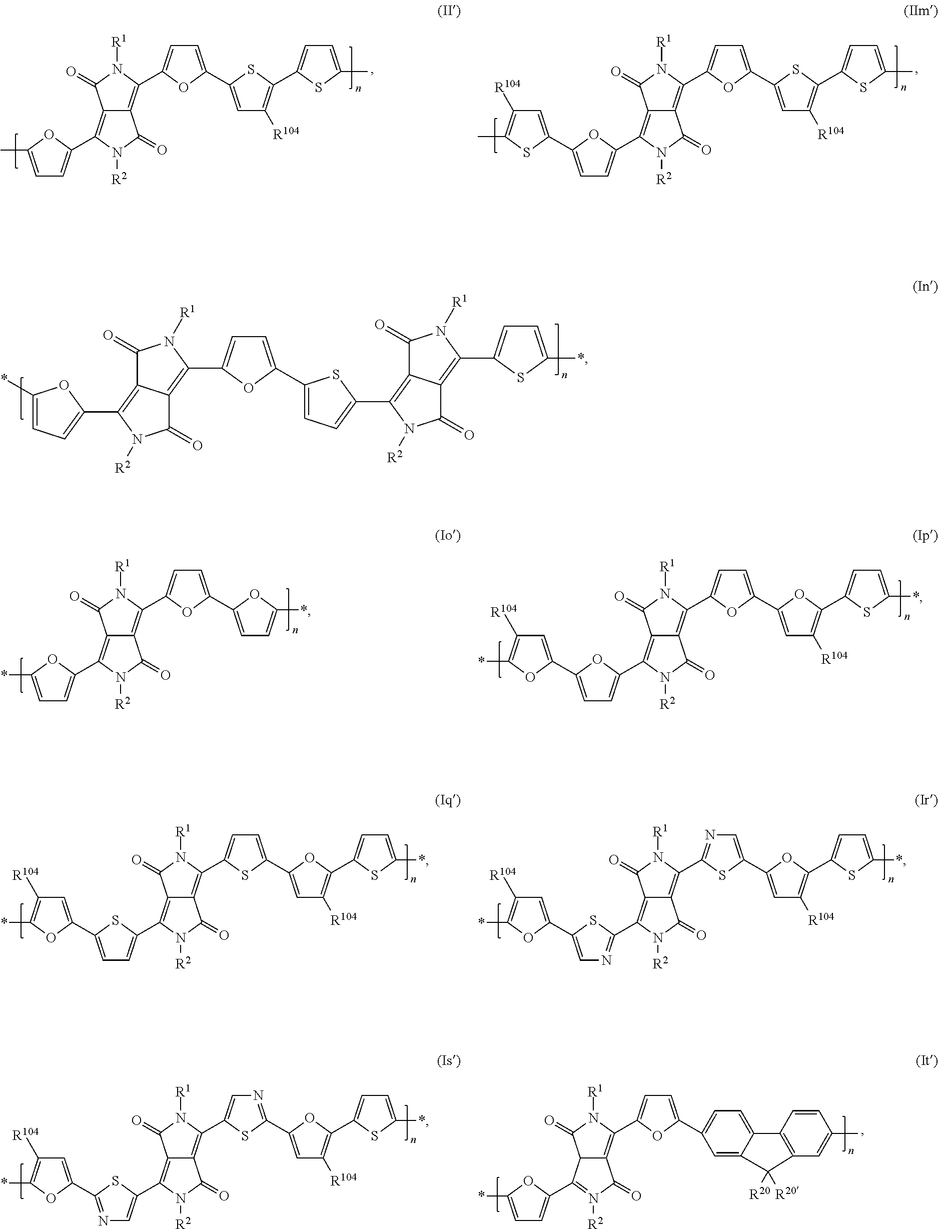 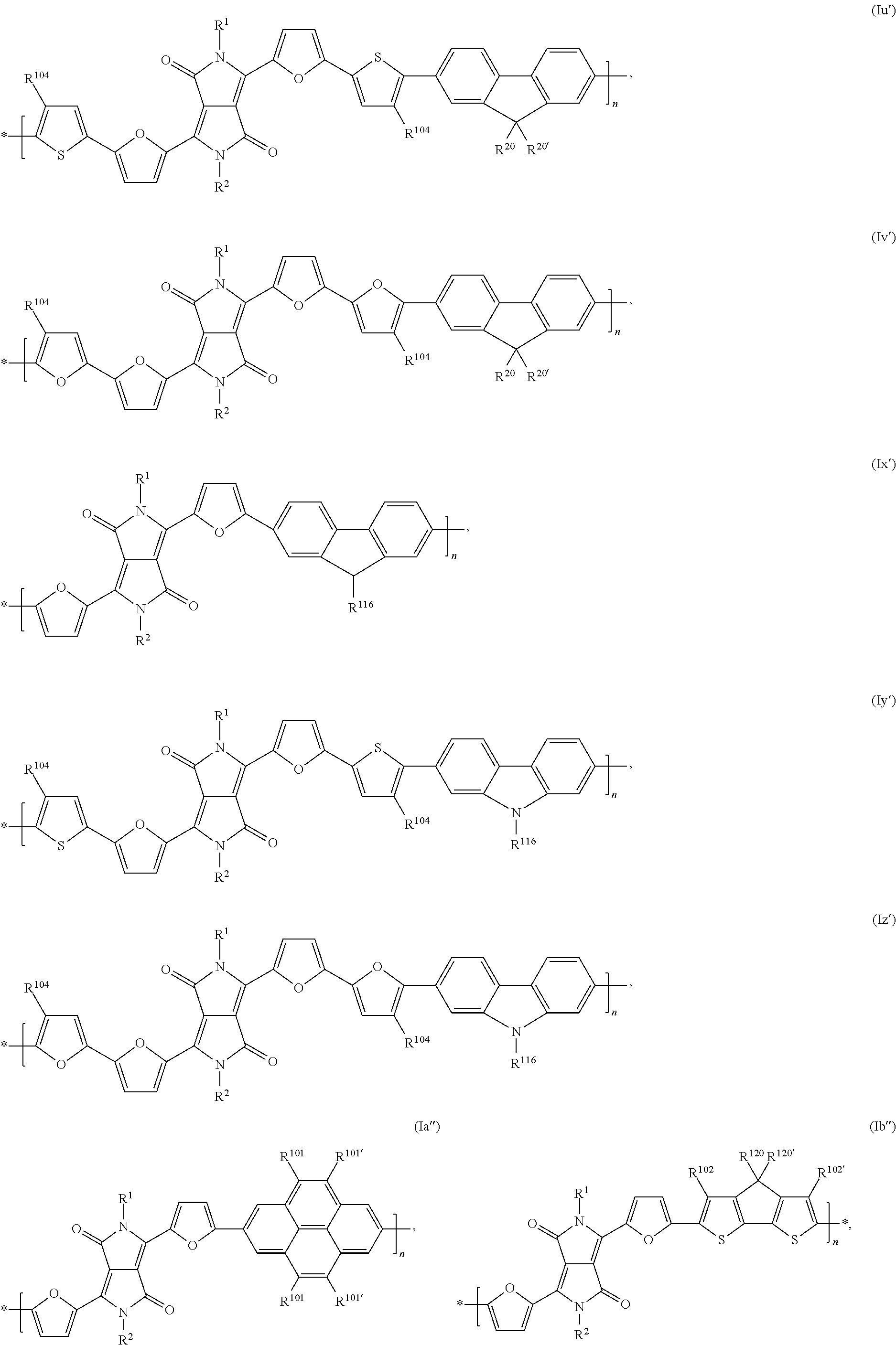 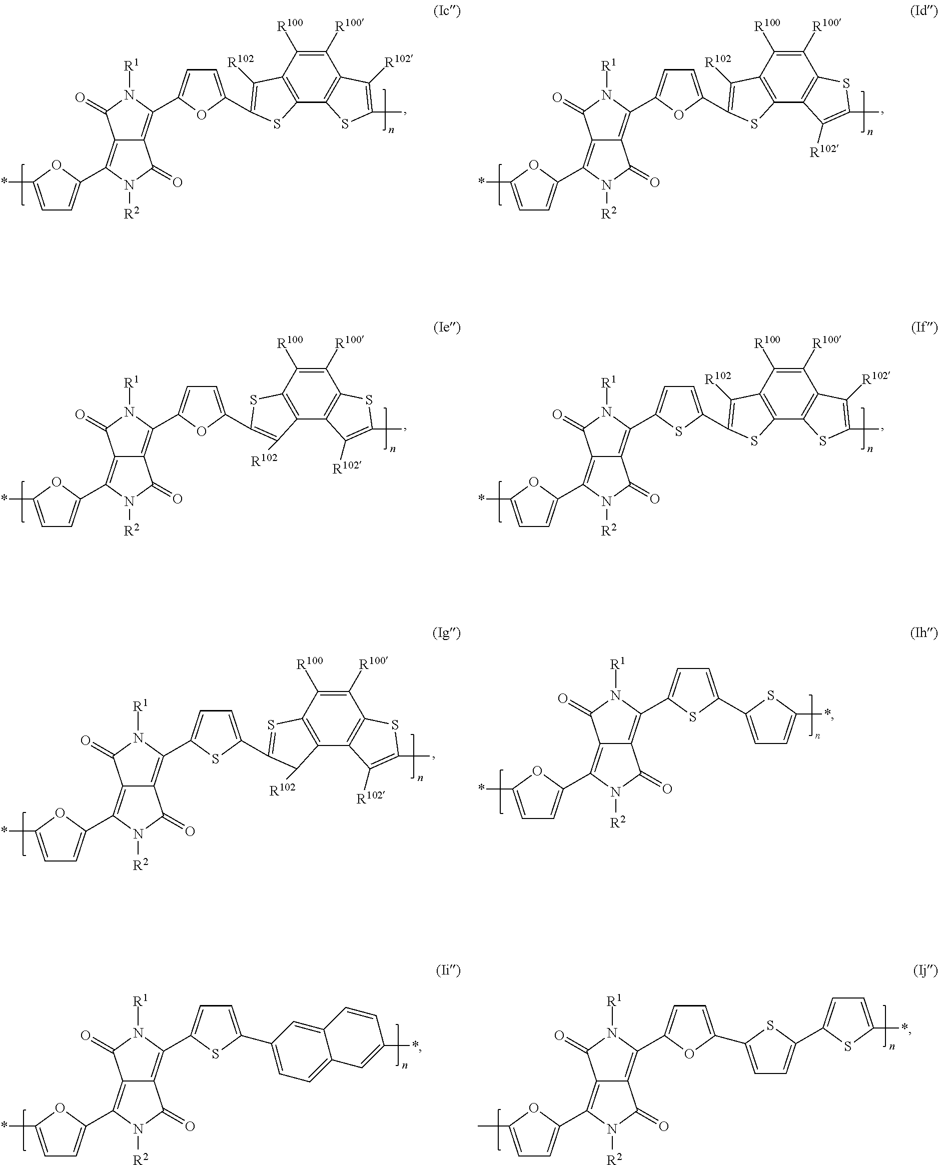 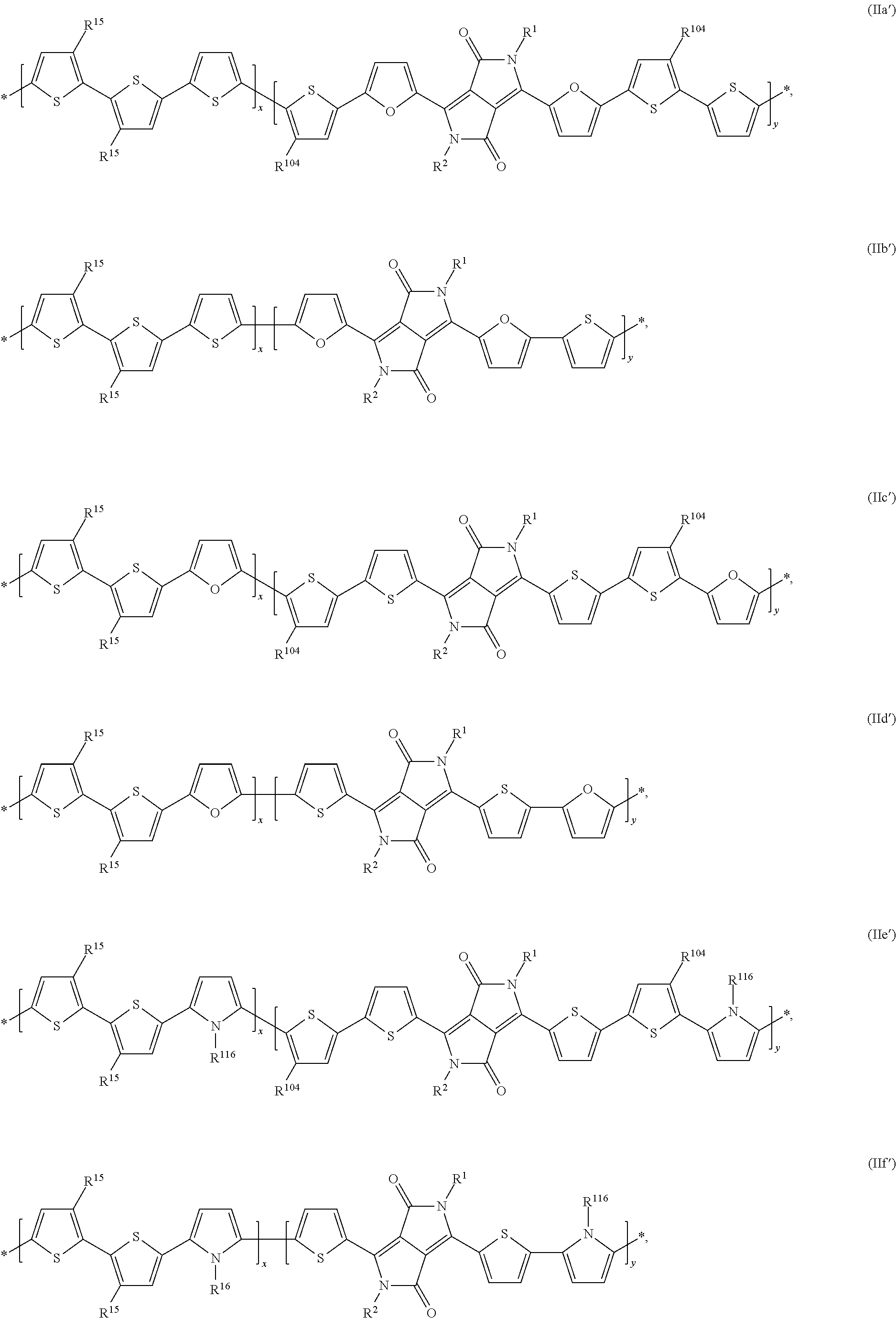 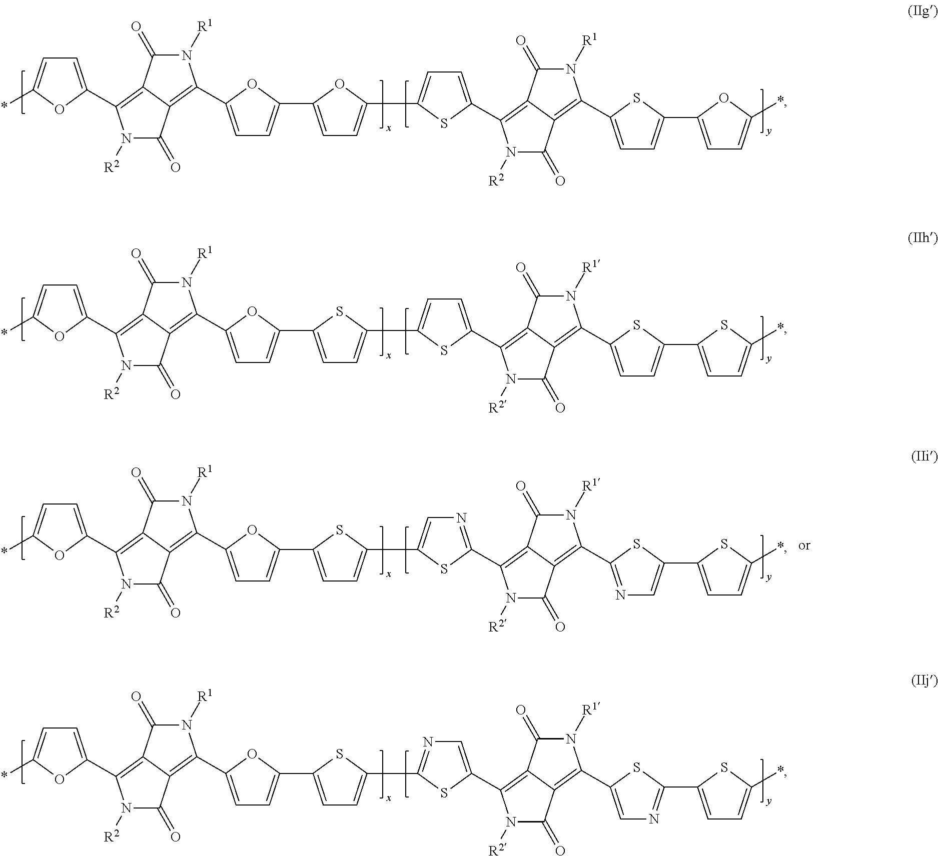
wherein R¹, R², R^{1′} and R^{2′} are independently of each other a C₁-C₃₆alkyl group,
R¹⁰⁴ is a C₁-C₂₅alkyl group, which may optionally be interrupted by one or more oxygen or sulphur atoms,
R¹⁵, R^{15′} R¹⁷ and R^{17′} are independently of each other H or a C₁-C₂₅alkyl group which may optionally be interrupted by one or more oxygen atoms,
R²⁰ and R^{20′} are independently of each other hydrogen, C₇-C₂₅aralkyl or C₁-C₂₅alkyl which may optionally be interrupted by one or more oxygen or sulphur atoms,
R¹⁰⁰ and R^{100′} are H,
R¹⁰¹ and R^{101′} are H, a C₁-C₂₅alkyl group or a C₁-C₂₅alkoxy group,
R¹⁰² and R^{102′} are H or a C₁-C₂₅alkyl group,
R¹⁰³ and R^{103′} are H or a C₁-C₂₅alkyl group,
R¹¹⁶ is H or a C₁-C₂₅alkyl group,
R¹²⁰ and R¹²⁰ are a C₁-C₃₅alkyl group,
n is 4 to 1000 and
x=0.995 to 0.005 and y=0.005 to 0.995 wherein x+y=1.

9. The device according to claim 1, wherein the diketopyrrolopyrrole polymer is of formula 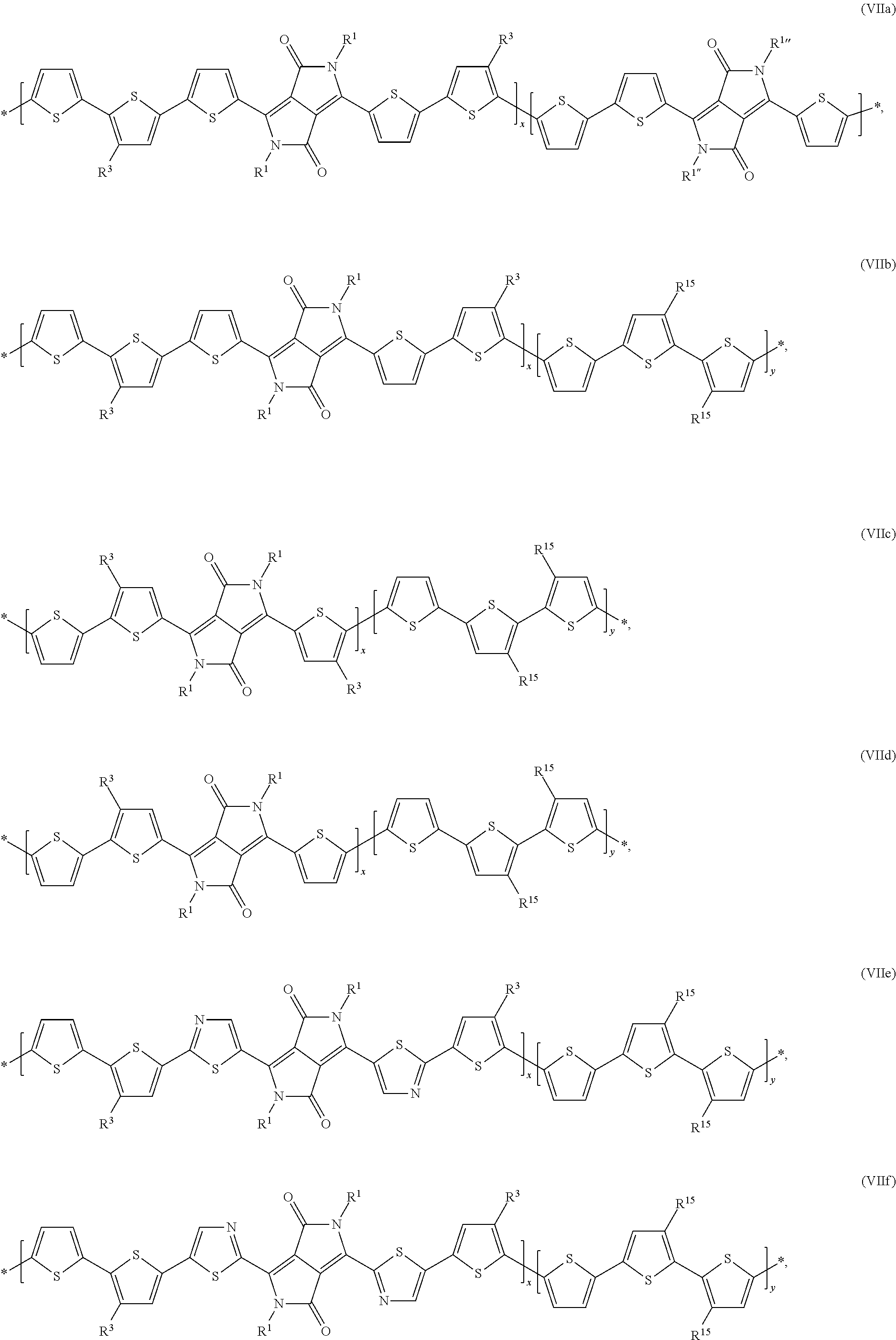 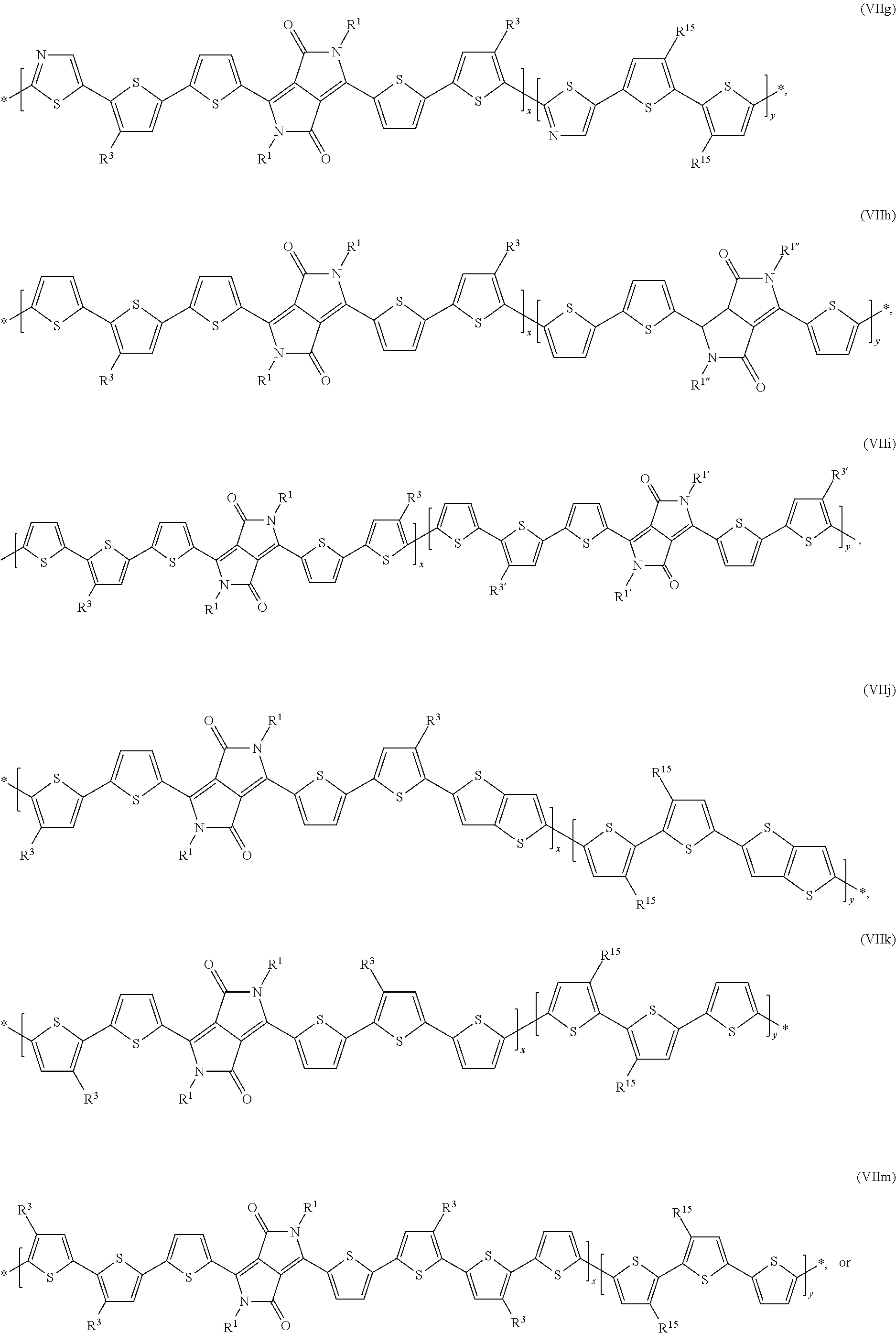 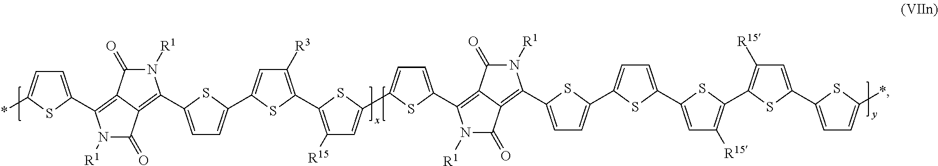
wherein
R¹ and R^{1″} are a C₈-C₃₈alkyl group,
R¹⁵, R^{15′} and R³ are a C₁-C₁₈alkyl group,
R¹′ is C₈-C₃₆alkyl,
R³′ is C₁-C₁₈alkyl,
R¹≠R¹′ and/or R³≠R³′,
x is 0.005 to 0.995 and
y is 0.995 to 0.005.

10. The device of claim 1, wherein the average molecular weight of the diketopyrrolopyrrole polymer, as determined by high temperature gel permeation chromatography using polystyrene standards, is from the range 4000 to 2000000 Daltons.

11. The device of claim 1, where in the mixture comprising the at least one diketopyrrolopyrrole polymer and the at least one stabilizing agent, the weight ratio of stabilizing agent relative to the diketopyrrolopyrrole polymer is in the range of from 0.0001:1 to 0.1:1 to

12. The device of claim 1, wherein the mixture additionally comprises at least one electron acceptor material, where the weight ratio of the electron acceptor material relative to the diketopyrrolopyrrole polymer is in the range of from 0.1:1 to 10:1.

13. The device of claim 1, comprising
(a) a cathode;
(b) optionally a transition layer;
(c) the photovoltaic layer;
(d) optionally a smoothing layer;
(j) an anode; and
(k) a substrate;
said device optionally further comprising
(e) a middle electrode;
(f) optionally a further electrode;
(g) optionally a transition layer;
(h) a further photovoltaic layer; and
(i) optionally a smoothing layer.

14. A process for the production of an organic photovoltaic device, said process comprising
(aa) providing at least one diketopyrrolopyrrole polymer, at least one stabilizing agent selected from the group consisting of UV absorbing agents and anti-radical agents and at least one electron acceptor material;
(bb) providing a substrate onto which an anode and optionally, onto the anode, a smoothing layer, has been applied;
(cc) mixing the compounds provided in (aa) with at least one suitable solvent; and
(dd) applying the mixture obtained from (cc) onto the anode, optionally onto the smoothing layer, via slot-die (extrusion) coating, reverse gravure coating, flexography printing or (forward) gravure printing.

15. The device of claim 12, wherein the electron acceptor material is an optionally suitably modified fullerene having from 60 to 96 carbon atoms.

16. The device of claim 12, where the weight ratio of the electron acceptor material relative to the diketopyrrolopyrrole polymer is in the range from 0.5:1 to 3:1.

17. The device of claim 12, where the weight ratio of the electron acceptor material relative to the diketopyrrolopyrrole polymer is in the range from 0.8:1 to 2:1.

18. The device of claim 11, where the weight ratio of stabilizing agent relative to diketopyrrolopyrrole polymer is in the range from 0.005:1 to 0.025:1.

19. The device of claim 10, where the average molecular weight of the diketopyrrolopyrrole polymer is from the range 10000 to 100000 Daltons.

20. The device of claim 8, where the diketopyrrolopyrrole polymer is [chemical structure]
